(19) United States
(12) Patent Application Publication
(10) Pub. No.: US 2026/0101490 A1
(43) Pub. Date: Apr. 9, 2026

(54) SEMICONDUCTOR STRUCTURE AND MANUFACTURING METHOD THEREOF

(71) Applicant: TAIWAN SEMICONDUCTOR MANUFACTURING COMPANY, LTD., Hsinchu (TW)

(72) Inventor: Jhon Jhy LIAW, Hsinchu County (TW)

(73) Assignee: TAIWAN SEMICONDUCTOR MANUFACTURING COMPANY, LTD., Hsinchu (TW)

(21) Appl. No.: 18/911,009

(22) Filed: Oct. 9, 2024

(51) Int. Cl. H10B 10/00; G11C 15/04

(52) U.S. Cl. CPC H10B 10/125; G11C 15/04

(57) ABSTRACT

A method includes forming a ternary content addressable memory (TCAM) cell in a device layer, wherein the TCAM comprises a first static random access memory (SRAM) cell, a second SRAM cell, and a match cell, the first SRAM cell comprises a first pull-down transistor and a second pull-down transistor, and the second SRAM cell comprises a third pull-down transistor and a fourth pull-down transistor; forming a match line over a front-side of the device layer, wherein the match line is electrically coupled to the match cell; forming a first power supply voltage line over a back-side of the device layer, wherein the first power supply voltage line is electrically coupled to the first and third pull-down transistors of the first and second SRAM cells.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are schematic views of a wafer including a front-side interconnect structure and a back-side interconnect structure on a device region thereof in accordance with some embodiments of the present disclosure.

FIGS. 2A and 2B are circuit diagrams of ternary content addressable memory (TCAM) cells in accordance with some embodiments of the present disclosure.

FIGS. 3A and 3B illustrate layout diagrams of a memory cell on a front side and a back side of a semiconductor structure, respectively, according to some embodiments of the present disclosure.

FIGS. 3C to 3H illustrate cross-sectional views obtained from reference cross-sections C1-C1′, C2-C2′, C3-C3′, C4-C4′, C5-C5′, and C6-C6′ in FIGS. 3A and 3B.

FIGS. 4A and 4B illustrate layout diagrams of a memory cell on a front side and a back side of a semiconductor structure, respectively, according to some embodiments of the present disclosure.

FIGS. 5A and 5B illustrate layout diagrams of a memory cell on a front side and a back side of a semiconductor structure, respectively, according to some embodiments of the present disclosure.

FIGS. 6A and 6B illustrate layout diagrams of a memory cell on a front side and a back side of a semiconductor structure, respectively, according to some embodiments of the present disclosure.

FIGS. 7A and 7B illustrate layout diagrams of a memory cell on a front side and a back side of a semiconductor structure, respectively, according to some embodiments of the present disclosure.

FIGS. 8A and 8B illustrate layout diagrams of a memory cell on a front side and a back side of a semiconductor structure, respectively, according to some embodiments of the present disclosure.

FIGS. 9A and 23C illustrate schematic views of intermediate stages in the formation of a semiconductor structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit (IC) structures and methods of forming the same. More particularly, some embodiments of the present disclosure are related to gate-all-around (GAA) devices including improved isolation structures to reduce current leakage from channels to the substrate. A GAA device includes a device that has its gate structure, or portions thereof, formed on four-sides of a channel region (e.g., surrounding a portion of a channel region). The channel region of a GAA device may include nanosheet channels, bar-shaped channels, and/or other suitable channel configurations. In some embodiments, the channel region of a GAA device may have multiple horizontal nanosheets or horizontal bars vertically spaced, making the GAA device a stacked horizontal GAA (S-HGAA) device. The GAA devices presented herein include a p-type metal-oxide-semiconductor GAA device and an n-type metal-oxide-semiconductor GAA device stack together. Further, the GAA devices may have one or more channel regions (e.g., nanosheets) associated with a single, contiguous gate structure, or multiple gate structures. One of ordinary skill may recognize other examples of semiconductor devices that may benefit from aspects of the present disclosure. In some embodiments, the nanosheets can be interchangeably referred to as nanowires, nanoslabs, nanorings, or nanostructures having nano-scale size (e.g., a few nanometers), depending on their geometry. In addition, the embodiments of the disclosure may also be applied, however, to a variety of metal oxide semiconductor transistors (e.g., complementary-field effect transistor (CFET) and fin field effect transistor (FinFET)).

Some embodiments discussed herein are discussed in the context of nano-FETs formed using a gate-last process. In other embodiments, a gate-first process may be used. Also, some embodiments contemplate aspects used in planar devices, such as planar FETs, or in fin field-effect transistors (FinFETs). For example, FinFETs may include fins on a substrate, with the fins acting as channel regions for the FinFETs. Similarly, planar FETs may include a substrate, with portions of the substrate acting as channel regions for the planar FETs.

In the course of IC evolution, functional density (i.e., the number of interconnected devices per chip area) has generally increased while geometry size (i.e., the smallest component (or line) that can be created using a fabrication process) has decreased. However, the smaller and more dense the metal lines in the IC structure will result in worse resistant thereof, thereby wasting processing power and processing speed during the operation of the IC structure. For example, in a cell routing of the IC structure, Vdd and Vss power routing may occupy too many routing resources and therefore impact the cell scaling as well as the performance of the IC structure (e.g., RC delay or IR drop).

Therefore, the present disclosure in various embodiments provides a metal line routing method for memory cell, such as ternary content addressable memory (TCAM) cell, to improve the functional density and operation performance on the IC structure. This method can place lower-level metal layers, such as Vss and/or Vss, to the back-side of the wafer. This placement can not only facilitate further scaling by freeing up space on the front-side but also reduce parasitic capacitance and improve overall device integrity. Additionally, the match line contact of the TCAM cell can be located at the cell boundaries and can be shared with adjacent cells, optimizing the integration within the chip layout and reducing resistance at the junctions, which in turn allows for enhancing the electrical performance and reliability of the device. Embodiments disclosed herein will be described with respect to the TCAM cell and array. Various modifications are discussed with respect to embodiments; however, other modifications may be made to disclosed embodiments while remaining within the scope of the subject matter. A person of ordinary skill in the art will understand modifications that may be made.

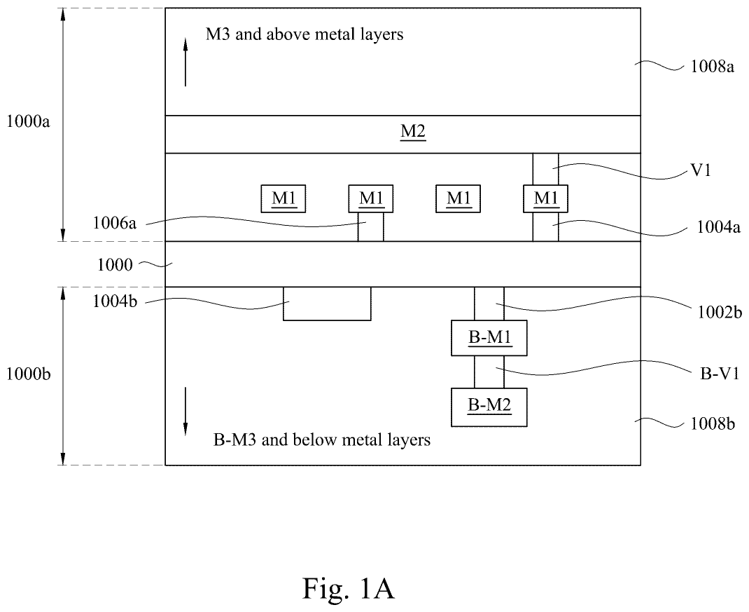

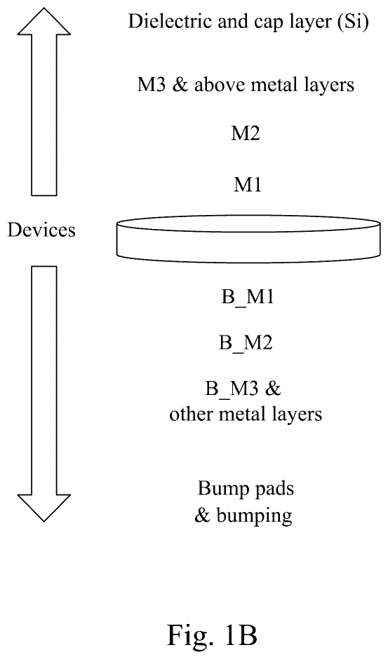

Reference is made to FIGS. 1A and 1B. FIGS. 1A and 1B are schematic views of a wafer including a front-side interconnect structure and a back-side interconnect structure on a device region thereof in accordance with some embodiments of the present disclosure. As shown in FIGS. 1A and 1B, a device region 1000 (see FIG. 1A) is provide in the wafer W and includes, such as gate, channel, and source/drain regions. A front-side interconnect structure 1000a is formed after the device region formation. Specifically, the front-side interconnect structure 1000a is formed to have a front-side gate via 1006a, and a front-side source/drain via 1004a. The front-side interconnect structure 1000a may further include, for example, two metallization layers, labeled as M1 and M2, with one layer of metallization via or interconnect, labeled as V1. Other embodiments may contain more or fewer metallization layers and corresponding more or fewer number of vias. The metal line illustrated here just for an example, and the metal line may be otherwise oriented (rotated 90 degrees or at other orientations). The front-side interconnect structure 1000a includes a full metallization stack, including a portion of each of metallization layers M1 and M2 connected by the interconnect V1, with the front-side gate via 1006a, and the front-side source/drain via 1004a connecting the stack to the source/drain region and the gate of the transistor in the device region 1000. As shown in FIG. 1B, a dielectric structure and a cap layer may be further formed over the front-side interconnect structure 1000a. Also included in the front-side interconnect structure 1000a shown in FIG. 1A is a front-side IMD (inter-metal dielectric) layer 1008a. The front-side IMD layer 1008a may provide electrical insulation as well as structural support for the various features in the front-side interconnect structure 1000a.

As shown in FIGS. 1A and 1B, a back-side interconnect structure 1000b (see FIG. 1A) is formed after device region formation. Specifically, a back-side interconnect structure 1000b is formed to have a back-side via 1002b and a back-side contact 1004b. In some embodiments, the back-side contact 1004b can be a back-side butt contact connecting a source/drain region and a gate structure of a transistor in the device region 1000. The back-side interconnect structure 1000b may further include, for example, two metallization layers, labeled as B-M1 and B-M2, with one layer of metallization via or interconnect, labeled as B-V1. Other embodiments may contain more or fewer metallization layers and corresponding more or fewer number of vias. The metal line illustrated here just for an example, and the metal line may be otherwise oriented (rotated 90 degrees or at other orientations). The back-side interconnect structure includes a full metallization stack, including a portion of each of metallization layers B-M1 and B-M2 connected by interconnect B-V1, with the back-side via 1002b and the back-side contact 1004b connecting the stack to the source/drain region and the gate structure of the transistor in the device region 1000. As shown in FIG. 1B, a plurality of bond pads may be further formed over the back-side interconnect structure 1000b. Also included in the back-side interconnect structure 1000b shown in FIG. 1A can be a back-side IMD layer 1008b. The back-side IMD layer 1008b may provide electrical insulation as well as structural support for the various features in the back-side interconnect structure 1000b.

FIG. 1B illustrates a semiconductor structure including the layers and materials used in both the front-side and back-side configurations, as well as in the I/O and power bump pads. In some embodiments, the front-side of the semiconductor device can include more than six levels of metal layers. This front-side multilayer structure can be used for facilitating complex routing and connectivity within the device, allowing for enhanced signal integrity and electrical performance by providing multiple pathways for electrical signals, reducing cross-talk, and enabling more efficient distribution of power and ground connections. In some embodiments, the back-side of the semiconductor device can include more than three levels of metal layers.

In some embodiments, I/O bump pads and power bump pads, along with solder bumping, can be placed on the back-side of the semiconductor structure. This placement can optimize the use of available space on the front-side for other components and circuits. In some embodiments, the I/O bump pads, the power bump pads, and the solder bumping can be made from aluminum (Al), copper (Cu), nickel (Ni), or combinations thereof. In some embodiments, a passivation layer (e.g., dielectric layer) can act as an insulator to protect the underlying circuits from electrical shorts and external contaminants, which in turn allows for maintaining the integrity and reliability of electrical functions of the device. In some embodiments, a polyimide layer can be added in the passivation layer.

In some embodiments, an under bump metallization (UBM) can serve as a barrier and adhesion promoter between the pad and the solder bump, ensuring a strong bond and uniform current distribution across the connection, reducing electromigration, and improving the longevity of the device. In some embodiments, a redistribution layer (RDL) can be formed in the back-side of the semiconductor structure. The redistribution layer can facilitates the redistribution of electrical connections from the densely packed integrated circuit to the more spread-out bump pads. In some embodiments, bump balls can be formed over the back-side of the semiconductor structure. The bump balls can be made of a lead-free material.

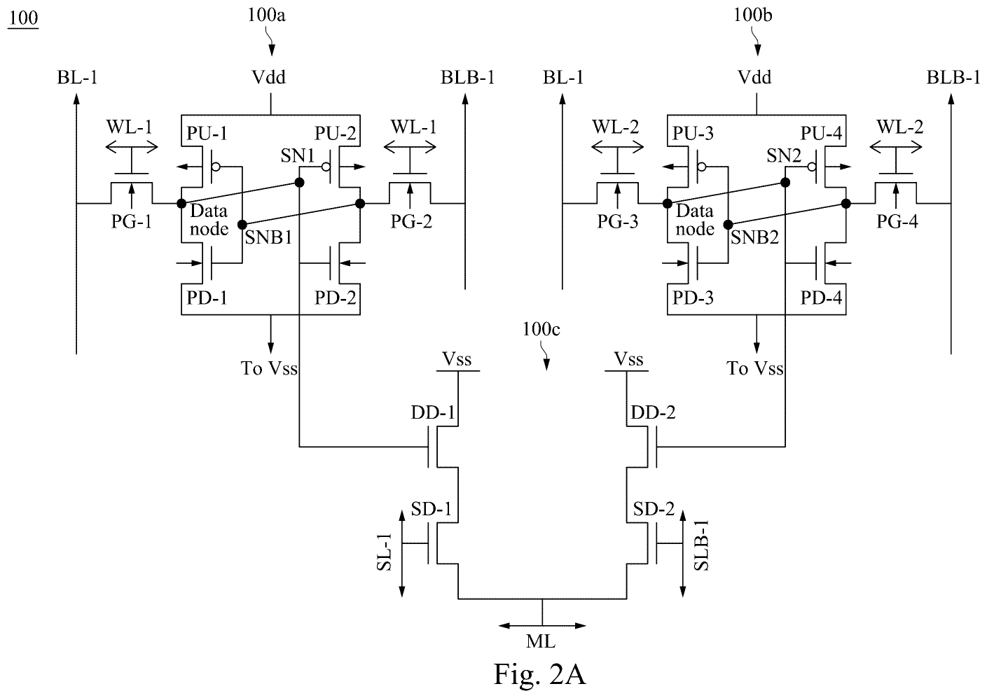

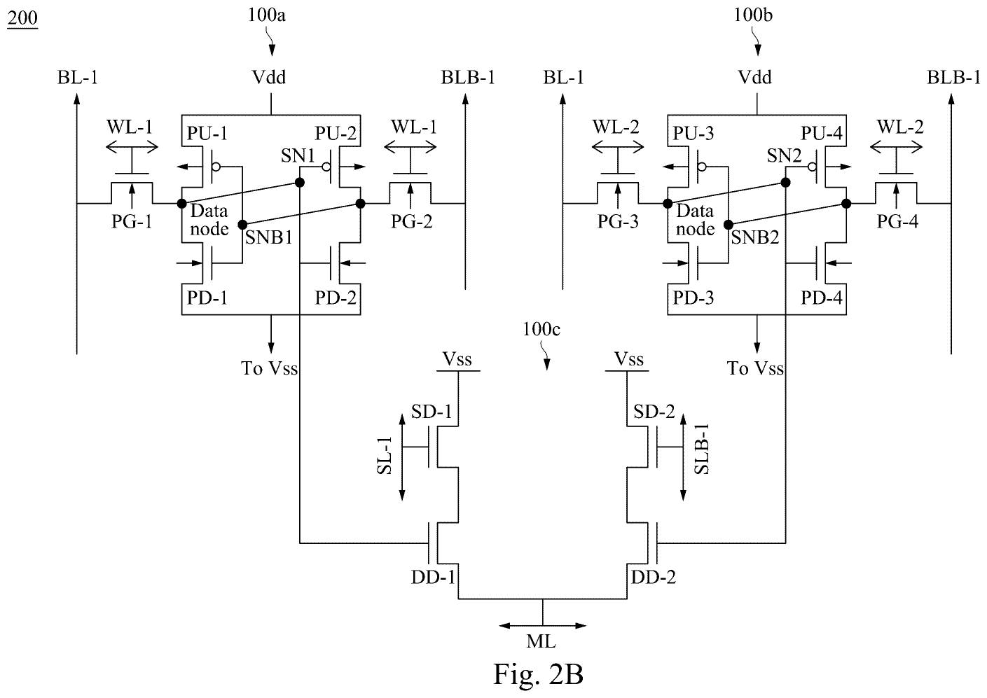

Reference is made to FIG. 2A. FIG. 2A is a circuit diagram of a memory cell 100, such as a ternary content addressable memory (TCAM) cell, in accordance with some embodiments of the present disclosure. The memory cell 100 can include pull-up transistors PU-1, PU-2 PU-3, and PU-4; pull-down transistors PD-1, PD-2, PD-3, and PD-4; pass-gate transistors PG-1, PG-2, PG-3, and PG-4; search gate transistors SD-1 and SD-2; and data gate transistors DD-1 and DD-2. In some embodiments, the transistors PU-1, PU-2, PU-3, and PU-4 can be of a first conductivity type, and the transistors PG-1, PG-2, PG-3, PG-4, PD-1, PD-2, PD-3, PD-4, SD-1, SD-2, DD-1, and DD-2 can be of a second conductivity type opposite to the first conductivity type. By way of example but not limiting the present disclosure, the transistors PU-1, PU-2, PU-3, and PU-4 can be p-type transistors, and the transistors PG-1, PG-2, PG-3, PG-4, PD-1, PD-2, PD-3, PD-4, SD-1, SD-2, DD-1, and DD-2 can be n-type transistors. In some embodiments, the transistors PU-1, PU-2, PU-3, and PU-4 can be n-type transistors, and transistors PG-1, PG-2, PG-3, PG-4, PD-1, PD-2, PD-3, PD-4, SD-1, SD-2, DD-1, and DD-2 are p-type transistors.

The drains of the pull-up transistor PU-1 and the pull-down transistor PD-1 are coupled together, and the drains of the pull-up transistor PU-2 and the pull-down transistor PD-2 are coupled together. The transistors PU-1 and PD-1 are cross-coupled with transistors PU-2 and PD-2 to form a first data latch. The gates of the transistors PU-2 and PD-2 are coupled together and to the drains of the transistors PU-1 and PD-1 to form a first storage node SN1, and the gates of the transistors PU-1 and PD-1 are coupled together and to the drains of transistors PU-2 and PD-2 to form a complementary first storage node SNB1. Sources of the pull-up transistors PU-1 and PU-2 are coupled to power voltage Vdd, and the sources of the pull-down transistors PD-1 and PD-2 are coupled to a ground voltage Vss.

The first storage node SN1 of the first data latch is coupled to a bit line BL through the pass-gate transistor PG-1, and the complementary first storage node SNB1 is coupled to the complementary bit line BLB through the pass-gate transistor PG-2. The first storage node N1 and the complementary first storage node SNB1 are complementary nodes that are at opposite logic levels (logic high or logic low). Gates of the pass-gate transistors PG-1 and PG-2 are coupled to a word line WL.

The drains of the pull-up transistor PU-3 and the pull-down transistor PD-3 are coupled together, and the drains of the pull-up transistor PU-4 and the pull-down transistor PD-4 are coupled together. The transistors PU-3 and PD-3 are cross-coupled with the transistors PU-4 and PD-4 to form a second data latch. The gates of the transistors PU-4 and PD-4 are coupled together and to the drains of the transistors PU-3 and PD-3 to form a second storage node SN2, and the gates of the transistors PU-3 and PD-3 are coupled together and to the drains of the transistors PU-4 and PD-4 to form a complementary second storage node SNB2. Sources of the pull-up transistors PU-3 and PU-4 are coupled to the power voltage Vdd, and the sources of the pull-down transistors PD-3 and PD-4 are coupled to the ground voltage Vss.

The second storage node SN2 of the second data latch is coupled to the bit line BL through pass-gate transistor PG-3, and the complementary second storage node SNB2 is coupled to the complementary bit line BLB through the pass-gate transistor PG-4. The second storage node SN2 and the complementary second storage node SNB2 are complementary nodes that are at opposite logic levels (logic high or logic low). Gates of the pass-gate transistors PG-3 and PG-4 are coupled to the word line WL.

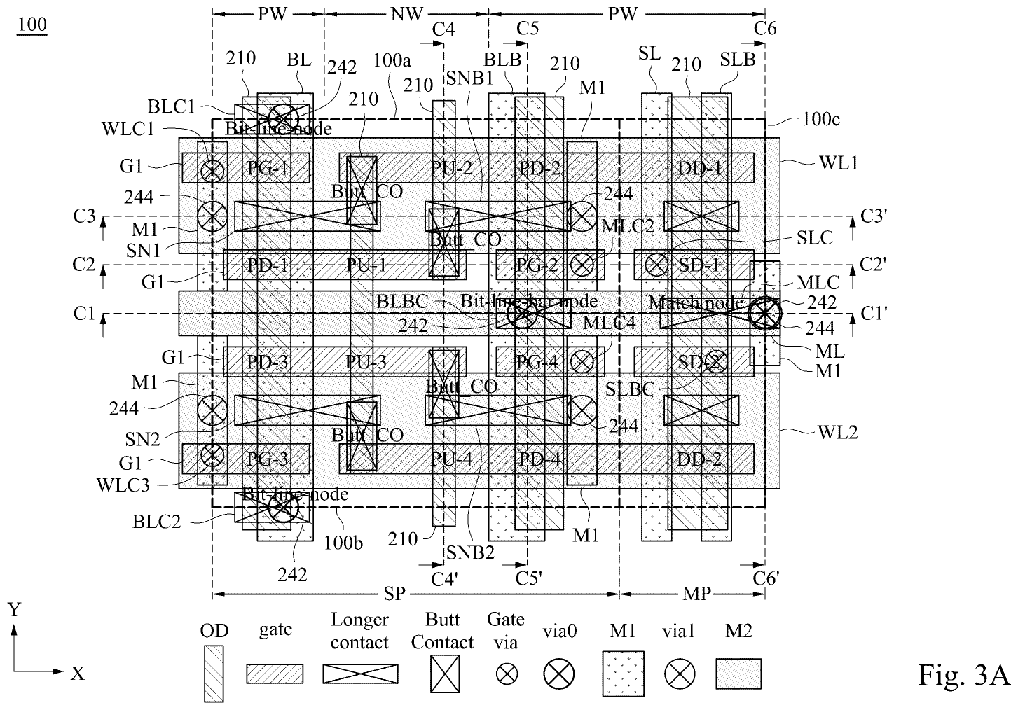

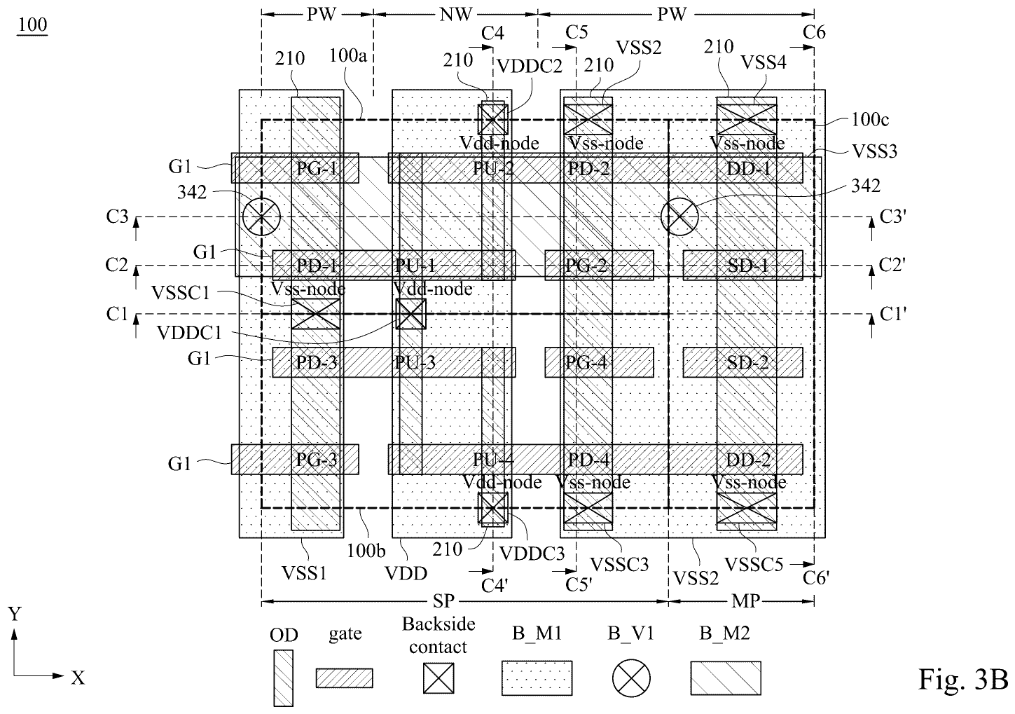

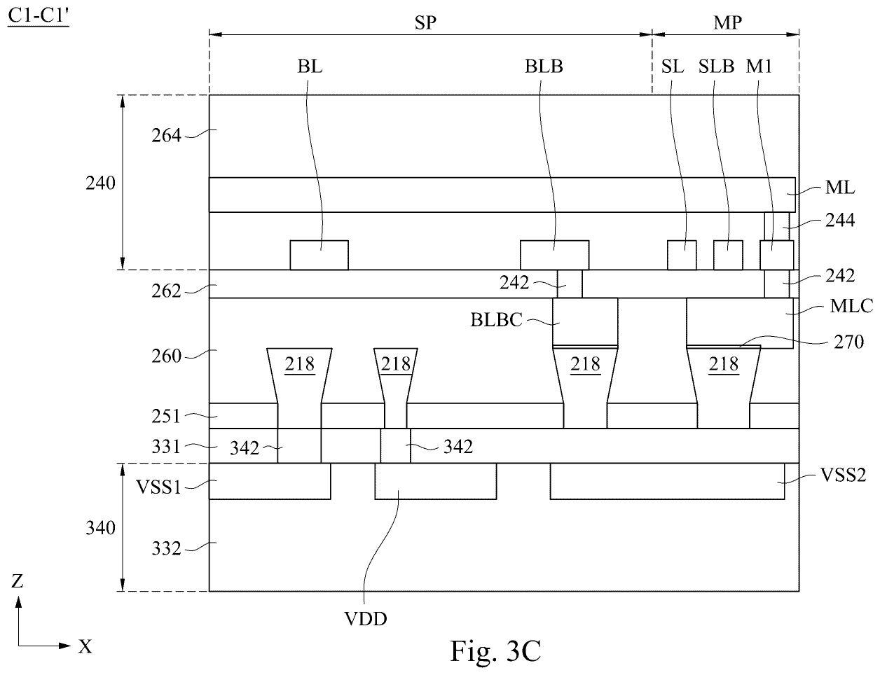

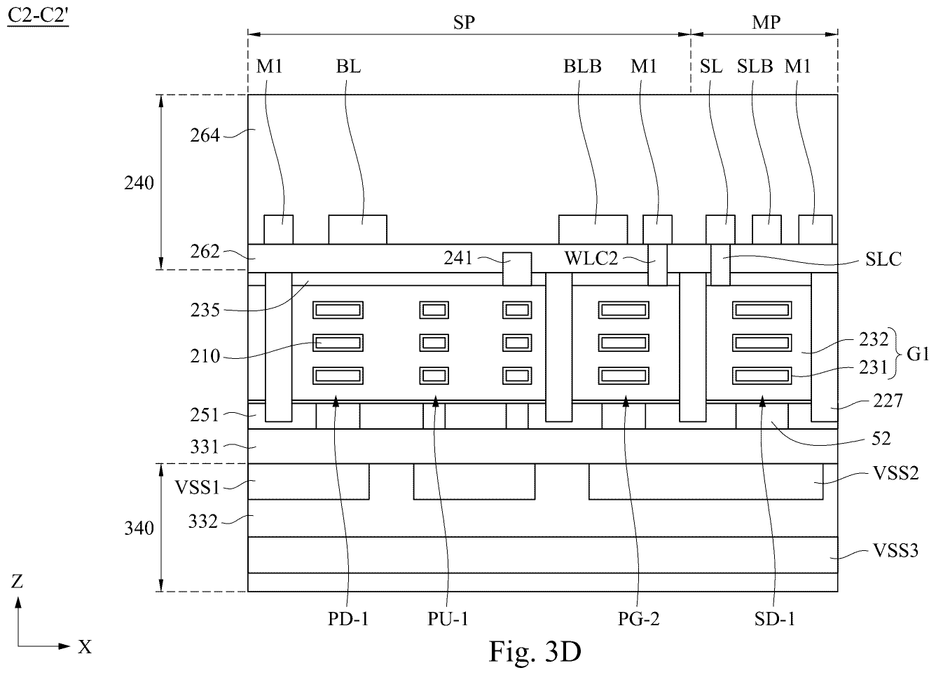

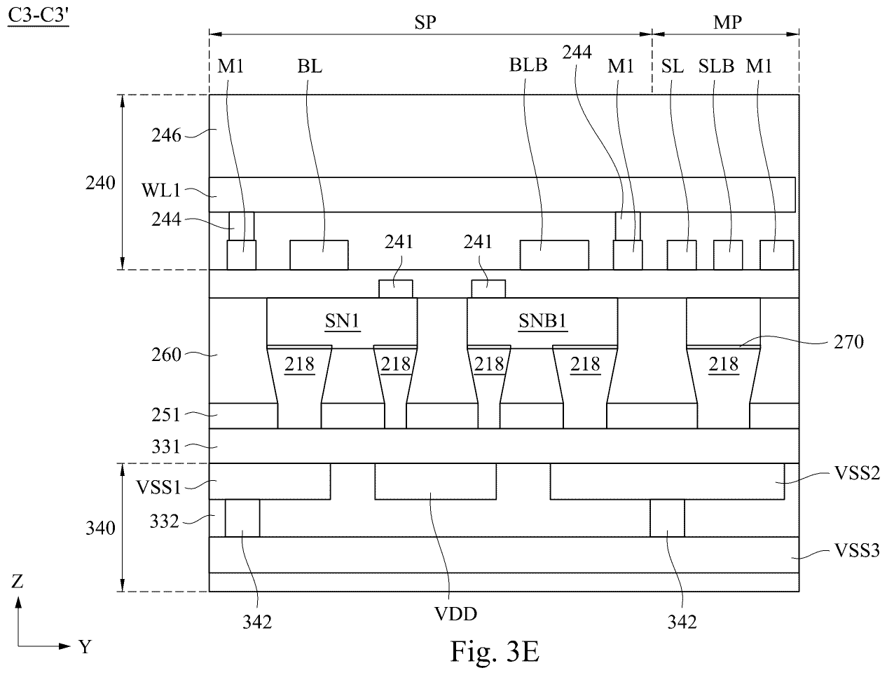

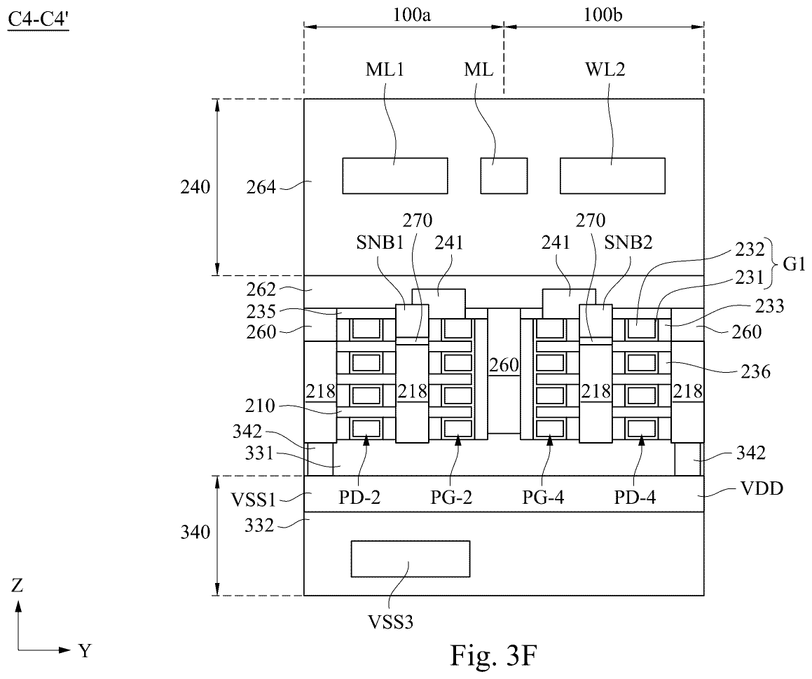

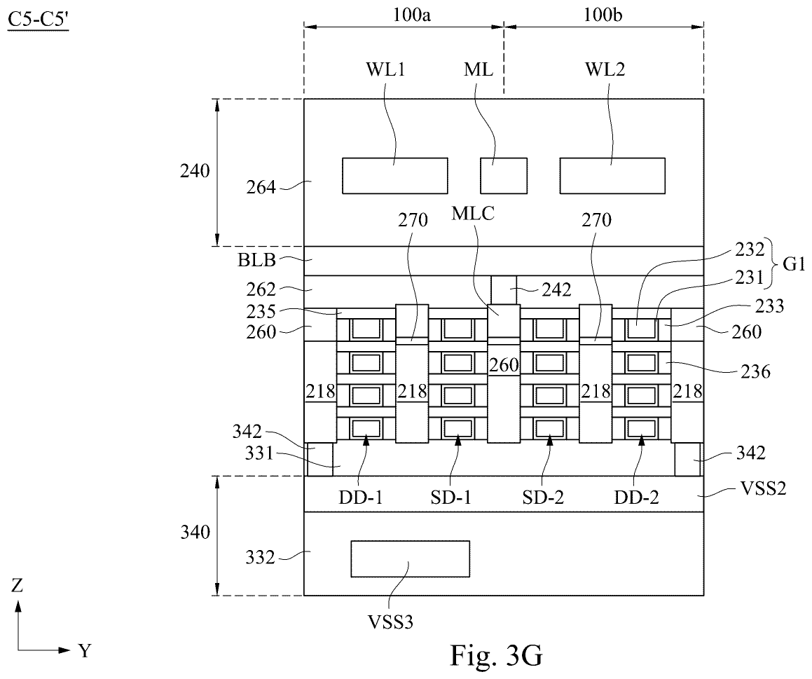

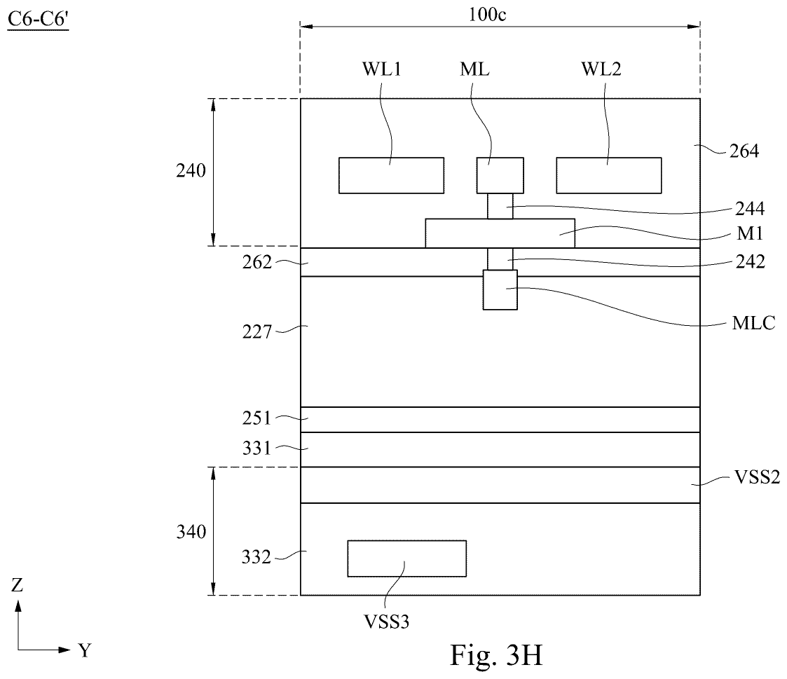

Together, the first and second data latches form a storage port SP (see FIGS. 3A and 3B) of the memory cell 100. A match port MP (see FIGS. 3A and 3B) of the memory cell 100 can be cascaded from the storage port SP. A source of the data gate transistor DD-1 is coupled to a ground voltage Vss. A drain of the data gate transistor DD-1 is coupled to a source of the search gate transistor SD-1. A drain of the search gate transistor SD-1 is coupled (adjacent) to a match line ML. A gate of the search gate transistor SD-1 is coupled to a search line SL, and a gate of the data gate transistor DD-1 is coupled to the first storage node SN1. A source of the data gate transistor DD-2 is coupled to a ground voltage Vss. A drain of the data gate transistor DD-2 is coupled to a source of the search gate transistor SD-2. A drain of the search gate transistor SD-2 is coupled (adjacent) to the match line ML. A gate of the search gate transistor SD-2 is coupled to a complementary search line SLB, and a gate of the data gate transistor DD-2 is coupled to the second storage node SN2.

Reference is made to FIGS. 3A-3H. FIGS. 3A and 3B illustrate layout diagrams of the memory cell 100, such as a TCAM cell, on a front side and a back side of a semiconductor structure, respectively, according to some embodiments of the present disclosure. FIGS. 3A and 3B each illustrates two dashed boxes, where each dashed box represents a data latch portion (i.e., first storage cell 100a/second storage cell 100a) and corresponding cascaded device portion (i.e., match cell 100c). The data latch portions of both boxes represent the storage port SP (e.g., static random access memory (SRAM) cell region), and the cascaded device portions of both boxes represent the match port MP. The exterior boundaries of the dashed boxes represent boundaries of the cell. The memory cell 100 may be mirrored around any Y-direction exterior boundary or mirrored or translated around any X-direction exterior boundary to form a layout comprising more cells, such as an array of cells.

Specifically, in the SRAM cell region, power supply voltage line VSS1, VSS2, and VDD (see FIG. 3B) can be placed on the back-side of the semiconductor structure to lower metal resistance, which contributes to speed enhancement by reducing the power IR (voltage drop across the resistor due to current) in the chip. Additionally, an incorporation of M2 level on the back-side of the semiconductor structure and higher back-side metal layers can strengthen the power mesh, minimizing the voltage drop across the Vss node in SRAM, enhancing overall efficiency and stability. Furthermore, chip Bump Pads can be located on the back-side of the semiconductor structure. The chip bump pads can facilitate the connection of power mesh conductors (e.g., Vdd and Vss) to bond pads, reducing the IR drop, and thus maintaining a stable and efficient power supply across the chip.

In the front-side of the semiconductor structure (see FIG. 3A), the M1 level (or layer) can be dedicated to housing the bit-line BL/complementary bit line BLB, and search Line SL, complementary search line SLB, which in turn allows for the enlargement of metal width, resulting in lower resistance, or further scaling down of the X-pitch of the cell. Therefore, minimum voltage required for writing to the cell (i.e., write V_min) can be enhanced and the cell size can be reduced. Additionally, the match line contact MLC can be positioned at the cell boundary on the M1 level (or layer) and can be shared with an adjacent cell, which in turn facilitates scaling of the X-pitch of the cell, optimizing space and enhancing the packing density and performance of the cell.

FIG. 3A an 3B illustrates six distinct active regions (e.g., semiconductive sheet 210 shown in FIGS. 3D, 3F, and 3G) formed in and/or on a substrate, such as a semiconductor substrate like bulk silicon, that are respective portions of the transistors PU-1, PU-2 PU-3, PU-4, PD-1, PD-2, PD-3, PD-4, PG-1, PG-2, PG-3, PG-4, SD-1, SD-2, DD-1, and DD-2. In other embodiments, there may be more or less active regions, which may be used to control a width of a transistor for current matching. The active regions in FIGS. 3A and 3B extend in the Y-direction, which also corresponds to a direction of current flow of the transistors during operation. The active regions depicted as crossing a boundary of the cell layout (illustrated by exterior dashed lines) may be shared by transistors of adjacent cells. FIGS. 3A and 3B further illustrate boundaries between a first conductivity type wells PW and a second conductivity type well NW having an opposite conductivity type to the first conductivity type wells PW. By way of example but not limiting the present disclosure, the first conductivity type wells PW can be p-doped wells PW, and the second conductivity type well NW can be n-doped well. In some embodiments, the first conductivity type wells PW can be n-doped wells, and the second conductivity type well NW can be p-doped well NW. The respective boundaries extend in a Y-direction. The first conductivity type transistors, as discussed in FIG. 2A, may be formed in the second conductivity type well NW, and second conductivity type transistors, as discussed in FIG. 2A, may be formed in the first conductivity type well PW.

A first one of the active regions (e.g., semiconductive sheet 210 shown in FIGS. 3D, 3F, and 3G) can form the source, channel, and drain regions of each of the transistors PD-1, PG-1, PG-3, and PD-3. A second one of the active regions can form the source, channel, and drain regions of the transistors PU-1 and PU-3. Third and fourth ones of the active regions can form the source, channel, and drain regions of each of the transistors PU-2 and PU-4, respectively, and may be substantially aligned along longitudinal axes thereof (e.g., in a Y-direction). A fifth one of the active region can form the source, channel, and drain regions of each of the transistors PG-2, PD-2, PD-4, and PG-4. A sixth one of the active region can form the source, channel, and drain regions of each of the transistors SD-1, DD-1, DD-2, and SD-2. In some embodiments, the formation process of the transistors SD-1, DD-1, DD-2, and SD-2 may be different than the formation process of the transistors PD-1, PD-2, PD-3, PD-4, PG-1, PG-2, PG-3, and PG-4, such that, for example, a threshold voltage of the transistor PD-2 may be higher than a threshold voltage of the transistor DD-1, such as the difference being larger than 30 mV.

FIGS. 3A and 3B further illustrate distinct gate structures G1, which may include a gate dielectric layer 231 (see FIGS. 3D, 3F and 3G) with a gate electrode layer 232 (see FIGS. 3D, 3F and 3G), such as doped polysilicon, a metal, and/or silicide, thereover. As depicted in FIGS. 3A and 3B, the gate structures G1 extend in the X-direction. The transistors PD-1 and PU-1 can share a common gate structure over respective channel regions of the transistors PD-1 and PU-1. The transistor PG-1 can have a gate structure G1 over its channel region, and the gate structure G1 may be shared by another transistor in an adjacent cell. The transistor PG-3 can have a gate structure G1 over its channel region, and the gate structure G1 may be shared by another transistor in an adjacent cell. The transistors PD-3 and PU-3 can share a common gate structure G1 over respective channel regions of the transistors PD-3 and PU-3. The transistors PU-2, PD-2, and DD-1 can share a common gate structure G1 over respective channel regions of the transistors PU-2, PD-2, and DD-1. The transistors PU-4, PD-4, and DD-2 can share a common gate structure G1 over respective channel regions of the transistors PU-4, PD-4, and DD-2. Transistor PG-2 can have a gate structure G1 over its channel region, and the transistor PG-4 can have a gate structure G1 over its channel region. The transistor SD-1 can have a gate structure G1 over its channel region, and the transistor SD-2 can have a gate structure G1 over its channel region.

FIGS. 3A and 3B further illustrate various contacts and meal layers formed to components in the cell. The contacts and meal layers may be formed in a front-side lower-most dielectric layer(s) and/or in a back-side lower-most dielectric layer(s), such as a front-side inter-layer dielectric (ILD) and/or a back-side inter-layer dielectric (ILD), with a conductive material, such as a metal with or without a barrier layer. As shown in FIGS. 3A and 3B, the lower-level metal layers, such as Vss, can be place to the back-side of the wafer (see FIG. 3B). This placement can not only facilitate further scaling by freeing up space on the front-side but also help reduce parasitic capacitance and improve overall device integrity. The match line contact MLC can be placed to the front-side of the wafer (see FIG. 3A) and can be located at the cell boundaries and can be shared with adjacent cells, enhancing the electrical performance and reliability of the device. This layout of data and search devices can minimize resistance for maintaining high performance and efficiency, as device dimensions continue to shrink.

Specifically, in FIG. 3A, a storage node contact SN1 can couple together the drain of the transistor PD-1, a source/drain region of the transistor PG-1, the drain of the transistor PU-1, and the common gate structure for the transistors PU-2, PD-2, and DD-1. The storage node contact SN1 may comprise a butted contact (see FIGS. 3D-3F) between the active region of the transistor PU-1 and the common gate structure for the transistors PU-2, PD-2, and DD-1. A storage node contact SN2 can couple together the drain of the transistor PD-3, a source/drain region of the transistor PG-3, the drain of the transistor PU-3, and the common gate structure for the transistors PU-4, PD-4, and DD-2. The storage node contact SN2 may comprise a butted contact (see FIGS. 3D-3F) between the active region of the transistor PU-3 and the common gate structure for the transistors PU-4, PD-4, and DD-2. In some embodiments, the storage node contacts SN1 and SN2 can be interchangeably referred to source/drain contacts, front-side contacts, or landing pads.

A complementary storage node contact SNB1 can couple together the drain of the transistor PD-2, a source/drain region of the transistor PG-2, the drain of transistor PU-2, and the common gate structure for the transistors PU-1 and PD-1. The complementary storage node contact SNB1 may comprise a butted contact 241 (see FIGS. 3D-3F) between the active region of the transistor PU-2 and the common gate structure for the transistors PU-1 and PD-1. A complementary storage node contact SNB2 can couple together the drain of the transistor PD-4, a source/drain region of the transistor PG-4, the drain of the transistor PU-4, and the common gate structure for the transistors PU-3 and PD-3. The complementary storage node contact SNB2 may comprise a butted contact (see FIGS. 3D-3F) between the active region of the transistor PU-4 and the common gate structure for the transistors PU-3 and PD-3. In some embodiments, the complementary storage node contacts SNB1 and SNB2 can be interchangeably referred to source/drain contacts, front-side contacts, or landing pads.

As shown in FIG. 3A, metal lines disposed at the M1 level on the front-side of the semiconductor structure may include a bit line BL, a complementary bit line BLB, a search line SL, a complementary search line SLB, metal lines M1, and metal lines disposed at the M2 level on the front-side of the semiconductor structure may include a match line ML, and word lines WL1 and WL2. In some embodiments, the lines can be interchangeably referred to metal layers, conductive lines, conductive layers, or conductors. The metal lines disposed at the M1 level on the front-side of the semiconductor structure may have lengthwise directions parallel to the Y-direction (e.g., column direction), and the metal lines disposed at the M2 level on the front-side of the semiconductor structure may have lengthwise directions parallel to the X-direction (e.g., row direction) substantially perpendicular to the Y-direction. In some embodiments, the semiconductor structure can allow for varying levels of metal lines on the front-side. Metal lines such as bit lines, complementary bit lines, search lines, complementary search line contacts, metal lines, match lines, and word lines can be placed at any appropriate level within the front-side structure.

Specifically, as shown in FIG. 3A, a bit line contact BLC1 can be electrically coupled to a source/drain region of the transistor PG-1, a bit line contact BLC2 can be electrically coupled to a source/drain region of the transistor PG-3, and a complementary bit line contact BLBC can be electrically coupled to a source/drain region of the transistors PG-2 and PG-4. The bit line BL can be electrically connected to the bit line contacts BLC1 and BLC2, respectively, through underlying metal vias 242. The complementary bit line BLB can be electrically connected to the complementary bit line contact BLBC through the underlying metal via 242. In some embodiments, the bit line contacts BLC1 and BLC2 and the complementary bit line contact BLBC can be interchangeably referred to source/drain contacts, front-side contacts, or landing pads, the bit line BL and the complementary bit line BLB can be interchangeably referred to conductors, and the metal vias 242 can be interchangeably referred to source/drain vias or front-side vias.

As shown in FIG. 3A, a search line contact SLC can be electrically coupled to the gate structure of transistor SD-1, and a complementary search line contact SLBC (or search line bar contact) can be coupled to the gate structure of the transistor SD-2. The search line SL and the complementary search line SLB (or search line bar) can be electrically connected to the underlying search line contact SLC and the underlying complementary search line contact SLBC, respectively. In some embodiments, the search line SL and the complementary search line SLB can be interchangeably referred to conductors, and the search line contact SLC and the complementary search line contact SLBC can be interchangeably referred to gate contacts or gate vias.

As shown in FIG. 3A, a match line contact MLC can be electrically coupled to a source/drain region of transistors SD-1 and SD-2. The match line ML can be electrically connected to the match line contact MLC through the underlying metal via 244, metal line M1, and metal via 242. The match line contact MLC can be located at the cell boundaries and can be shared with adjacent cells, optimizing the integration within the chip layout and reducing resistance at the junctions, which in turn allows for enhancing the electrical performance and reliability of the device. In In some embodiments, the match line ML can be interchangeably referred to a conductor, and the match line contact MLC can be interchangeably referred to a source/drain contact, a front-side contact, or a landing pad.

As shown in FIG. 3A, a word line contact WLC1 can be electrically coupled to the gate structure of the transistor PG-1, a word line contact WLC2 can be coupled to a gate structure of transistor PG-2, word line contact WLC3 can be coupled to the gate structure of transistor PG-3, and a word line contact WLC4 can be coupled to a gate structure of transistor PG-4. The word line WL1 can be electrically connected to the word line contacts WLC1 and WLC2 through the underlying metal vias 244 and metal lines M1, and the word line WL2 can be electrically connected to the word line contacts WLC3 and WLC2 through the underlying metal vias 244 and metal lines M1. In some embodiments, the word lines WL1 and WL2 and can be interchangeably referred to a conductors, and the word line contacts WLC1, WLC2, WLC3, and WLC4 can be interchangeably referred to gate contacts, gate vias, front-side contacts, or front-side vias.

As shown in FIG. 3B, metal lines disposed at the M1 level on the back-side of the semiconductor structure may include power supply voltage line VSS1, VSS2, and VDD, and metal lines disposed at the M2 level on the back-side of the semiconductor structure may include a power supply voltage line VSS3. The metal lines disposed at the M1 level on the back-side of the semiconductor structure may have lengthwise directions parallel to the Y-direction (e.g., column direction), and the metal lines disposed at the M2 level on the back-side of the semiconductor structure may have lengthwise directions parallel to the X-direction (e.g., row direction) substantially perpendicular to the Y-direction. In some embodiments, the semiconductor structure can allow for varying levels of metal lines on the back-side. Metal lines such as power supply voltage lines can be placed at any appropriate level within the back-side structure.

As shown in FIG. 3B, a power supply voltage contact VSSC1 can be coupled to a source region of the transistors PD-1 and PD-3, a power supply voltage contact VSSC2 can be coupled to a source region of transistor PD-2, a power supply voltage contact VSSC3 can be coupled to a source region of transistor PD-4, a power supply voltage contact VSSC4 can be coupled to a source region of transistor DD-1, and a power supply voltage contact VSSC5 can be coupled to a source region of transistor DD-2. The power supply voltage line VSS1 can be electrically connected to the power supply voltage contact VSSC1, and the power supply voltage line VSS2 can be electrically connected to the power supply voltage contacts VSSC2, VSSC3, VSSC4, and VSSC5. The power supply voltage line VSS3 can be electrically connected to the power supply voltage lines VSS1 and VSS2 thorough the metal via 342. In some embodiments, the power supply voltage contacts VSSC2, VSSC3, VSSC4, and VSSC5 can be interchangeably referred to source/drain contacts or back-side contacts, and the metal via 342 can be interchangeably referred to a back-side via or a back-side contact.

As shown in FIG. 3B, a power supply voltage contact VDDC1 can be coupled to a source region of the transistors PU-1 and PU-3, a power supply voltage contact VDDC2 can be coupled to a source region of transistor PU-2, and a power supply voltage contact VDDC3 can be coupled to a source region of transistor PU-4. The power supply voltage line VDD can be electrically connected to the power supply voltage contacts VDDC1, VDDC2, and VDDC3. In some embodiments, the power supply voltage lines VSS1, VSS2, VSS3, and VDD disposed at the M1 level and M2 level can be interchangeably referred to power supply voltage landing pads. power supply voltage landing lines, or conductors. In some embodiments, the power supply voltage contacts VDDC1, VDDC2, and VDDC3 can be interchangeably referred to source/drain contacts or back-side contacts, and the power supply voltage lines VSS1 and VSS2 and can be interchangeably referred to a conductor.

As shown in FIGS. 3C-3H, second semiconductive sheets 210 (see FIG. 3D) can be formed over fins 52 (see FIG. 3D). A shallow trench isolation (STI) structures 251 (see FIGS. 3C-3E and 3H) can be formed around at least a portion of the fin 52. In some embodiments, the top surfaces of the STI structures 251 can be coplanar (within process variations) with the top surfaces of the fins 52. In some embodiments, the top surfaces of the STI structures 251 are above or below the top surfaces of the fins 52. The STI structures 251 can separate the features of adjacent devices.

As shown in FIGS. 3C-3H, gate spacers 233 (see FIGS. 3F and 3G) can be formed over on opposite sidewalls of the gate structure G1 (see FIGS. 3F and 3G). In some embodiments, the gate spacers 233 can be interchangeably referred to top/upper spacers. Inner spacers 236 (see FIGS. 3F and 3G) are formed to act as isolation features between the source/drain regions and the gate structures G1. In some embodiments, the inner spacers 236 can be interchangeably referred to lower gate spacers. Moreover, although the sidewalls of the inner spacers 236 are illustrated as being straight, the sidewalls of the inner spacers 236 may be concave or convex. Epitaxial source/drain regions 218 (see FIGS. 3E-3G) can be formed, such that each gate structures G1 (and corresponding channel regions) can be disposed between respective adjacent pairs of the epitaxial source/drain regions 218. In some embodiments, the gate spacers 233 and the inner spacers 236 are used to separate the epitaxial source/drain regions 218 from, respectively, the gate structures G1 by an appropriate lateral distance so that the epitaxial source/drain regions 218 do not short out with subsequently formed gates of the resulting nano-FETs. In some embodiments, front-side silicide layers 270 (see FIGS. 3F and 3G) can be formed between the source/drain contacts and the source/drain regions 218. In some embodiments, a hard mask layer 235 (see FIGS. 3D, 3F, and 3G) can be formed over the gate electrode layers 232 and the gate dielectric layer 231, such that source/drain contacts can be formed by a self-aligned contact process using the hard mask layer 235 as a contact etch protection layer.

As shown in FIGS. 3A, 3B, and 3D, dielectric regions 227 can be formed on opposite ends of the gate structure G1. In some embodiments, each dielectric region 227 can be a gate-cut structure for the gate structure G1, and the gate-cut structure is formed by a cut metal gate (CMG) process. In some embodiments, the dielectric region 227 can be interchangeably referred to a gate end dielectric. As shown in FIGS. 3A, 3B, and 3H, the gate electrode layers 232 and the gate dielectric layer 231 on the boundary of the circuit region can be removed to form an isolation region 228 separating the source/drain regions of neighboring semiconductor devices from each other and separate different semiconductor devices.

As shown in FIGS. 3C-3H, an inter-layer dielectric (ILD) layer 260 can be deposited over the epitaxial source/drain regions 218, the gate spacers 233, and the gate structures G1. An ILD layer 262 can be deposited over the ILD layer 260. The metal vias 242 can be formed in the ILD layer 262 and land on the source/drain contacts. A back-side dielectric layer 331 can be formed over a back-side surface of the STI structure 251 and a back-side surface of the fin 52, such that back-side contacts (e.g., power supply voltage contacts VSSC2, VSSC3, VSSC4, VSSC5, VDDC1, VDDC2, and VDDC3 as shown in FIG. 3B) can be formed in the back-side dielectric layer 331 and over the source/drain regions 218.

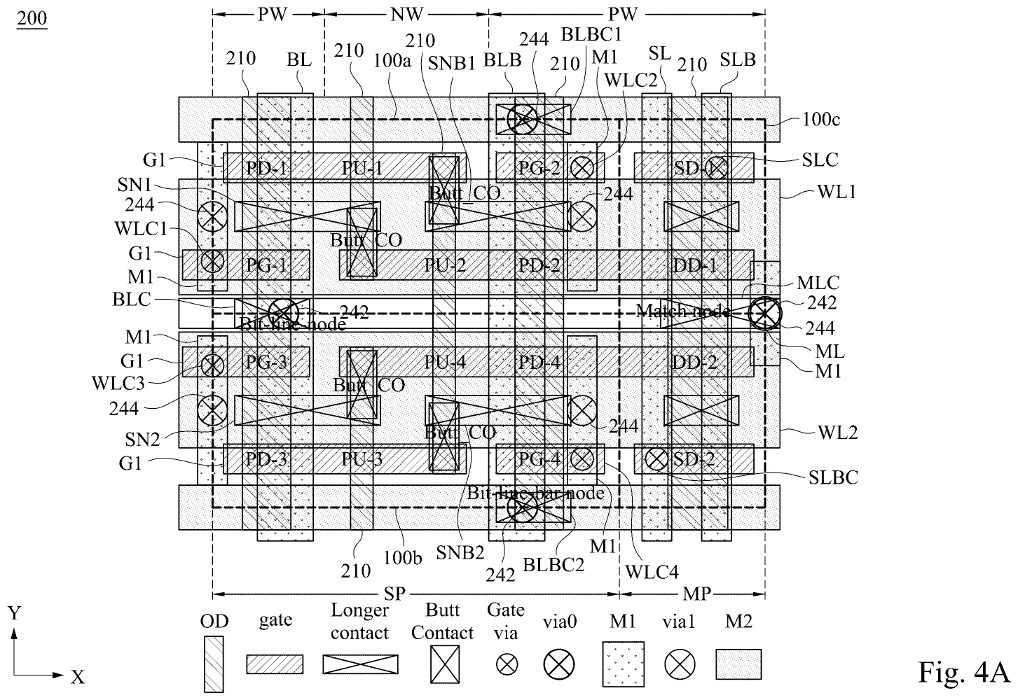

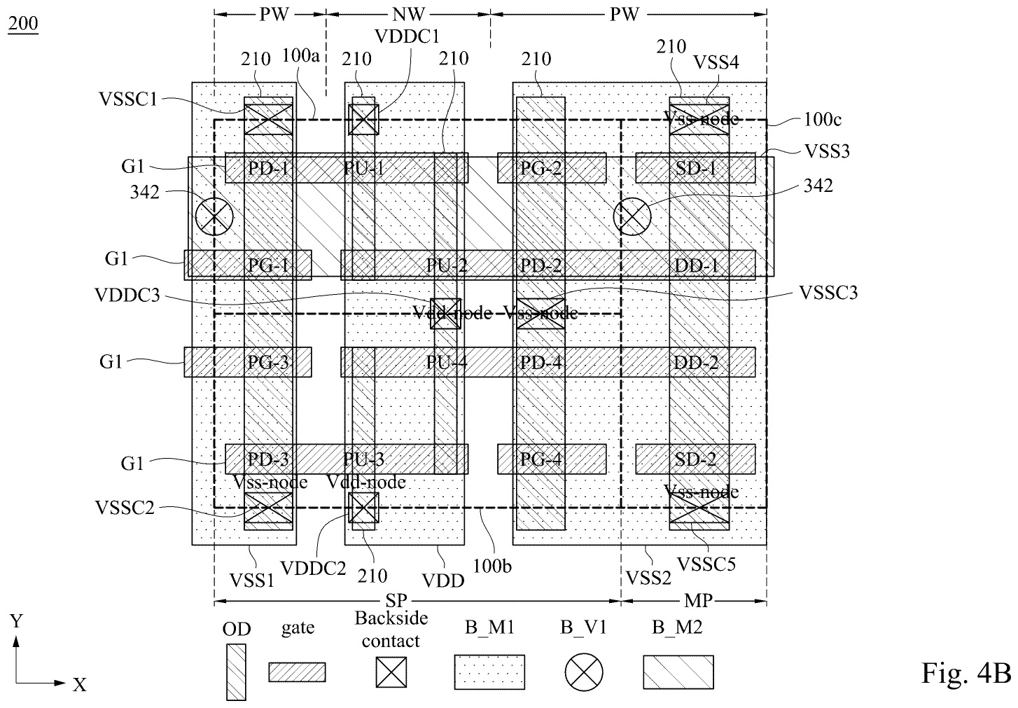

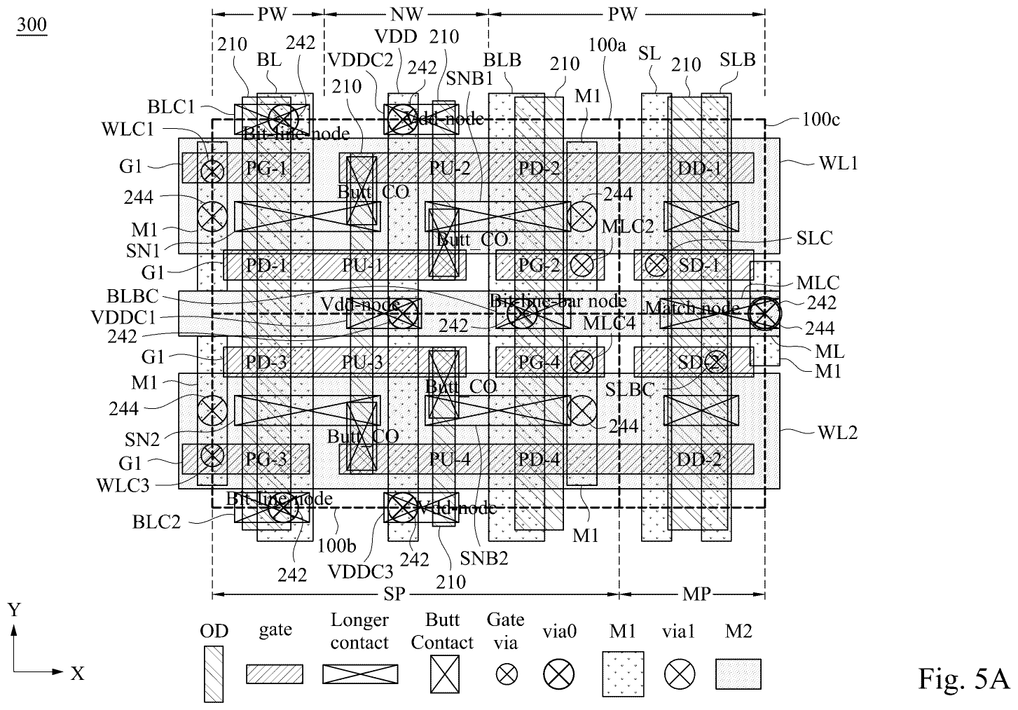

Reference is made to FIGS. 2B, 4A and 4B. FIG. 2B is a circuit diagram of a memory cell 200, such as a TCAM cell, in accordance with some embodiments of the present disclosure. FIGS. 4A and 4B illustrate layout diagrams of the memory cell 200 on a front side and a back side of a semiconductor structure, respectively, according to some embodiments of the present disclosure. While FIGS. 2B, 4A, and 4B show embodiments of the memory cell 200b with different circuit profile and layout profiles than the those in FIGS. 2A, 3A, and 3B. In addition, the present disclosure may repeat reference numerals and/or letters in the various examples. This repetition is for the purpose of simplicity and clarity and does not in itself dictate a relationship between the various embodiments and/or configurations discussed.

Specifically, the distinction between the memory cell 200 as illustrated in FIGS. 2B, 4A, and 4B and the memory cell 100 as illustrated in FIGS. 2A, 3A, and 3B can revolve around the electrical connections of the search gate transistors SD-1 and SD-2 and data gate transistors DD-1 and DD-2. The sources of the search gate transistors SD-1 and SD-2 in the memory cell 200 are coupled to the ground voltage Vss. In some embodiments, this setup can stabilize the operation of the search gates by providing a consistent low potential for the search operation within a ternary content addressable memory (TCAM) setting. The drains of the data gate transistors DD-1 and DD-2 can be coupled to the match line ML. In some embodiments, this setup can facilitate the matching function in TCAM cells, where the match line can carry the output signal indicating whether the searched data matches the stored data.

As shown in FIG. 2B, the storage port SP of the circuit diagram of FIG. 2B is configured in the same manner as the storage port SP of the circuit diagram of FIG. 2A. A match port MP of the memory cell is cascaded from the storage port SP. A source of the search gate transistor SD-1 can be coupled to the ground voltage Vss. A drain of the search gate transistor SD-1 can be coupled to a source of the data gate transistor DD-1. A drain of the data gate transistor DD-1 can be coupled (adjacent) to a match line ML. A gate of the search gate transistor SD-1 can be coupled to a search line SL, and a gate of the data gate transistor DD-1 can be coupled to the first storage node SN1. A source of the search gate transistor SD-2 can be coupled to a ground voltage Vss. A drain of the search gate transistor SD-2 can be coupled to a source of the data gate transistor DD-2. A drain of the data gate transistor DD-2 can be coupled (adjacent) to the match line ML. A gate of the search gate transistor SD-2 is coupled to a complementary search line SLB, and a gate of the data gate transistor DD-2 is coupled to the second storage node SN2.

As shown in FIG. 4A, a bit line contact BLC can be electrically coupled to a source/drain region of the transistors PG-1 and PG-3, a complementary bit line contact BLBC1 (or bit line bar contact) can be electrically coupled to a source/drain region of the transistor PG-2, and a complementary bit line contact BLBC2 (or bit line bar) can be electrically coupled to a source/drain region of the transistor PG-4. The bit line BL can be electrically connected to the bit line contact BLC through underlying metal vias 242. The complementary bit line BLB can be electrically connected to the complementary bit line contacts BLBC1 and BLBC2 through the underlying metal vias 242. In some embodiments, the bit line contact BLC and the complementary bit line contacts BLBC1 and BLBC2 can be interchangeably referred to source/drain contacts or front-side contacts. A match line contact MLC can be electrically coupled to a source/drain region of transistors DD-1 and DD-2. The match line ML can be electrically connected to the match line contact MLC through the underlying metal via 244, metal line M1, and metal via 242.

As shown in FIG. 4B, a power supply voltage contact VSSC1 can be coupled to a source/drain region of the transistors PD-1, a power supply voltage contact VSSC2 can be coupled to a source/drain region of the transistors PD-3, a power supply voltage contact VSSC3 can be coupled to a source/drain region of the transistors PD-2 and PD-4, a power supply voltage contact VSSC4 can be coupled to a source/drain region of the transistor SD-1, and a power supply voltage contact VSSC5 can be coupled to a source/drain region of the transistor SD-2. The power supply voltage line VSS1 can be electrically connected to the power supply voltage contacts VSSC1 and VSSC2, and the power supply voltage line VSS2 can be electrically connected to the power supply voltage contacts VSSC3, VSSC4, and VSSC5. The power supply voltage line VSS3 can be electrically connected to the power supply voltage lines VSS1 and VSS2 thorough the metal via 342. A power supply voltage contact VDDC1 can be coupled to a source/drain region of the transistors PU-1, a power supply voltage contact VDDC2 can be coupled to a source/drain region of the transistors PU-3, a power supply voltage contact VDDC3 can be coupled to a source/drain region of the transistors PU-2 and PU-4. The power supply voltage line VDD can be electrically connected to the power supply voltage contacts VDDC1, VDDC2, and VDDC3.

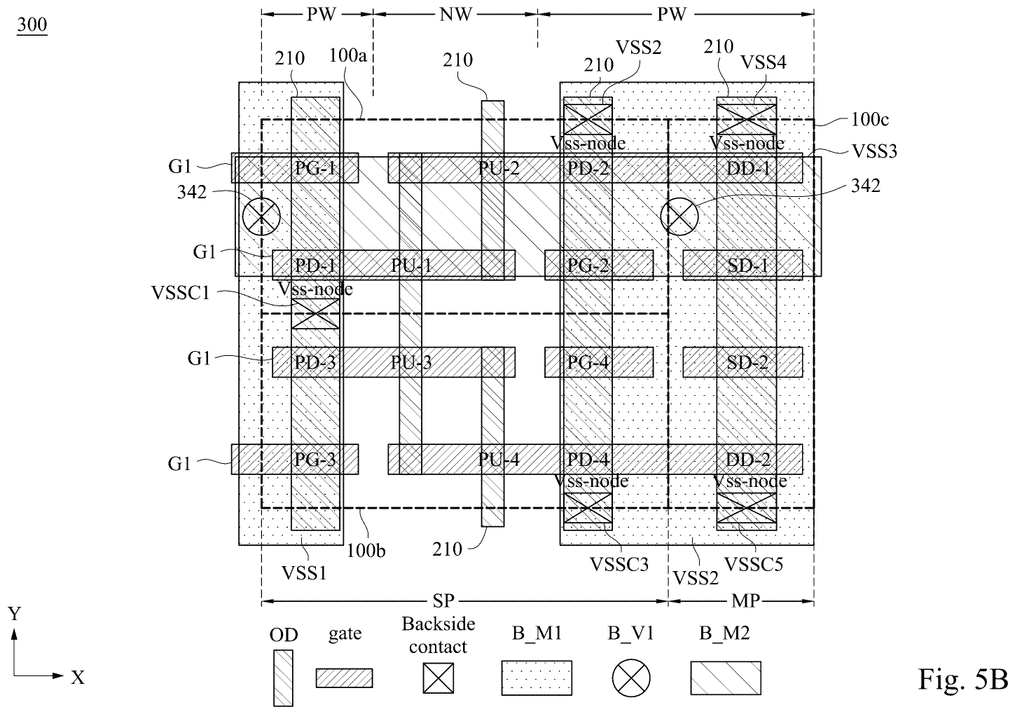

Reference is made to FIGS. 5A and 5B. FIGS. 5A and 5B illustrate layout diagrams of a memory cell 300, such as a TCAM cell, on a front side and a back side of a semiconductor structure, respectively, according to some embodiments of the present disclosure. While FIGS. 5A and 5B show an embodiment of the memory cell 300 with different layout profiles than the those in FIGS. 3A and 3B. In addition, the present disclosure may repeat reference numerals and/or letters in the various examples. This repetition is for the purpose of simplicity and clarity and does not in itself dictate a relationship between the various embodiments and/or configurations discussed.

Specifically, the distinction between the memory cell 300 as illustrated in FIGS. 5A and 5B and the memory cell 100 as illustrated in FIGS. 3A and 3B can revolve around the power supply configurations. In memory cell 300, the power supply voltage contacts VDDC1, VDDC2, and VDDC3 can be placed on the front-side of the semiconductor structure. The power supply voltage contacts VDDC1, VDDC2, and VDDC3 can be connected to the power supply voltage line VDD, located at the M1 level on the front-side of the semiconductor structure, via metal vias 242. The power supply voltage line VDD can be positioned between the bit line BL and the complementary bit line BLB.

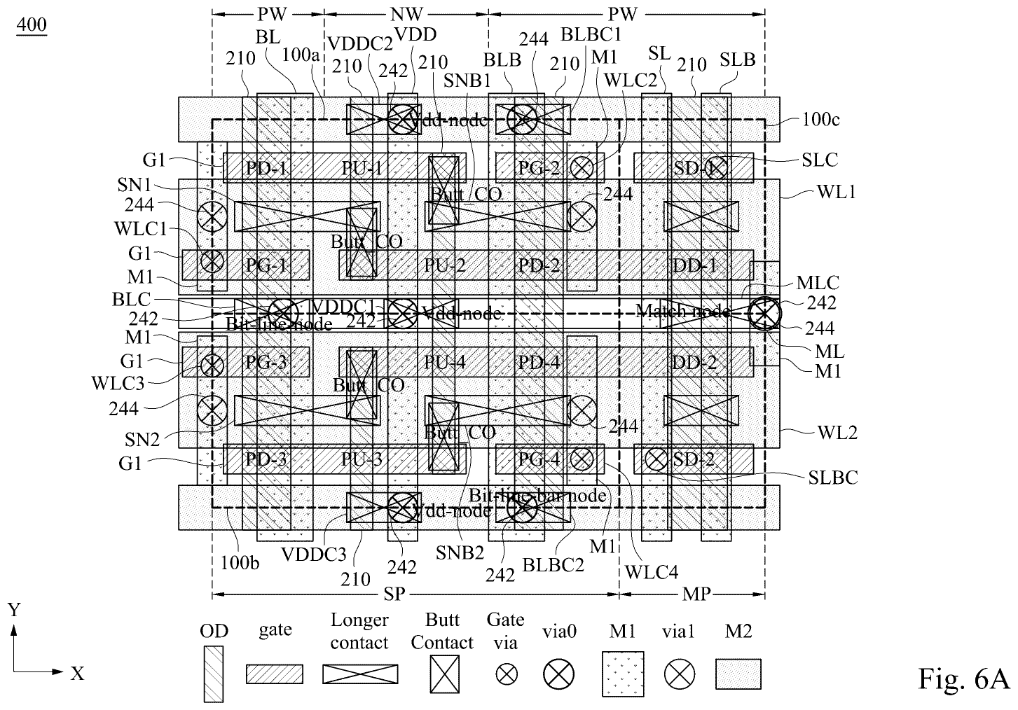

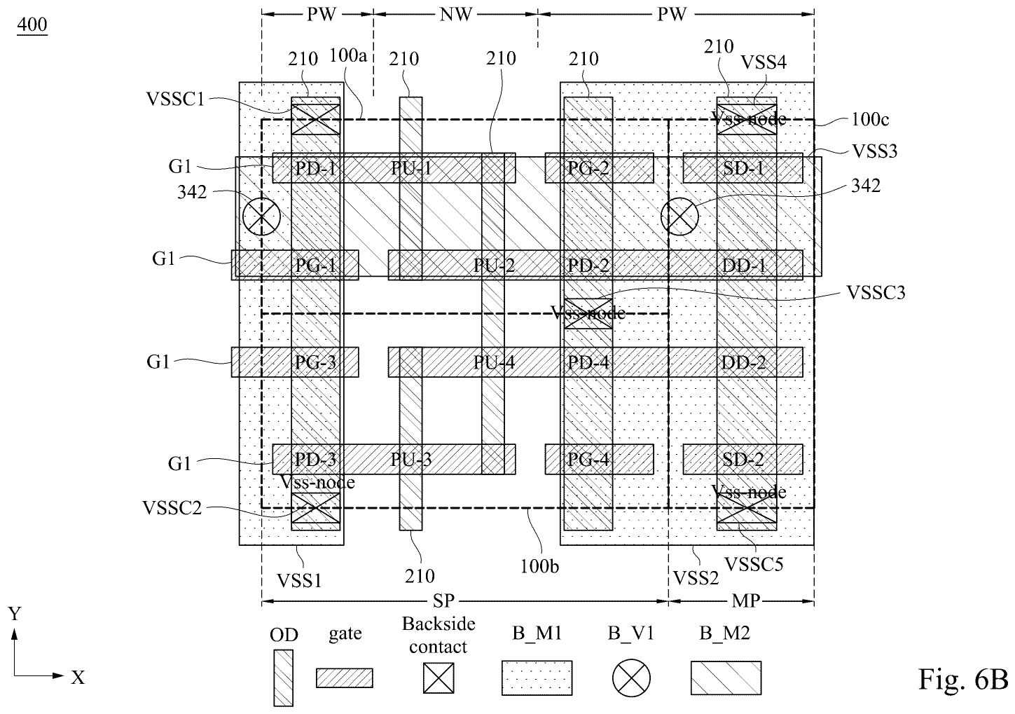

Reference is made to FIGS. 6A and 6B. FIGS. 6A and 6B illustrate layout diagrams of a memory cell 400, such as a TCAM cell, on a front side and a back side of a semiconductor structure, respectively, according to some embodiments of the present disclosure. While FIGS. 6A and 6B show an embodiment of the memory cell 400 with different layout profiles than the those in FIGS. 4A and 4B. In addition, the present disclosure may repeat reference numerals and/or letters in the various examples. This repetition is for the purpose of simplicity and clarity and does not in itself dictate a relationship between the various embodiments and/or configurations discussed.

Specifically, the distinction between the memory cell 400 as illustrated in FIGS. 6A and 6B and the memory cell 100 as illustrated in FIGS. 4A and 4B can revolve around the power supply configurations. In memory cell 400, the power supply voltage contacts VDDC1, VDDC2, and VDDC3 can be placed on the front-side of the semiconductor structure. The power supply voltage contacts VDDC1, VDDC2, and VDDC3 can be connected to the power supply voltage line VDD, located at the M1 level on the front-side of the semiconductor structure, via metal vias 242. The power supply voltage line VDD can be positioned between the bit line BL and the complementary bit line BLB.

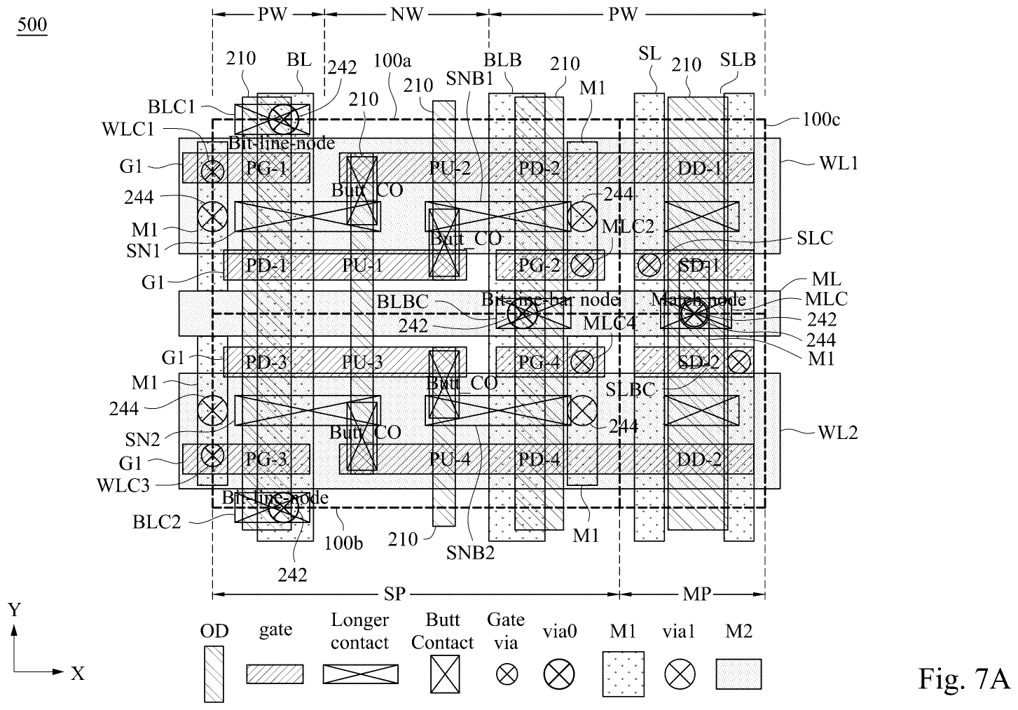

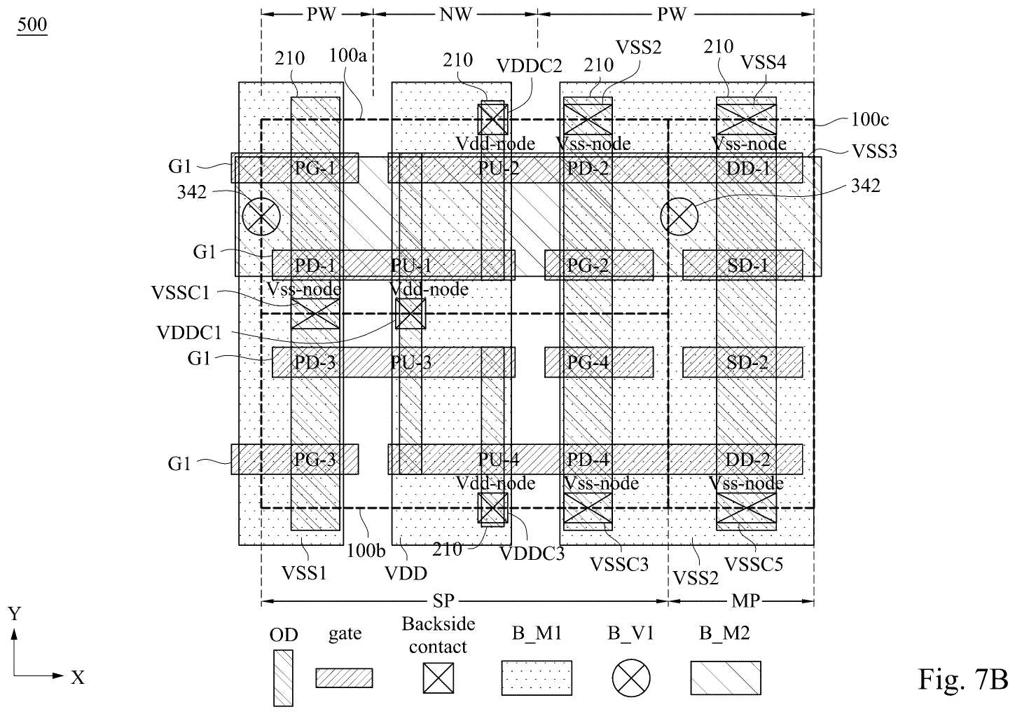

Reference is made to FIGS. 7A and 7B. FIGS. 7A and 7B illustrate layout diagrams of a memory cell 500, such as a TCAM cell, on a front side and a back side of a semiconductor structure, respectively, according to some embodiments of the present disclosure. While FIGS. 7A and 7B show an embodiment of the memory cell 500 with different layout profiles than the those in FIGS. 3A and 3B. In addition, the present disclosure may repeat reference numerals and/or letters in the various examples. This repetition is for the purpose of simplicity and clarity and does not in itself dictate a relationship between the various embodiments and/or configurations discussed.

Specifically, the distinction between the memory cell 500 as illustrated in FIGS. 7A and 7B and the memory cell 100 as illustrated in FIGS. 3A and 3B can revolve around the placement of the match line ML. In the memory cell 500, the match line ML can be positioned between the search line SL and the complementary search line SLB. In some embodiments, by placing the match line ML between the search line SL and the complementary search line SLB, the interference from the search operations to the match operations can be reduced. Additionally, this placement may also facilitate a more balanced and symmetrical distribution of electrical signals within the cell, which can improve signal integrity and reduce latency in accessing or writing data.

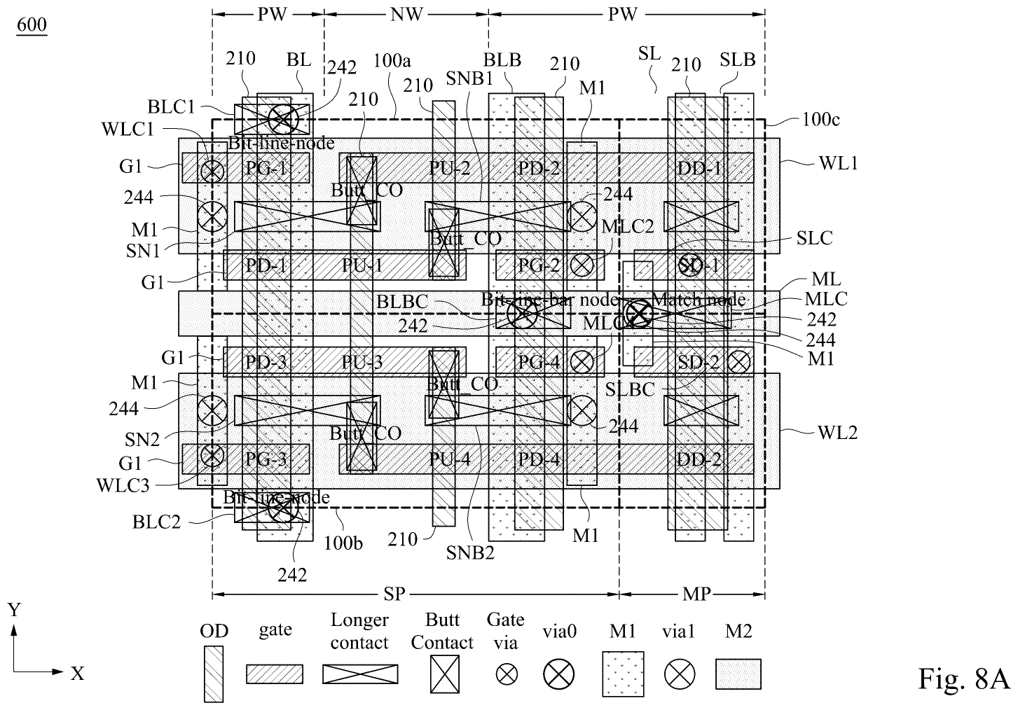

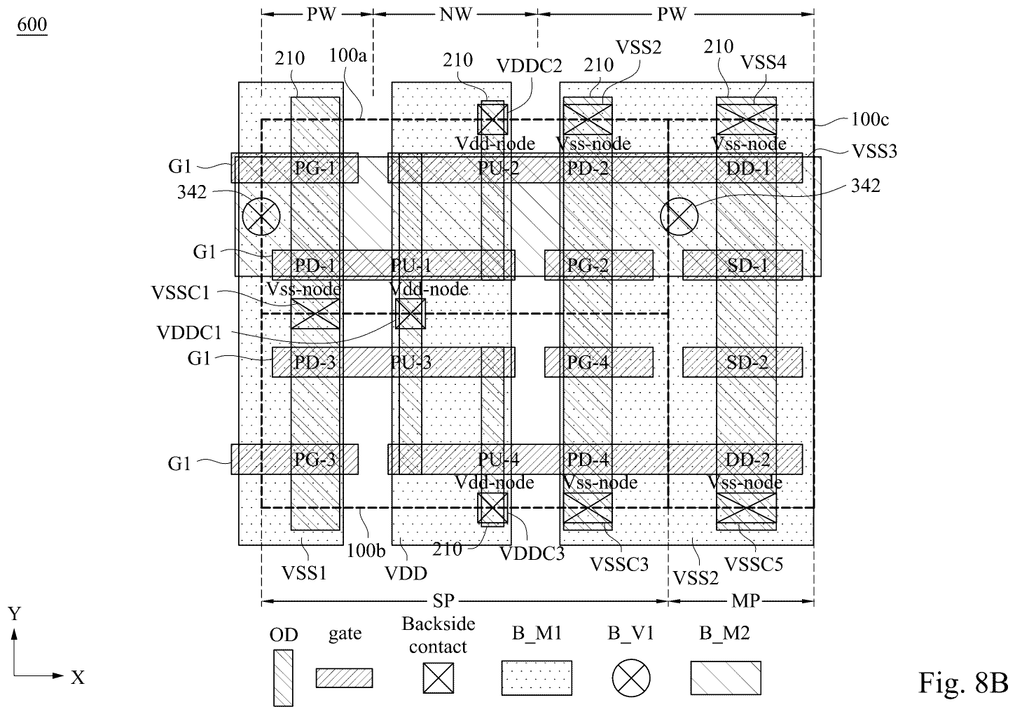

Reference is made to FIGS. 8A and 8B. FIGS. 8A and 8B illustrate layout diagrams of a memory cell 600, such as a TCAM cell, on a front side and a back side of a semiconductor structure, respectively, according to some embodiments of the present disclosure. While FIGS. 8A and 8B show an embodiment of the memory cell 600 with different layout profiles than the those in FIGS. 3A and 3B. In addition, the present disclosure may repeat reference numerals and/or letters in the various examples. This repetition is for the purpose of simplicity and clarity and does not in itself dictate a relationship between the various embodiments and/or configurations discussed.

Specifically, the distinction between the memory cell 600 as illustrated in FIGS. 8A and 8B and the memory cell 100 as illustrated in FIGS. 3A and 3B can revolve around the placement of the match line ML. In the memory cell 600, the match line ML can be positioned between the search line SL and the metal lines M1 that are connected to the word lines WL1 and WL2. In some embodiments, by placing the match line ML between the search line SL and the associated metal lines M1 may help in minimizing signal interference and crosstalk between these pathways.

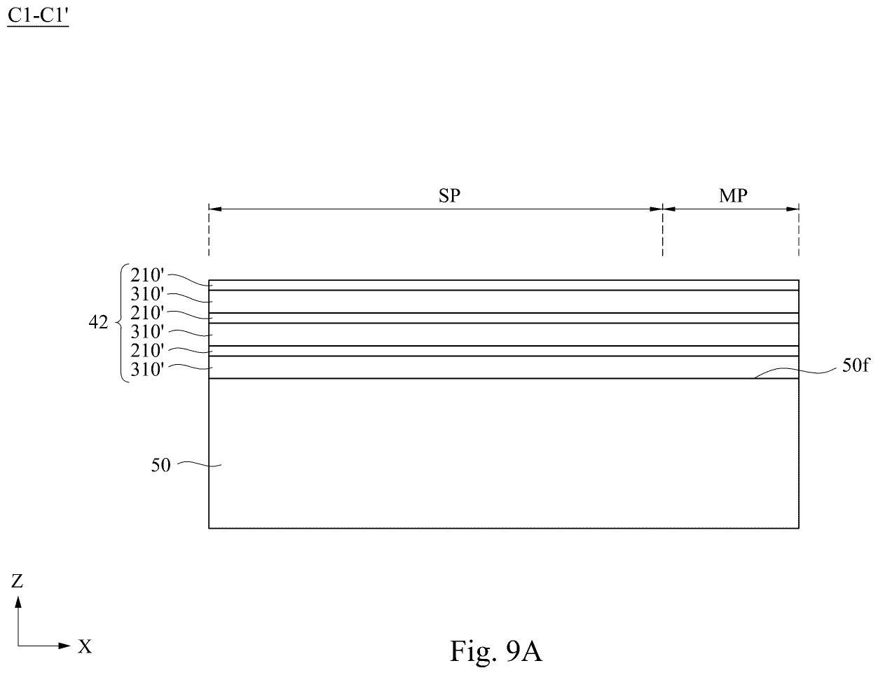

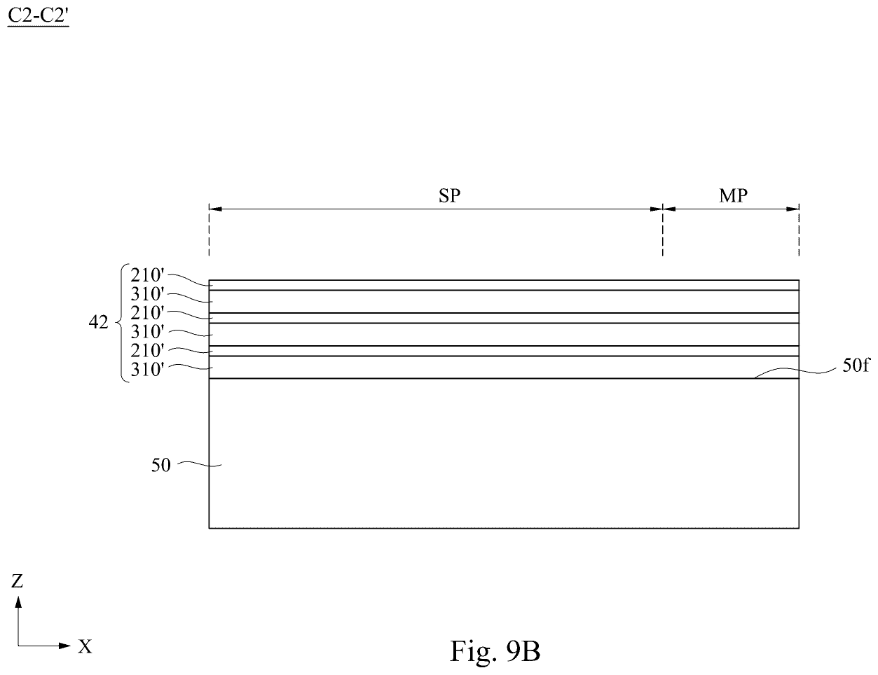

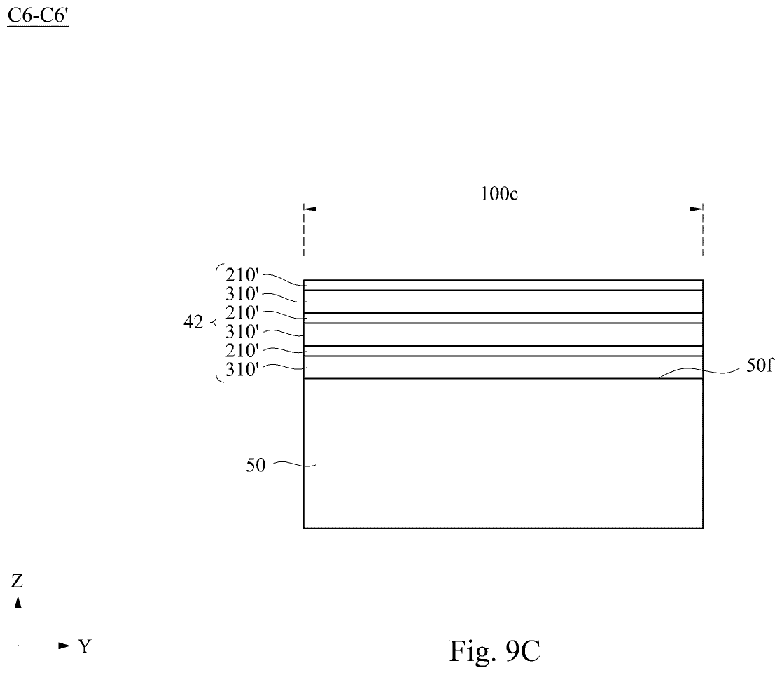

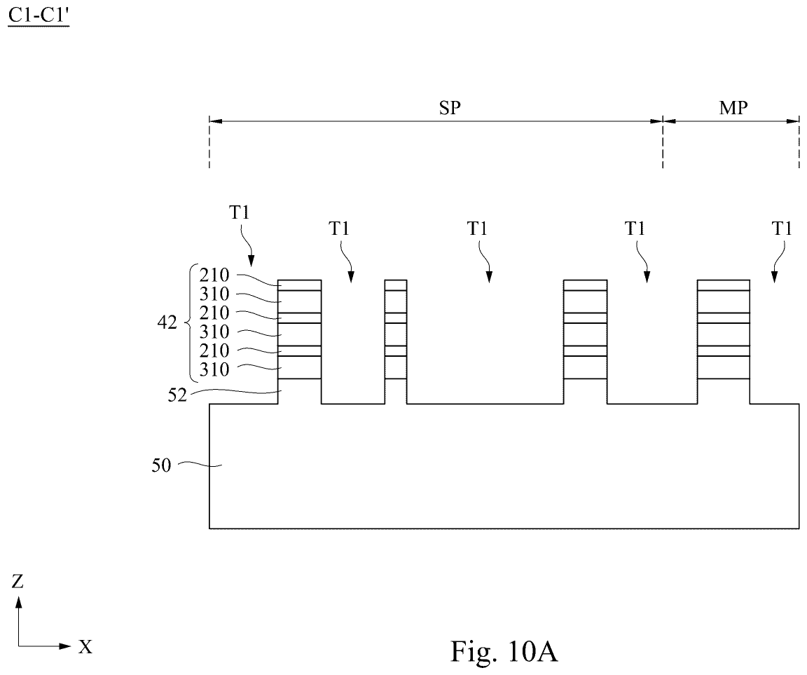

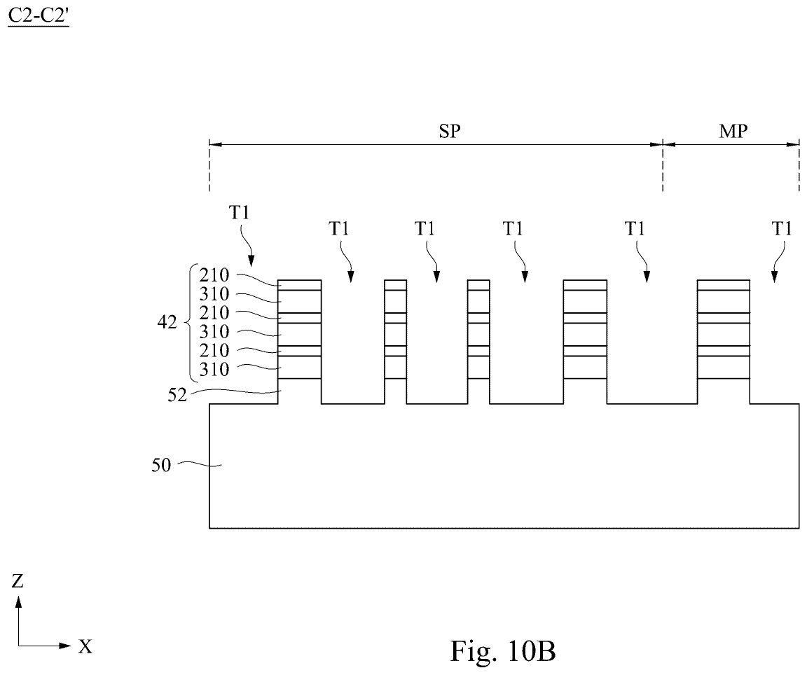

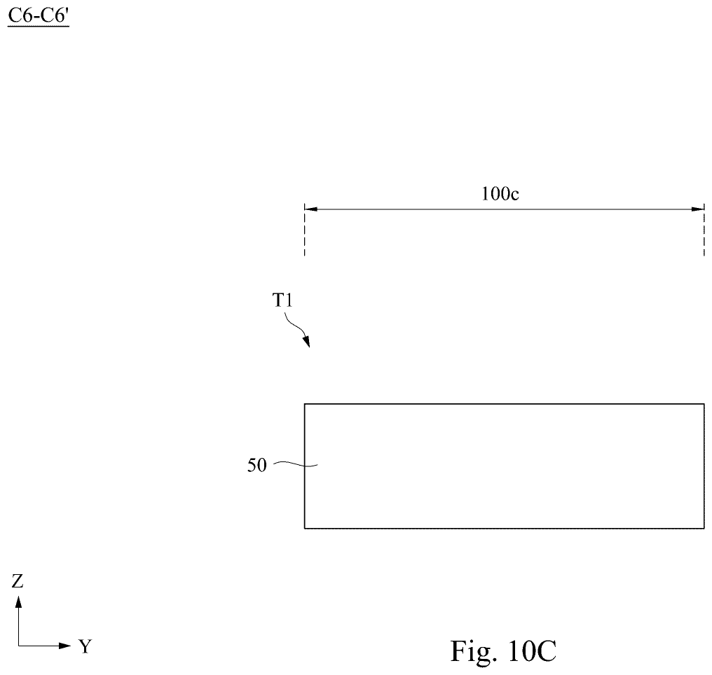

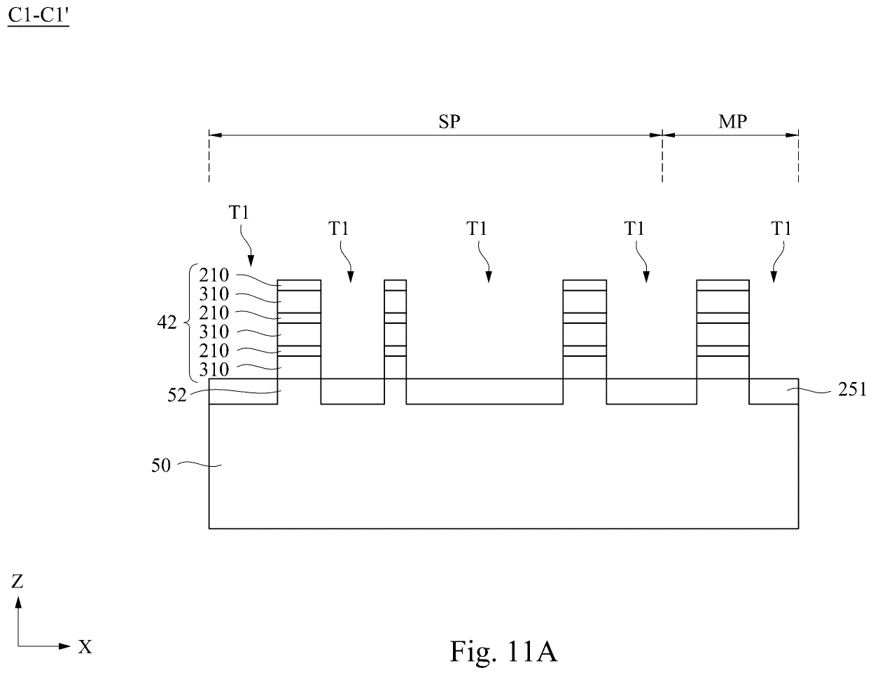

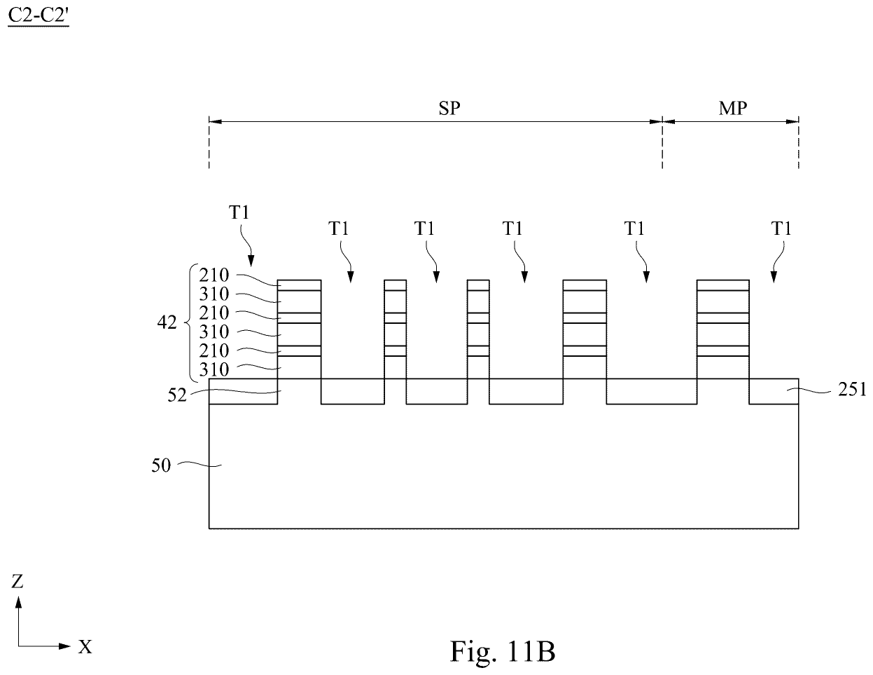

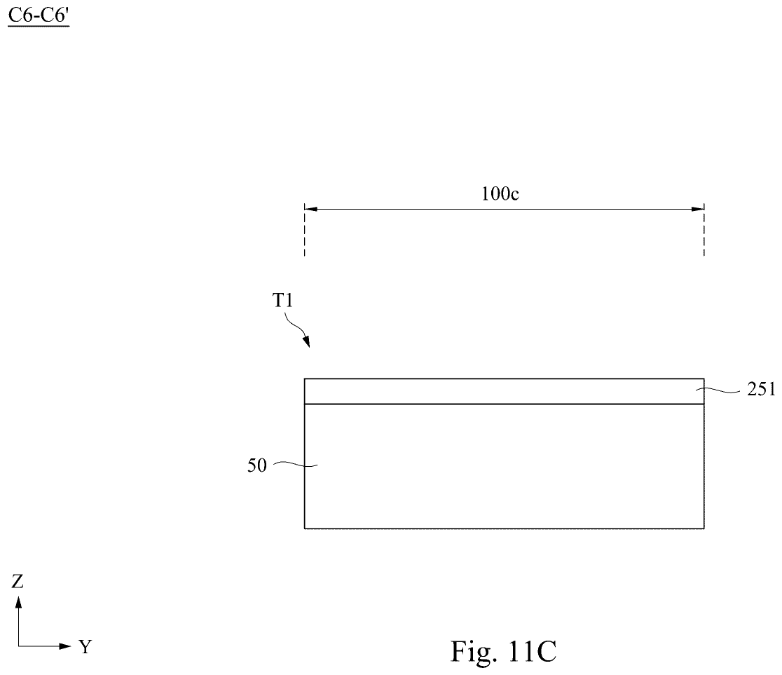

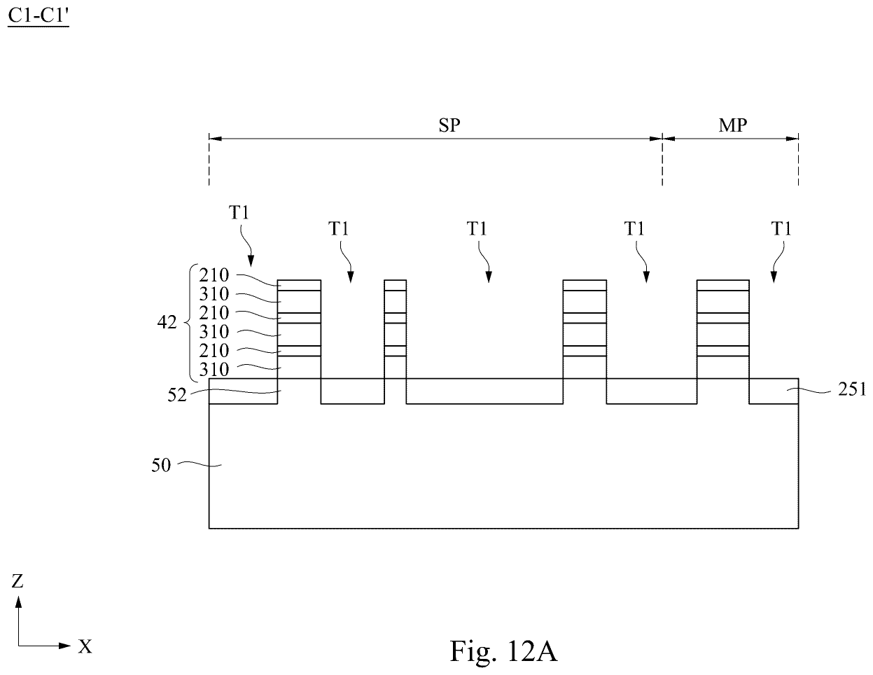

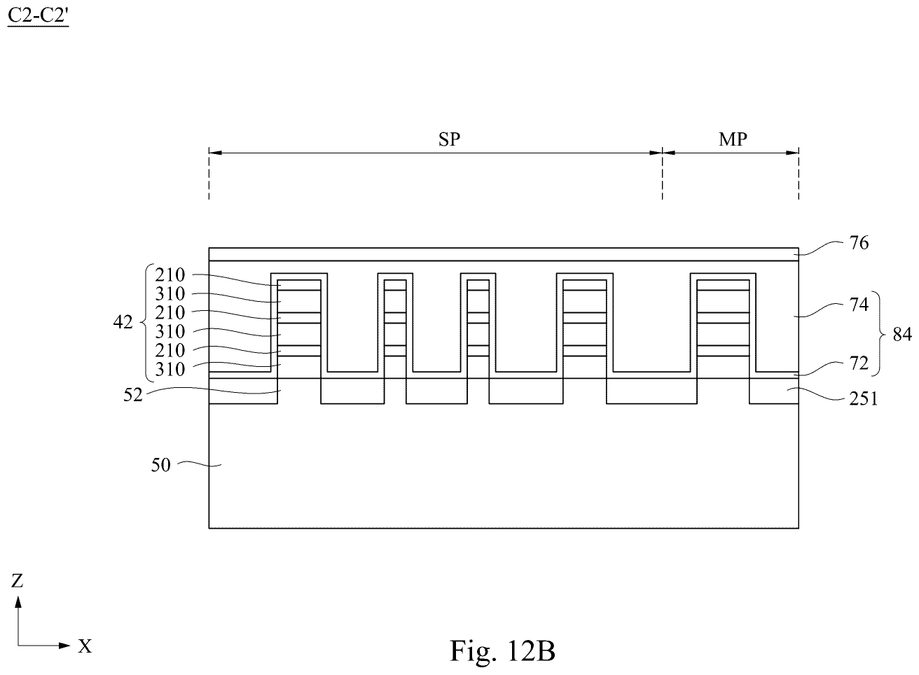

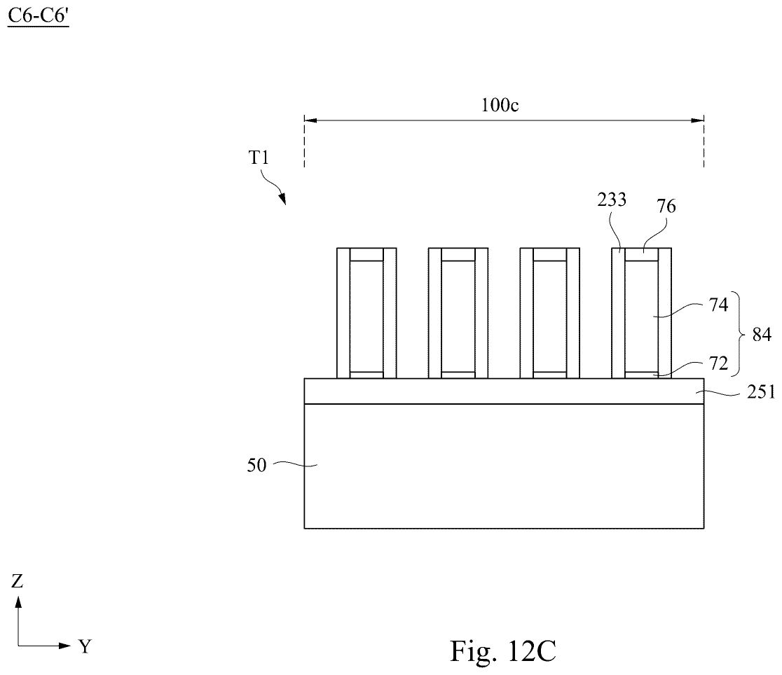

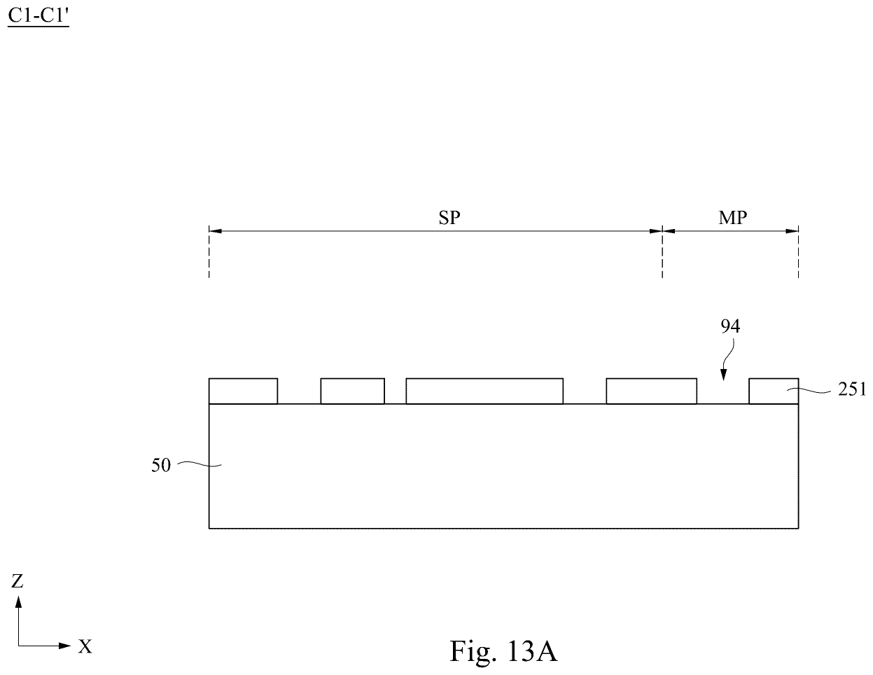

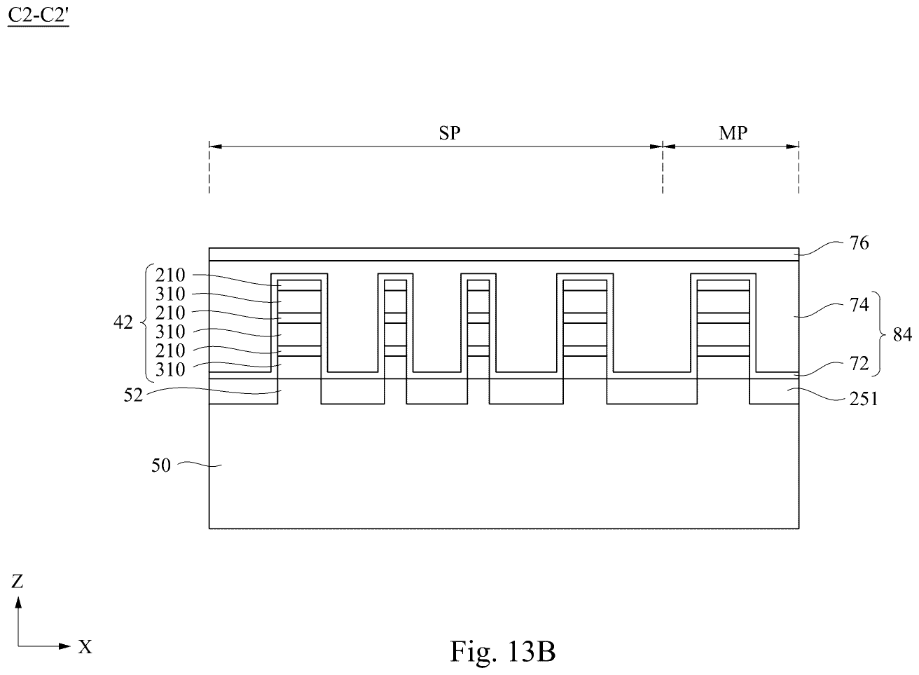

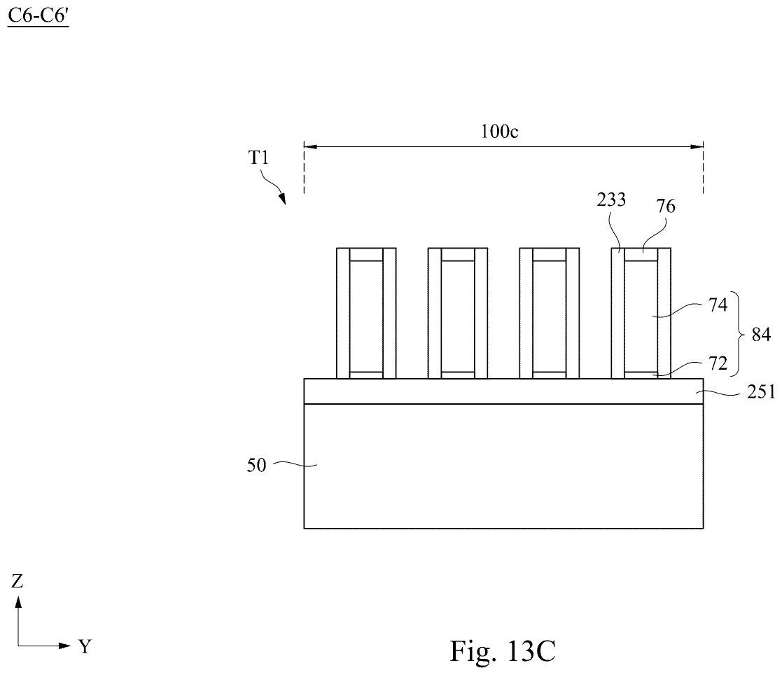

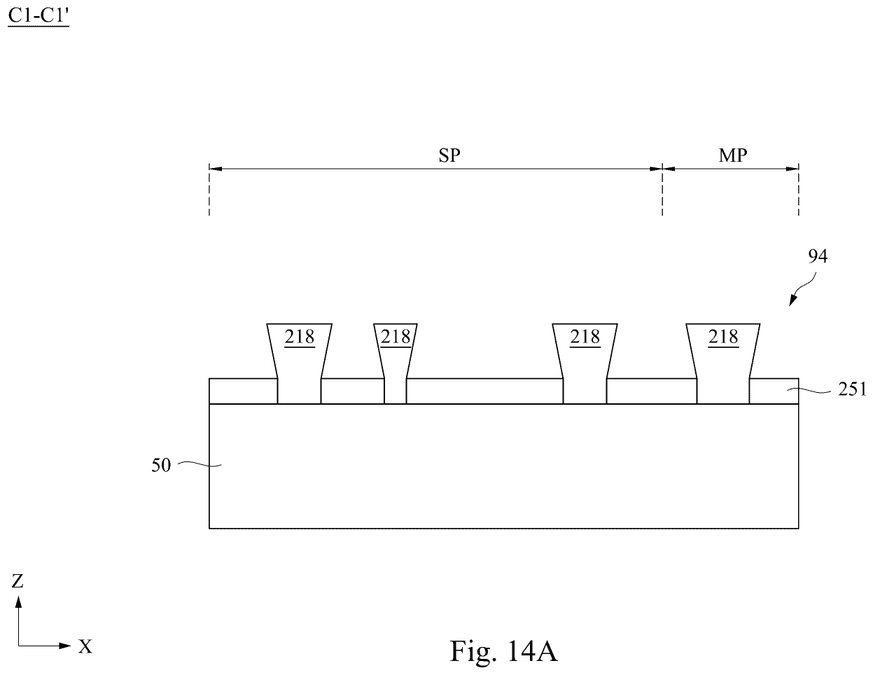

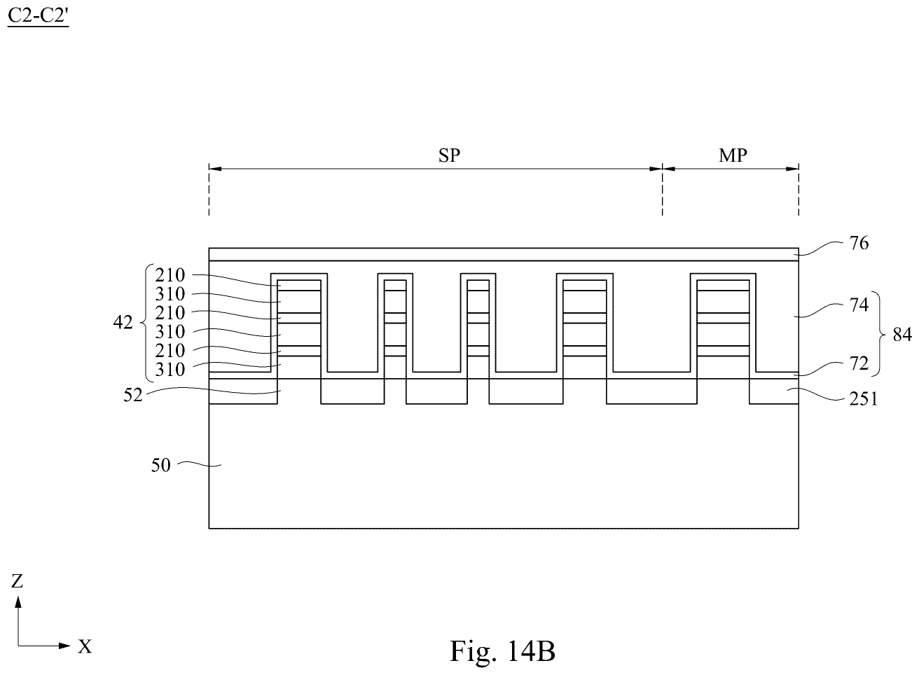

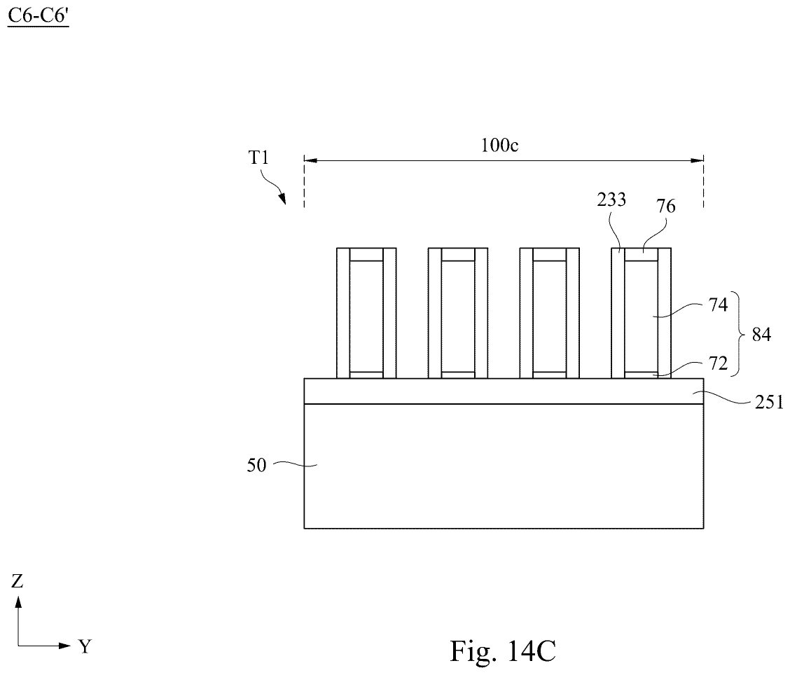

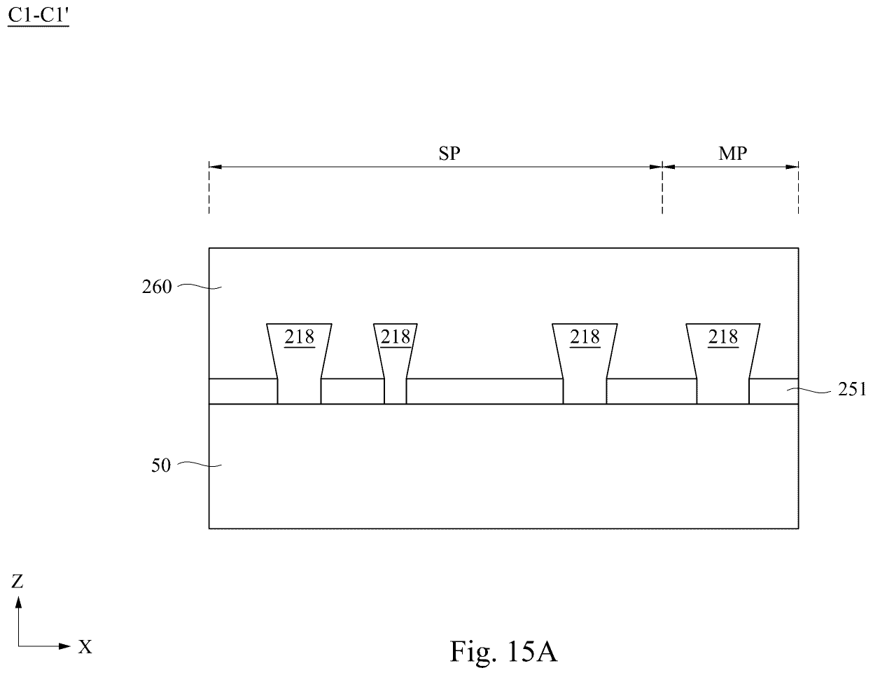

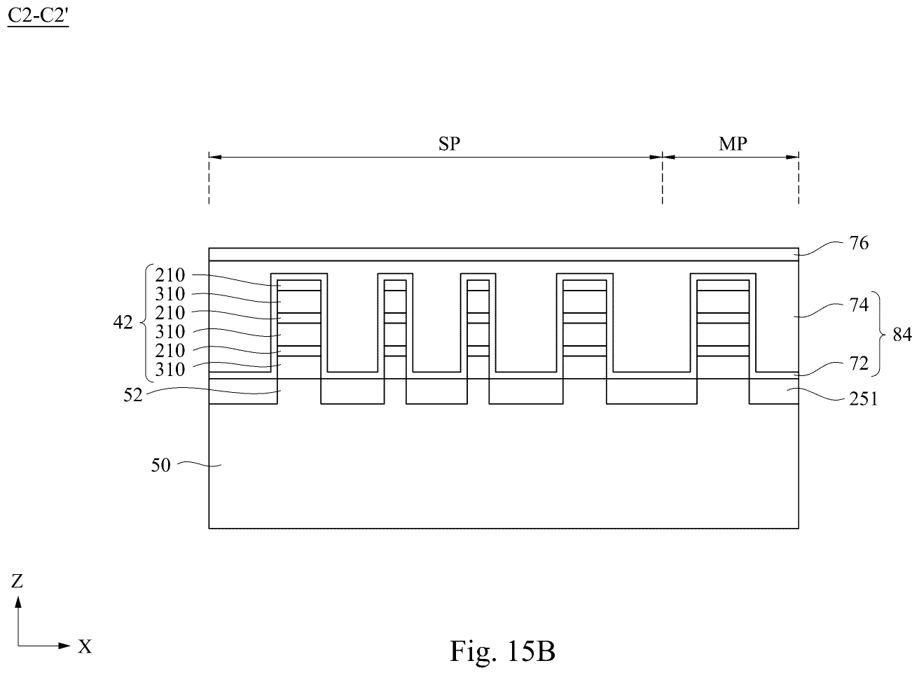

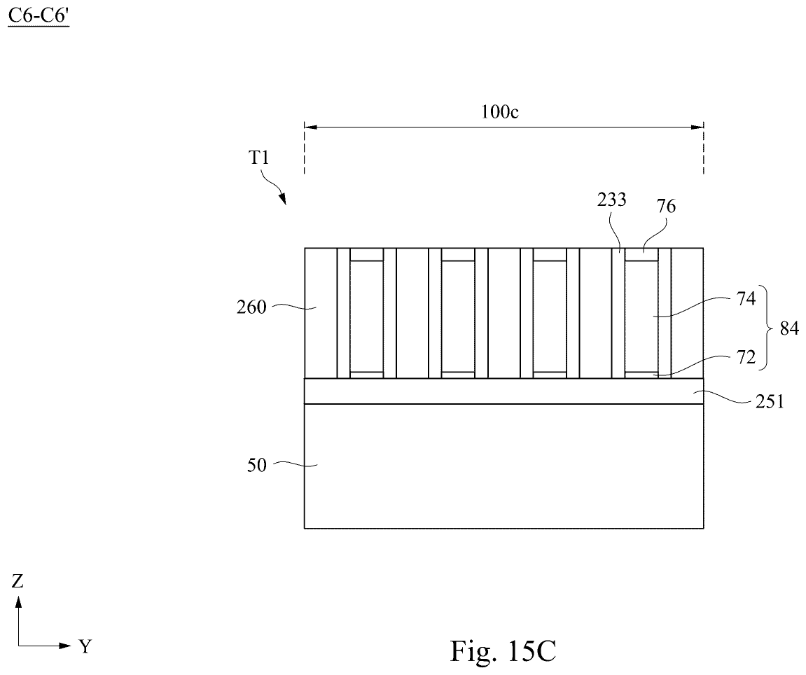

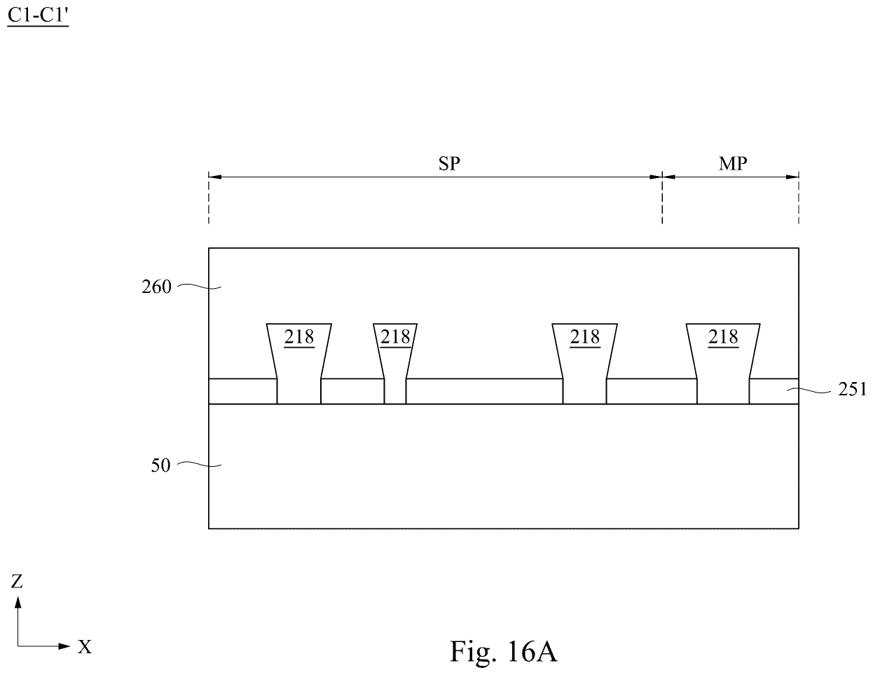

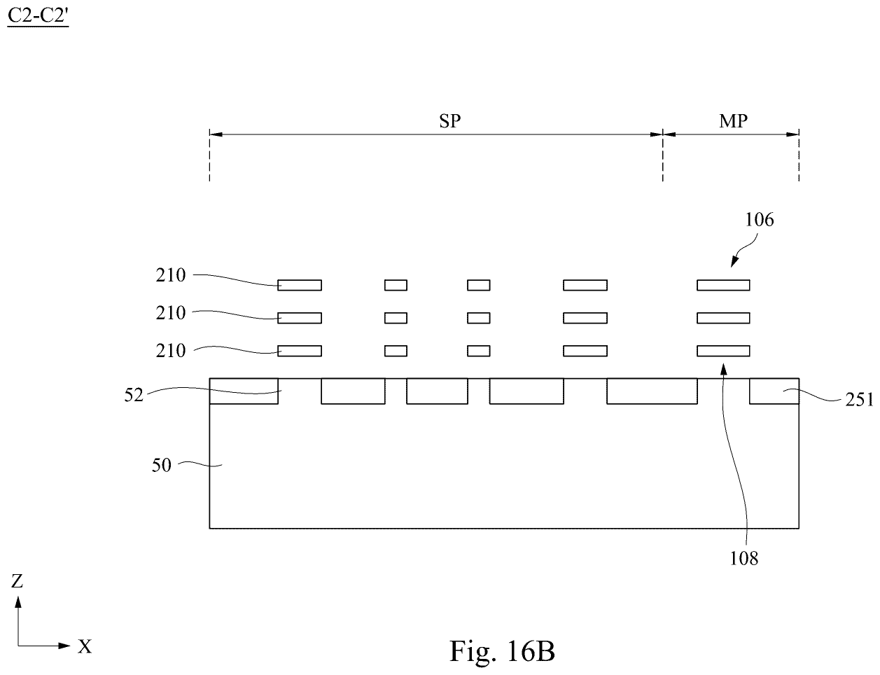

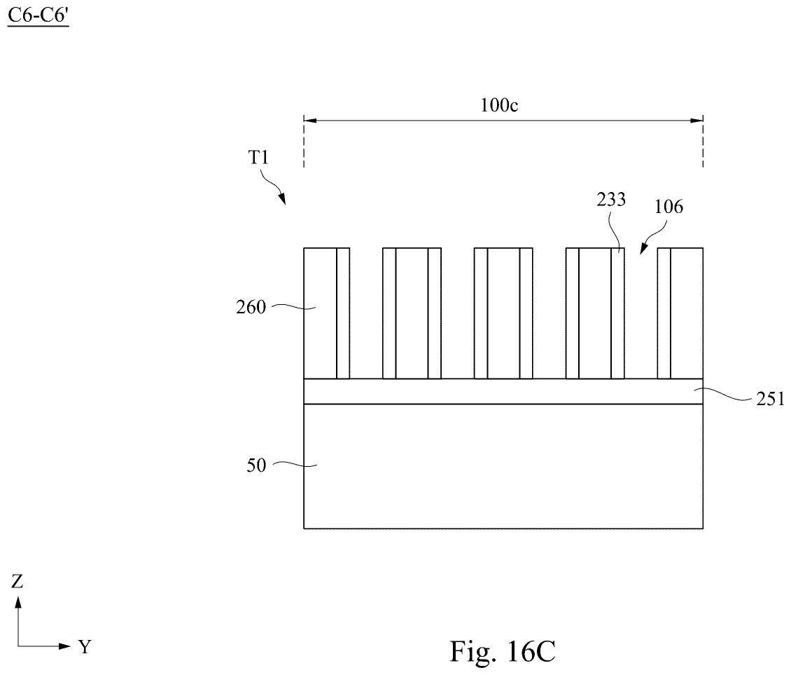

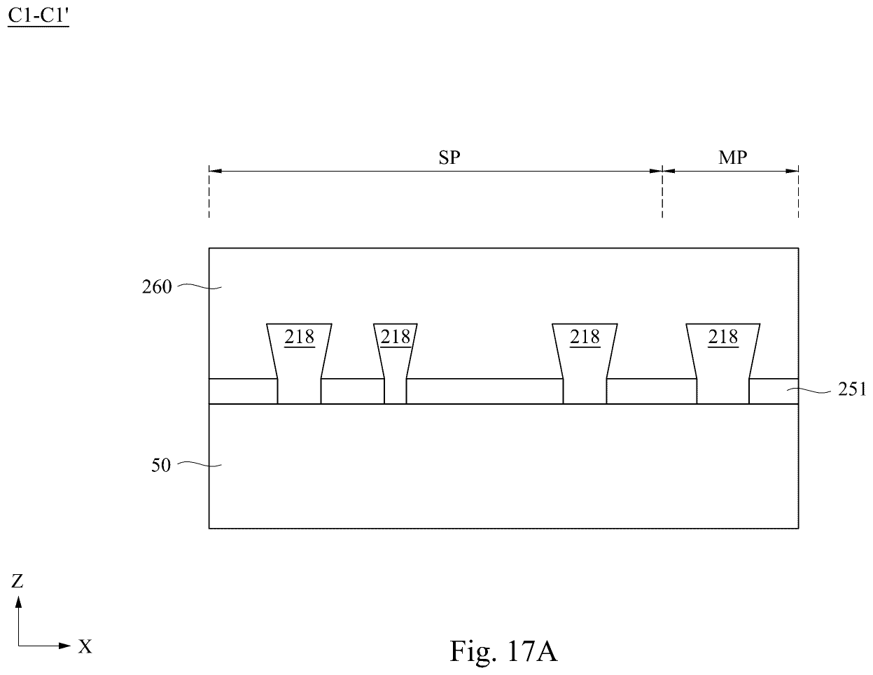

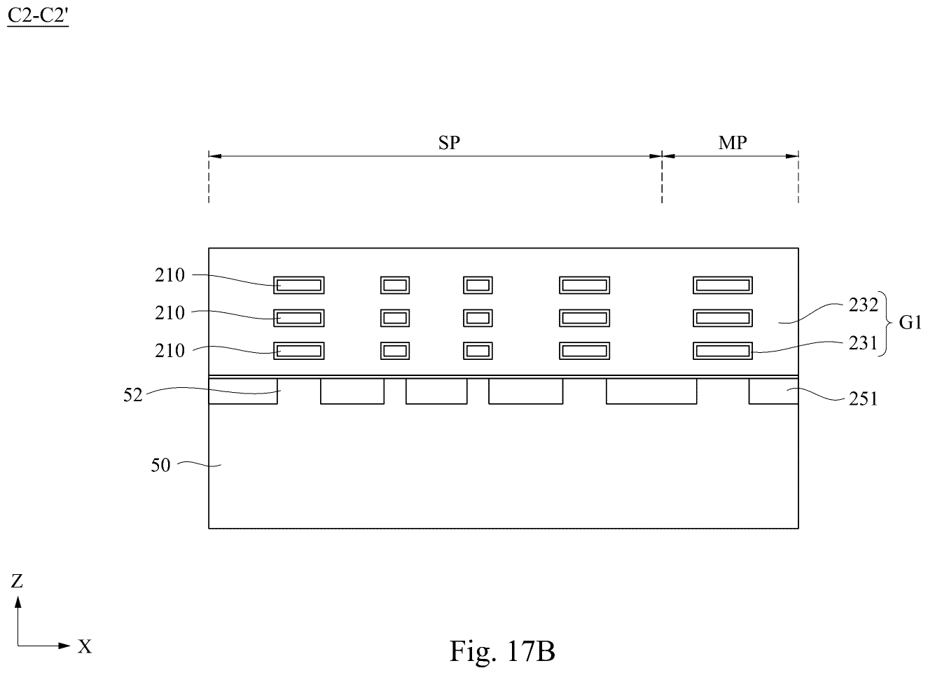

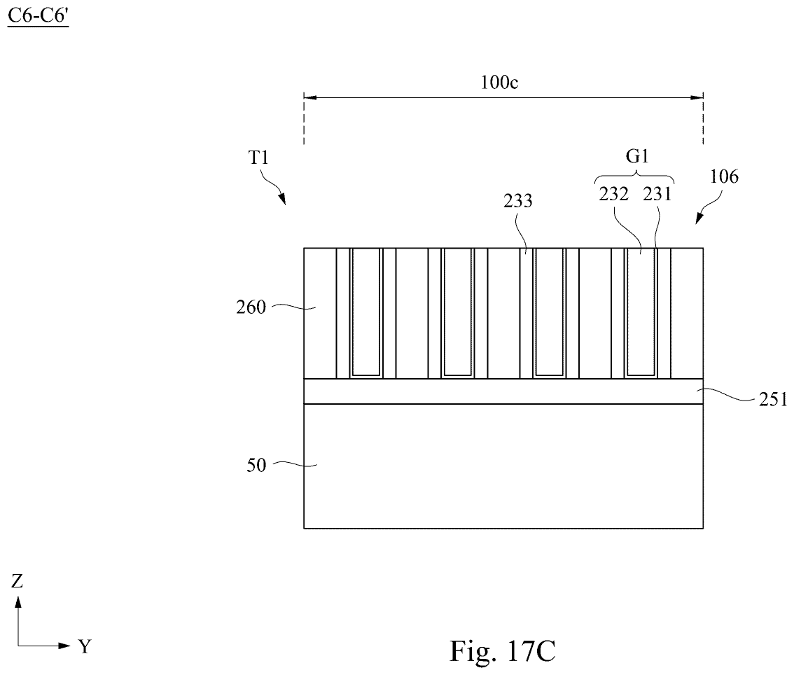

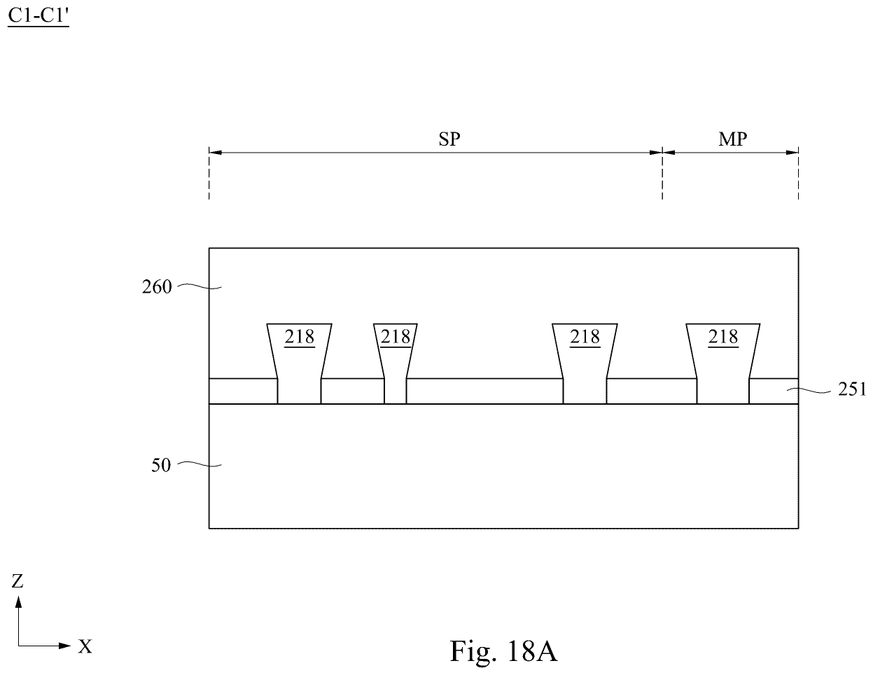

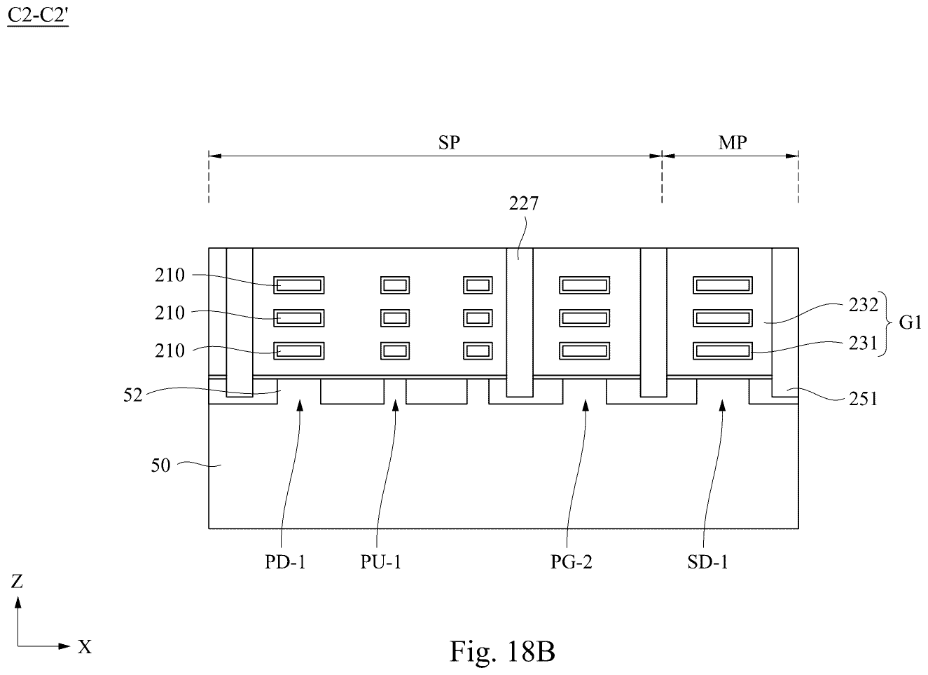

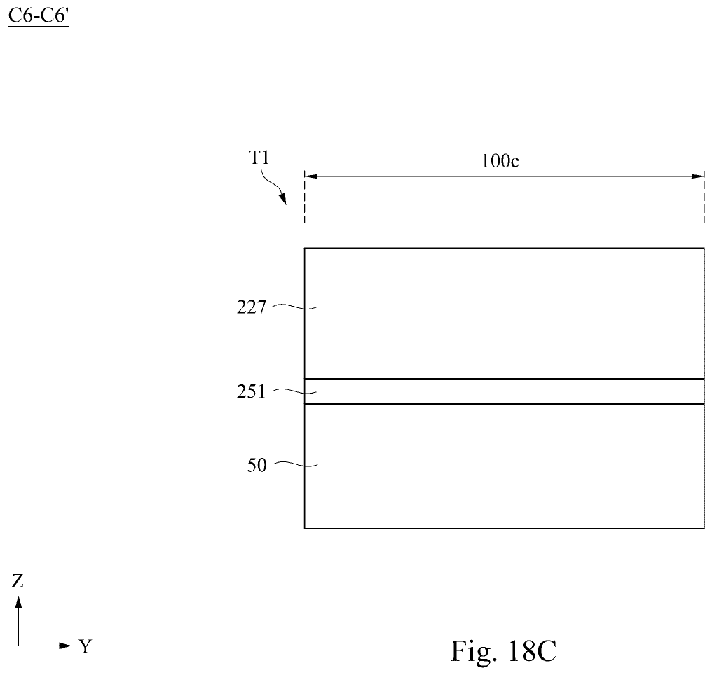

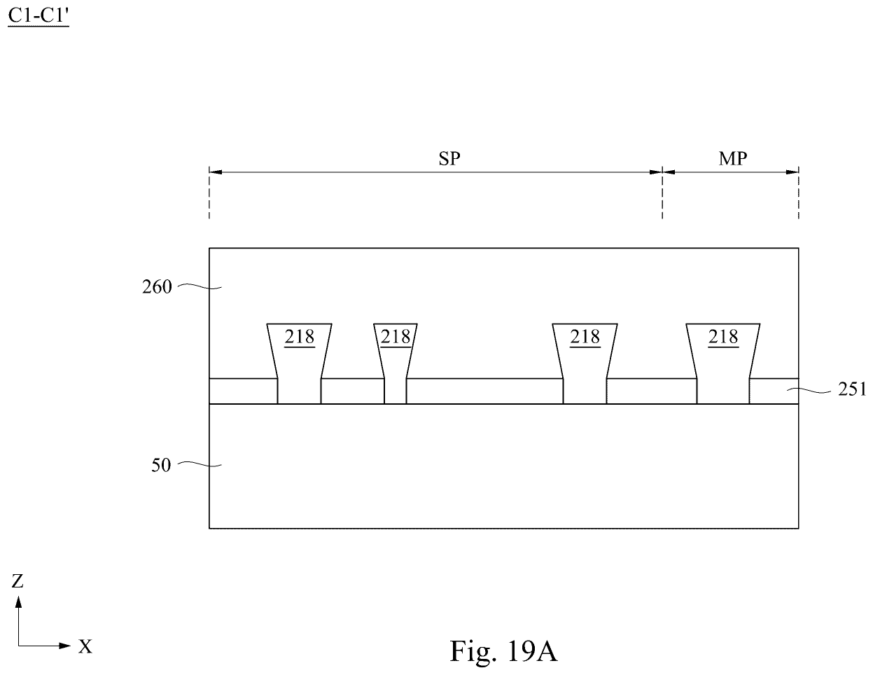

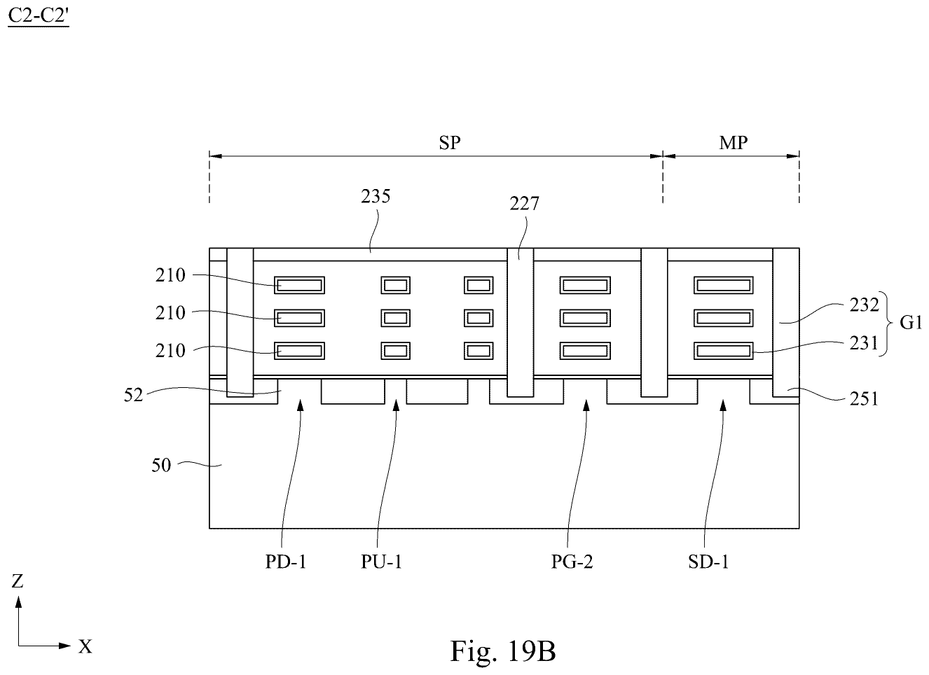

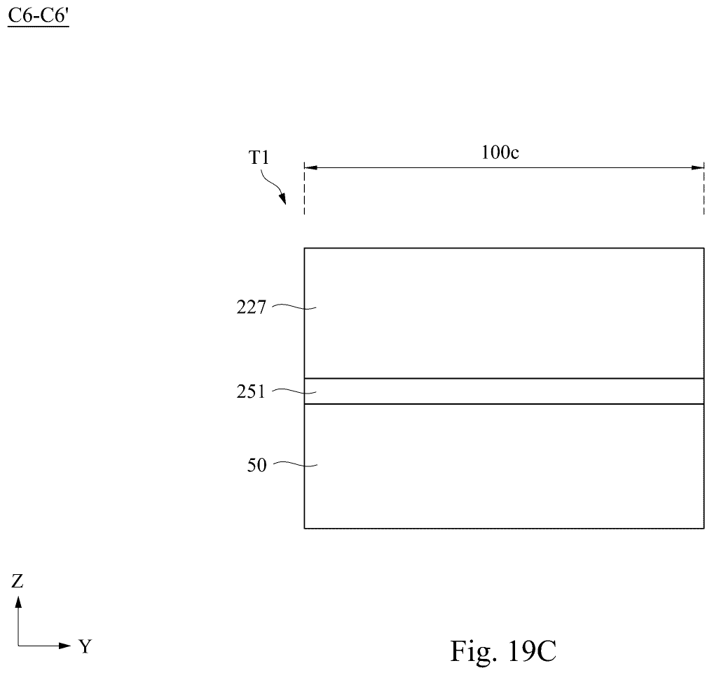

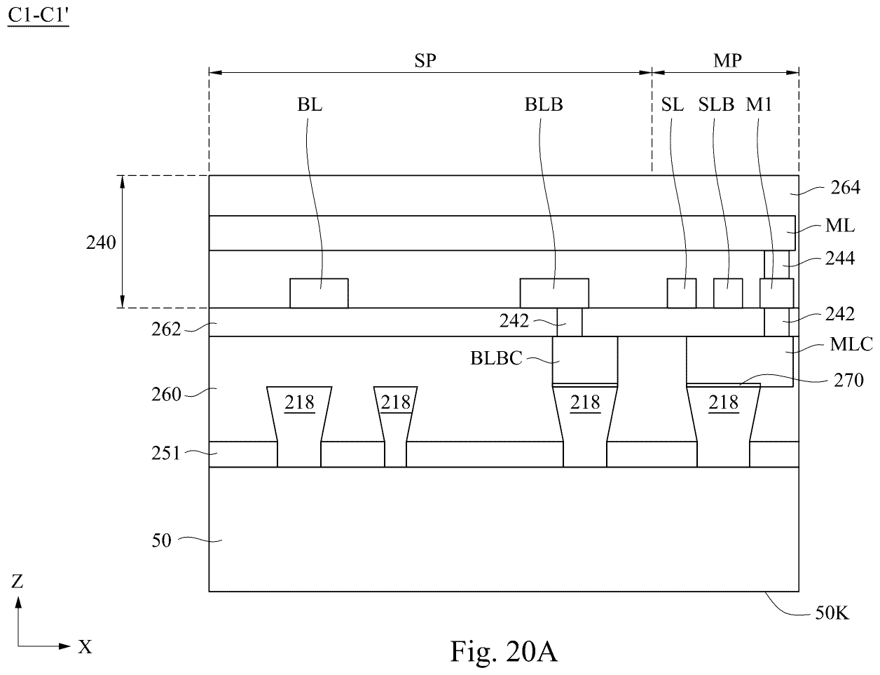

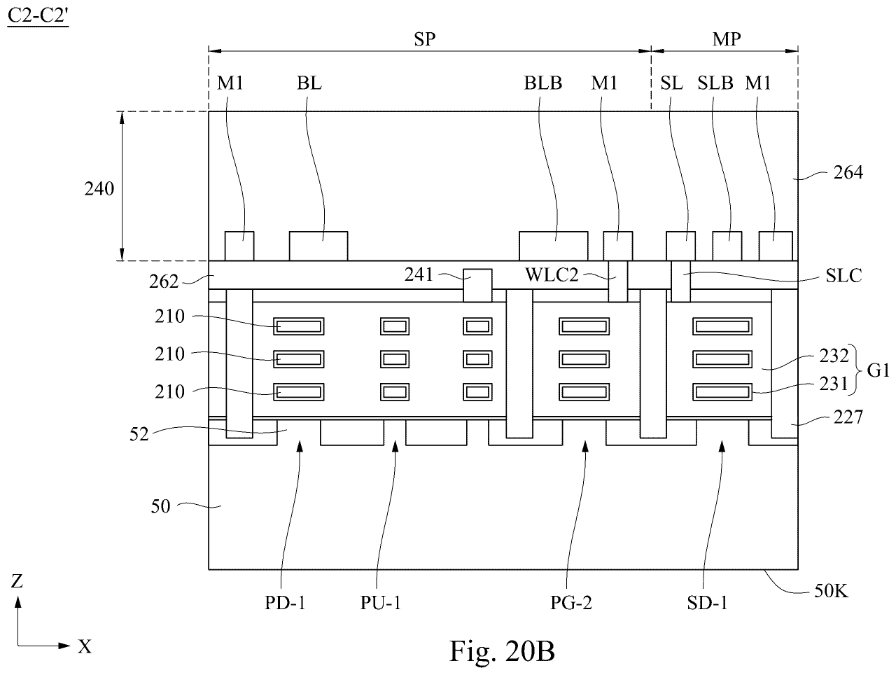

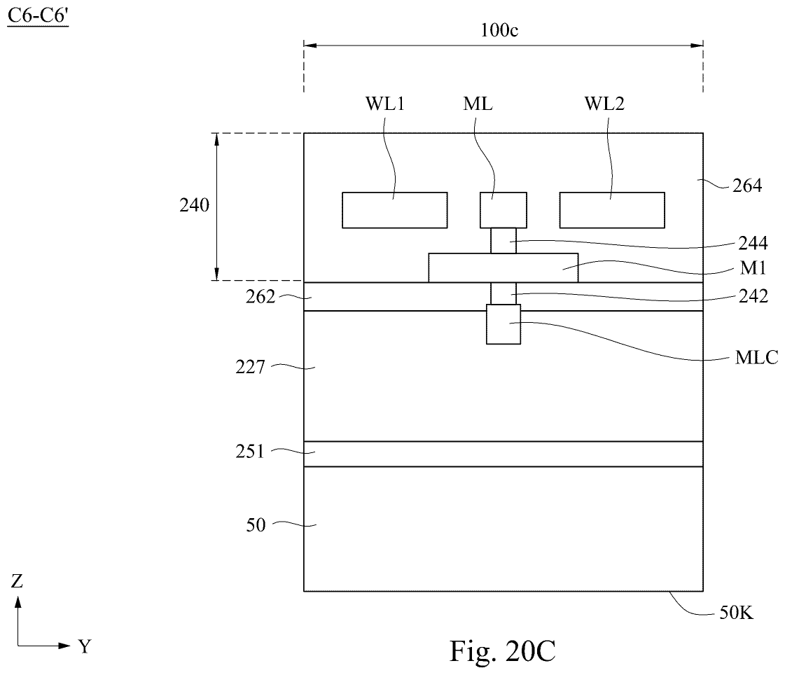

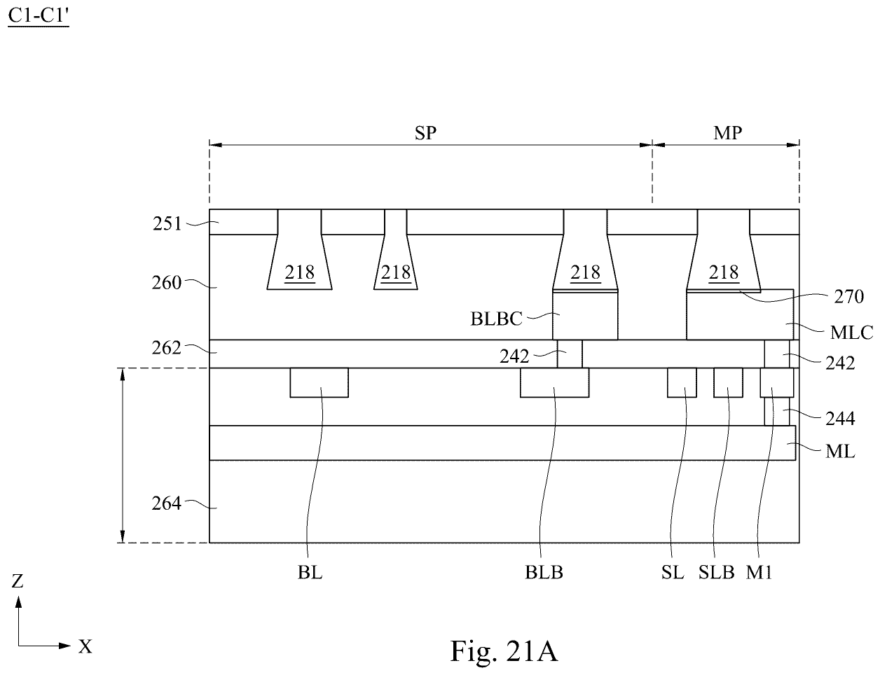

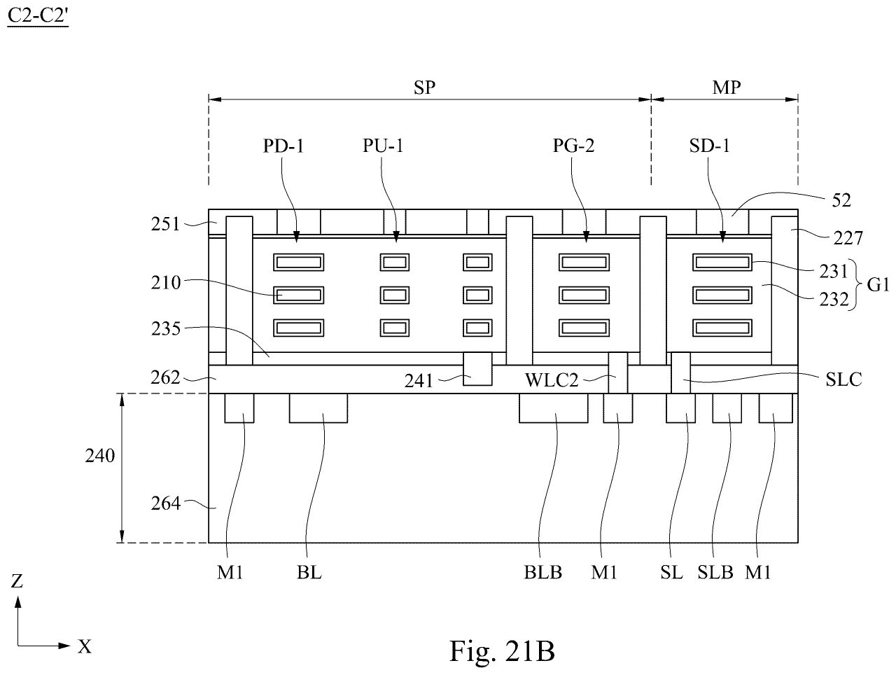

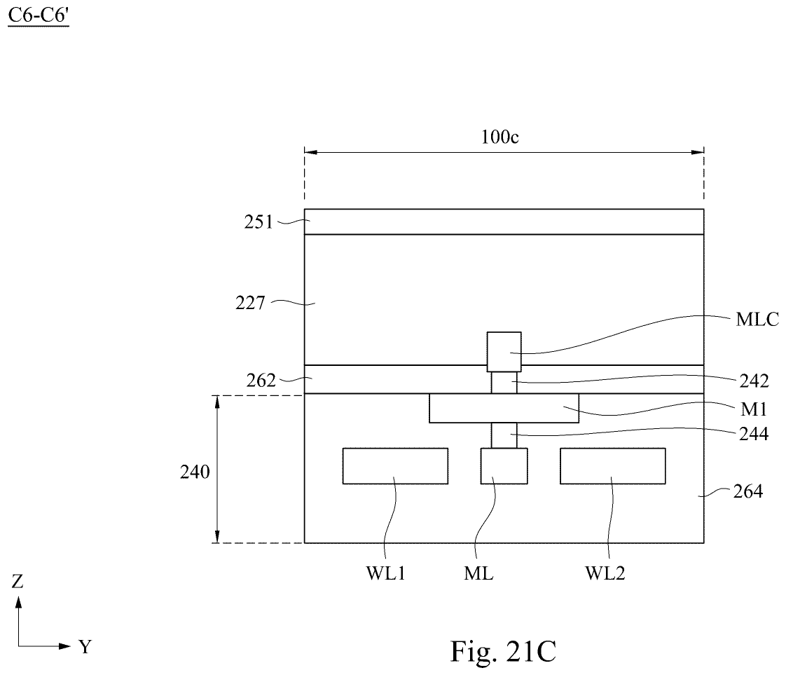

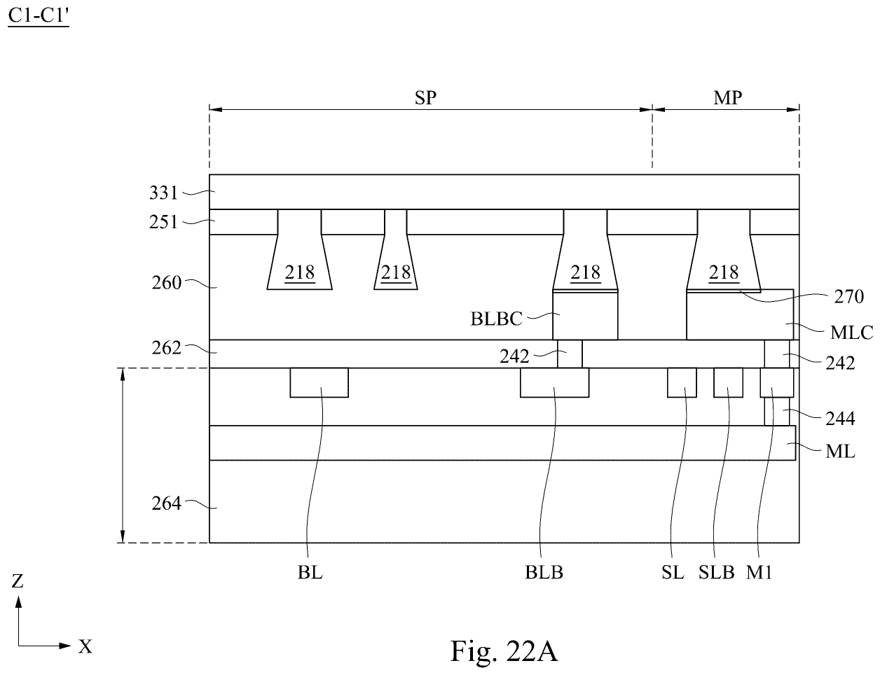

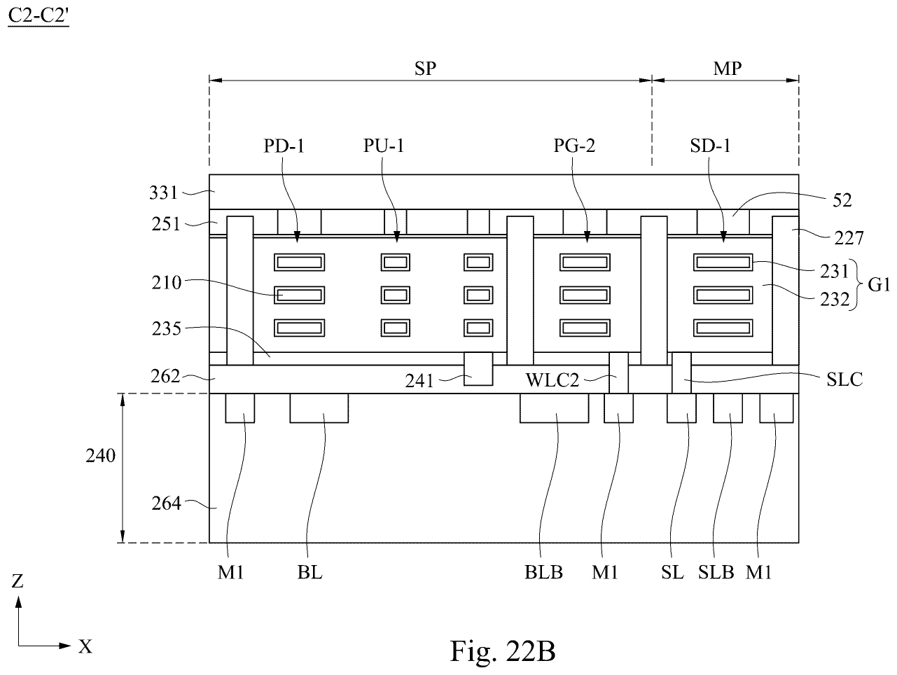

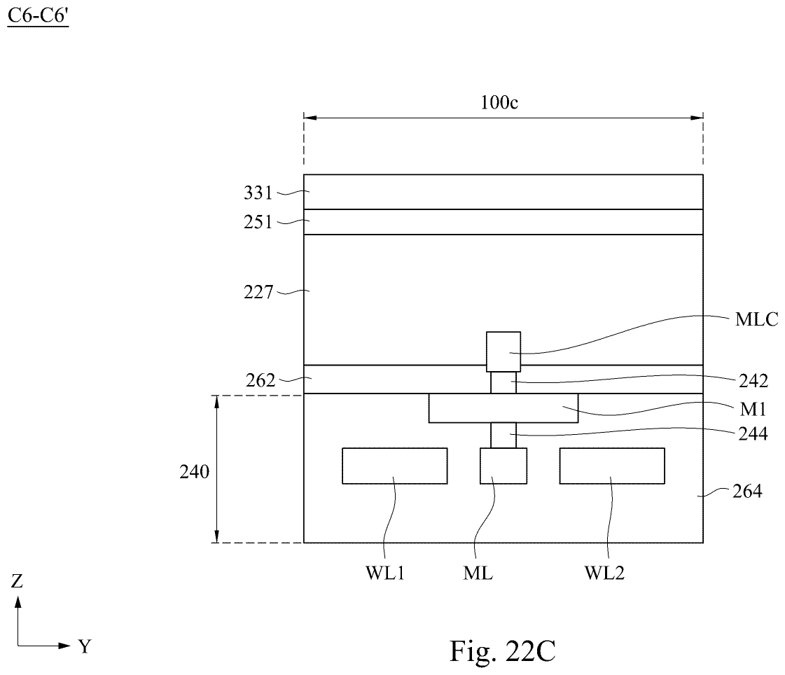

Reference is made to FIGS. 9A-23C. FIGS. 9A-23C illustrate schematic views of intermediate stages in the formation of a semiconductor structure in accordance with some embodiments of the present disclosure. FIGS. 9A, 10A, 11A, 12A, 13A, 14A, 15A, 16A, 17A, 18A, 19A, 20A, 21A, 22A, and 23A illustrate schematic cross-sectional views obtained from reference cross-sections C1-C1′ in FIGS. 2A and 2B. FIGS. 9B, 10B, 11B, 12B, 13B, 14B, 15B, 16B, 17B, 18B, 19B, 20B, 21B, 22B, and 23B illustrate schematic cross-sectional views obtained from reference cross-sections C2-C2′ in FIGS. 2A and 2B. FIGS. 9C, 10C, 11C, 12C, 13C, 14C, 15C, 16C, 17C, 18C, 19C, 20C, 21C, 22C, and 23C illustrate schematic cross-sectional views obtained from reference cross-sections C6-C6′ in FIGS. 2A and 2B. It is understood that additional operations can be provided before, during, and after the processes shown by FIGS. 4A-23C, and some of the operations described below can be replaced or eliminated, for additional embodiments of the method. The order of the operations/processes may be interchangeable.

Reference is made to FIGS. 9A-9C. A substrate 50 can be provided for forming nano-FETs. The substrate 50 may be a semiconductor substrate, such as a bulk semiconductor, a semiconductor-on-insulator (SOI) substrate, or the like, which may be doped (e.g., with a p-type or an n-type impurity) or undoped. The substrate 50 may be a wafer, such as a silicon wafer. Generally, a SOI substrate is a layer of a semiconductor material formed on an insulator layer. The insulator layer may be, for example, a buried oxide (BOX) layer, a silicon oxide layer, or the like. The insulator layer is provided on a substrate, such as a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; combinations thereof; or the like.

Subsequently, a multi-layer stack 42 is formed on the front-side 50f of the substrate 50. The multi-layer stack 42 includes alternating first semiconductor layers 310′ and second semiconductor layers 210′. The first semiconductor layers 310′ formed of a first semiconductor material, and the second semiconductor layers 210′ are formed of a second semiconductor material. The semiconductor materials may each be selected from the candidate semiconductor materials of the substrate 50. In some embodiments, the multi-layer stack 42 includes three layers of each of the first semiconductor layers 310′ and the second semiconductor layers 210′. It should be appreciated that the multi-layer stack 42 may include any number (e.g. about 2 to 6) of the first semiconductor layers 310′ and the second semiconductor layers 210′. In some embodiments, and as will be subsequently described in greater detail, the first semiconductor layers 310′ will be removed and the second semiconductor layers 210′ will patterned to form channel regions for the nano-FETs. The first semiconductor layers 310′ are sacrificial layers (or dummy layers), which will be removed in subsequent processing to expose the top surfaces and the bottom surfaces of the second semiconductor layers 210′. The first semiconductor material of the first semiconductor layers 310′ is a material that has a high etching selectivity from the etching of the second semiconductor layers 210′, such as silicon germanium. The second semiconductor material of the second semiconductor layers 210′ is a material suitable for both n-type and p-type devices, such as silicon.

In some embodiments, the first semiconductor material of the first semiconductor layers 310′ may be made of a material, such as silicon germanium (e.g., SiₓGe₁₋ₓ, where x can be in the range of 0 to 1), pure germanium, a III-V compound semiconductor, a II-VI compound semiconductor, or the like. The second semiconductor material of the second semiconductor layers 210′ may be made of a material, such as silicon, silicon carbide, a III-V compound semiconductor, a II-VI compound semiconductor, or the like. The first semiconductor material and the second semiconductor material may have a high etching selectivity from the etching of one another. Each of the layers of the multi-layer stack 42 may be grown by a process such as vapor phase epitaxy (VPE) or molecular beam epitaxy (MBE), deposited by a process such as chemical vapor deposition (CVD) or atomic layer deposition (ALD), or the like. In some embodiments, the multi-layer stack 42 may have a thickness in a range from about 70 to 120 nm, such as about 70, 80, 90, 100, 110, or 120 nm. In some embodiments, each of the layers may have a small thickness, such as a thickness in a range of about 5 nm to about 40 nm. In some embodiments, some layers (e.g., the second semiconductor layers 210′) are formed to be thinner than other layers (e.g., the first semiconductor layers 310′). For example, in embodiments in which the first semiconductor layers 310′ are sacrificial layers (or dummy layers) and the second semiconductor layers 210′ are patterned to form channel regions for the nano-FETs.

Reference is made to FIGS. 10A-10C. Trenches T1 can be patterned in the substrate 50 and the multi-layer stack 42 to form fins 52 and first and second semiconductive sheets 210 and 310 over the fins 52. The fins 52 can be semiconductor strips patterned in the substrate 50. In some embodiments, the fins 52 can be formed as a fin-like structure underlying the semiconductive sheets 210 and 310. The first semiconductive sheets 310 and the second semiconductive sheets 210 include the remaining portions of the first semiconductor layers 310′ and the second semiconductor layers 210′, respectively. The trenches T1 may be patterned by any acceptable etch process, such as a reactive ion etch (RIE), neutral beam etch (NBE), the like, or a combination thereof. The etching may be anisotropic. The fins 52 and the first and second semiconductive sheets 310, 210 may be patterned by any suitable method. For example, the fins 52 and the first and second semiconductive sheets 310, 210 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used as masks to pattern the fins 52 and the first and second semiconductive sheets 310, 210. In some embodiments, the mask (or other layer) may remain on the first and second semiconductive sheets 310, 210. The fins 52 and the first and second semiconductive sheets 310, 210 may each have widths in a range of about 8 nm to about 40 nm. In some embodiments, the fins 52 and the first and second semiconductive sheets 310, 210 have substantially equal widths. In some embodiments, the semiconductive sheet 210 can be interchangeable referred to as a semiconductive sheet, a semiconductive layer, a semiconductive pattern, a channel layer, a channel pattern, an active region, an active layer, or an active pattern.

Reference is made to FIGS. 11A-11C. STI structures 251 can be formed over the substrate 50 and between the fins 52. The STI structure 251 are disposed around at least a portion of the fin 52 such that at least a portion of the first and second semiconductive sheets 310, 210 protrude from between adjacent STI structures 251. In some embodiments, the top surfaces of the STI structures 251 can be coplanar (within process variations) with the top surfaces of the fins 52. In some embodiments, the top surfaces of the STI structures 251 are above or below the top surfaces of the fins 52. The STI structures 251 can separate the features of adjacent devices.

The STI structures 251 may be formed by any suitable method. For example, an insulation material can be formed over the substrate 50 and the first and second semiconductive sheets 310, 210, and between adjacent fins 52. The insulation material may be an oxide, such as silicon oxide, a nitride, such as silicon nitride, the like, or a combination thereof, which may be formed by a chemical vapor deposition (CVD) process, such as high density plasma CVD (HDP-CVD), flowable chemical vapor deposition (FCVD), the like, or a combination thereof. Other insulation materials formed by any acceptable process may be used. In some embodiments, the insulation material is silicon oxide formed by FCVD. An anneal process may be performed once the insulation material is formed. In some embodiments, the insulation material is formed such that excess insulation material covers the first and second semiconductive sheets 310, 210. Although the STI structures 251 are each illustrated as a single layer, some embodiments may utilize multiple layers. For example, in some embodiments a liner (not separately illustrated) may first be formed along surfaces of the substrate 50, the fins 52, and the first and second semiconductive sheets 310, 210. Thereafter, a fill material, such as those previously described may be formed over the liner.

A removal process is then applied to the insulation material to remove excess insulation material over the first and second semiconductive sheets 310, 210. In some embodiments, a planarization process such as a chemical mechanical polish (CMP), an etch-back process, combinations thereof, or the like may be utilized. In embodiments in which a mask remains on the first and second semiconductive sheets 310, 210, the planarization process may expose the mask or remove the mask. After the planarization process, the top surfaces of the insulation material and the mask (if present) or the first and second semiconductive sheets 310, 210 are coplanar (within process variations). Accordingly, the top surfaces of the mask (if present) or the first and second semiconductive sheets 310, 210 are exposed through the insulation material. In some embodiments, no mask remains on the first and second semiconductive sheets 310, 210. The insulation material is then recessed to form the STI structures 251. The insulation material is recessed, such as in a range from about 30 nm to about 80 nm, such that at least a portion of the first and second semiconductive sheets 310, 210 protrude from between adjacent portions of the insulation material. Further, the top surfaces of the STI structures 251 may have a flat surface as illustrated, a convex surface, a concave surface (such as dishing), or a combination thereof. The top surfaces of the STI structures 251 may be formed flat, convex, and/or concave by an appropriate etch. The insulation material may be recessed using any acceptable etching process, such as one that is selective to the material of the insulation material (e.g., selectively etches the insulation material of the STI structures 251 at a faster rate than the materials of the fins 52 and the first and second semiconductive sheets 310, 210). For example, an oxide removal may be performed using dilute hydrofluoric (dHF) acid.

The process previously described is just one example of how the fins 52 and the first and second semiconductive sheets 310, 210 may be formed. In some embodiments, the fins 52 and/or the first and second semiconductive sheets 310, 210 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 52 and/or the first and second semiconductive sheets 310, 210. The epitaxial structures may include the alternating semiconductor materials previously described, such as the first semiconductor material and the second semiconductor material. In some embodiments where epitaxial structures are epitaxially grown, the epitaxially grown materials may be in situ doped during growth, which may obviate prior and/or subsequent implantations, although in situ and implantation doping may be used together.

Reference is made to FIGS. 12A-12C. A dummy dielectric layer, a dummy gate layer, and a mask layer are sequentially formed on the fins 52 and the first and second semiconductive sheets 310, 210. Specifically, firstly, the dummy dielectric layer can be formed on the fins 52 and the first and second semiconductive sheets 310, 210. The dummy dielectric layer may be formed of a dielectric material such as silicon oxide, silicon nitride, a combination thereof, or the like, which may be deposited or thermally grown according to acceptable techniques. Subsequently, a dummy gate layer can be formed over the dummy dielectric layer. The dummy gate layer may be formed of a conductive or non-conductive material, such as amorphous silicon, polycrystalline-silicon (polysilicon), poly-crystalline silicon-germanium (poly-SiGe), a metal, a metallic nitride, a metallic silicide, a metallic oxide, or the like, which may be deposited by physical vapor deposition (PVD), CVD, or the like. The dummy gate layer may be formed of material(s) that have a high etching selectivity from the etching of insulation materials, e.g., the STI structures 251 and/or the dummy dielectric layer. Subsequently, a mask layer can be formed over the dummy gate layer. The mask layer may be formed of a dielectric material such as silicon nitride, silicon oxynitride, or the like.

Subsequently, the mask layer is patterned using acceptable photolithography and etching techniques to form masks 76 (see FIGS. 12B and 12C). The pattern of the masks 76 is then transferred to the dummy gate layer by any acceptable etching technique to form dummy gates 74 (see FIGS. 12B and 12C). The pattern of the masks 76 may optionally be further transferred to the dummy dielectric layer by any acceptable etching technique to form dummy dielectrics 72 (see FIGS. 12B and 12C). The dummy gate 74 and the dummy dielectric 72 may be collectively referred to as a dummy gate structure 84. The dummy gate structures 84 cover portions of the first and second semiconductive sheets 310, 210 that will be exposed in subsequent processing to form channel regions. Specifically, the dummy gate structures 84 extend across the portions of the second semiconductive sheets 210 that will be patterned to form channel regions, in lengthwise directions substantially perpendicular (within process variations) to the lengthwise directions of the fins 52b. In some embodiments, the masks 76 can optionally be removed after patterning, such as by any acceptable etching technique.

Subsequently, gate spacers 233 (see FIG. 12C) can be formed over the first and second semiconductive sheets 310, 210, on exposed sidewalls of the masks 76, the dummy gates 74, and the dummy dielectrics 72. In some embodiments, the gate spacers 233 can be interchangeably referred to top/upper spacers. In some embodiments, the gate spacers 233 may have a lateral dimension in a range from about 4 nm to about 12 nm. The gate spacers 233 may be formed by conformally depositing one or more dielectric material(s) and subsequently etching the dielectric material(s). In some embodiments, the gate spacer 233 may include multiple dielectric material and selected from a group consist of silicon oxide, silicon nitride, silicon oxynitride, silicon oxycarbonitride, carbon doped oxide, nitrogen doped oxide, porous oxide, air gap, or combinations thereof, which may be formed by a conformal deposition process such as chemical vapor deposition (CVD), plasma-enhanced chemical vapor deposition (PECVD), atomic layer deposition (ALD), plasma-enhanced atomic layer deposition (PEALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gate structures 84 (thus forming the gate spacers 233).

Reference is made to FIGS. 13A-13C. Source/drain recesses 94 (see FIG. 13A) can be formed in the first and second semiconductive sheets 310, 210. In some embodiments, the source/drain recesses 94 extend through the first and second semiconductive sheets 310, 210 and into the semiconductive layers 248a and 248b. In some embodiments, the fins 52 may be etched such that bottom surfaces of the source/drain recesses 94 are disposed below the top surfaces of the STI structures 251. The source/drain recesses 94 may be formed by etching the first and second semiconductive sheets 310, 210 using an anisotropic etching process, such as a RIE, a NBE, or the like. The gate spacers 233 and the dummy gate structures 84 collectively mask portions of the fins 52 and/or the first and second semiconductive sheets 310, 210 during the etching processes used to form the source/drain recesses 94. A single etch process may be used to etch each of the first and second semiconductive sheets 310, 210, or multiple etch processes may be used to etch the first and second semiconductive sheets 310, 210. Timed etch processes may be used to stop the etching of the source/drain recesses 94 after the source/drain recesses 94 reach a desired depth.

Subsequently, inner spacers 236 (see FIGS. 3F and 3G) are formed on sidewalls of the remaining portions of the first semiconductive sheets 310, e.g., those sidewalls exposed by the source/drain recesses 94. As will be subsequently described in greater detail, source/drain regions will be subsequently formed in the source/drain recesses 94, and the first semiconductive sheets 310 will be subsequently replaced with corresponding gate structures. The inner spacers 236 act as isolation features between the subsequently formed source/drain regions and the subsequently formed gate structures. Further, the inner spacers 236 may be used to substantially prevent damage to the subsequently formed source/drain regions by subsequent etching processes, such as etching processes used to subsequently remove the first semiconductive sheets 310. In some embodiments, the inner spacers 236 can be interchangeably referred to lower gate spacers. In some embodiments, the inner spacers 236 may have a lateral dimension in a range from about 4 nm to about 12 nm.

As an example to form the inner spacers 236, the source/drain recesses 94 can be laterally expanded. Specifically, portions of the sidewalls of the first semiconductive sheets 310 exposed by the source/drain recesses 94 may be recessed. Although sidewalls of the first semiconductive sheets 310 are illustrated as being straight, the sidewalls may be concave or convex. The sidewalls may be recessed by any acceptable etching process, such as one that is selective to the material of the first semiconductive sheets 310 (e.g., selectively etches the material of the first semiconductive sheets 310 at a faster rate than the material of the second semiconductive sheets 210). The etching may be isotropic. For example, when the second semiconductive sheets 210 are formed of silicon and the first semiconductive sheets 310 are formed of silicon germanium, the etching process may be a wet etch using tetramethylammonium hydroxide (TMAH), ammonium hydroxide (NH₄OH), or the like. In some embodiments, the etching process may be a dry etch using a fluorine-based gas such as hydrogen fluoride (HF) gas. In some embodiments, the same etching process may be continually performed to both form the source/drain recesses 94 and recess the sidewalls of the first semiconductive sheets 310. The inner spacers 236 can then be formed by conformally forming an insulating material and subsequently etching the insulating material. The insulating material may be silicon nitride or silicon oxynitride, although any suitable material, such as low-dielectric constant (low-k) materials having a k-value less than about 3.5, may be utilized. In some embodiments, the inner spacer 236 may have a higher K (dielectric constant) value than the gate spacer 233. In some embodiments, the material of inner spacer is selected from a group including SiO₂, Si₃N₄, SiON, SiOC, SiOCN base dielectric material, air gap, or combinations thereof. The insulating material may be deposited by a conformal deposition process, such as ALD, CVD, or the like. The etching of the insulating material may be anisotropic. For example, the etching process may be a dry etch such as a RIE, a NBE, or the like. Although outer sidewalls of the inner spacers 236 are illustrated as being flush with respect to the sidewalls of the gate spacers 233, the outer sidewalls of the inner spacers 236 may extend beyond or be recessed from the sidewalls of the gate spacers 233. In other words, the inner spacers 236 may partially fill, completely fill, or overfill the sidewall recesses. Moreover, although the sidewalls of the inner spacers 236 are illustrated as being straight, the sidewalls of the inner spacers 236 may be concave or convex.

Reference is made to FIGS. 14A-14C. Epitaxial source/drain regions 218 (see FIG. 14A) can be formed in the source/drain recesses 94, such that each dummy gate 84 (and corresponding channel regions) is disposed between respective adjacent pairs of the epitaxial source/drain regions 218. In some embodiments, the gate spacers 233 and the inner spacers 236 are used to separate the epitaxial source/drain regions 218 from, respectively, the dummy gate structures 84 and the first semiconductive sheets 310 by an appropriate lateral distance so that the epitaxial source/drain regions 218 do not short out with subsequently formed gates of the resulting nano-FETs. A material of the epitaxial source/drain regions 218 may be selected to exert stress in the respective channel regions, thereby improving performance of the semiconductor structure.

For example, the epitaxial source/drain regions 218 may include any acceptable material appropriate for n-type devices. For example, the epitaxial source/drain regions 218 may include materials exerting a tensile strain on the channel regions, such as silicon, silicon carbide, phosphorous doped silicon carbide, silicon phosphide, or the like, such that the epitaxial source/drain regions 218 may be referred to as “n-type source/drain region.” In some embodiments, the source/drain regions 218 may have a phosphorus concentration within a range from about 2E19/cm³ to about 3E21/cm³.

In some embodiments, the epitaxial source/drain regions 218 may include any acceptable material appropriate for p-type devices. For example, the epitaxial source/drain regions 218 may include materials exerting a compressive strain on the channel regions, such as silicon germanium, boron doped silicon germanium, germanium, germanium tin, or the like, such that the epitaxial source/drain regions 218 may be referred to as “p-type source/drain region. ” In some embodiments, the source/drain regions 218 may have a boron concentration within a range from about 1E19/cm³ to about 6E20/cm³. In some embodiments, the source/drain regions 218 may have a Ge atomic percentage within a range of about 36% to about 85%. In some embodiments, the epitaxial source/drain regions 218 may have surfaces raised from respective surfaces of the fin 52 and the first and second semiconductive sheets 310, 210, and may have facets.

Reference is made to FIGS. 15A-15C. An inter-layer dielectric (ILD) layer 260 (see FIGS. 15A and 15C) can be deposited over the epitaxial source/drain regions 218, the gate spacers 233, and the dummy gate structures 84. The ILD layer 260 may be formed of a dielectric material, which may be deposited by any suitable method, such as CVD, plasma-enhanced CVD (PECVD), FCVD, or the like. Acceptable dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) is formed between the ILD layer 260 and the epitaxial source/drain regions 218, the gate spacers 233, and the dummy gate structures 84. The CESL may be formed of a dielectric material, such as silicon nitride, silicon oxide, silicon oxynitride, or the like, having a high etching selectivity from the etching of the ILD 260. The CESL may be formed by an any suitable method, such as CVD, ALD, or the like.

Subsequently, a removal process is performed to level the top surfaces of the ILD layer 260 with the top surfaces of the dummy gate structures 84. In some embodiments, a planarization process such as a chemical mechanical polish (CMP), an etch-back process, combinations thereof, or the like may be utilized. The planarization process may also remove the masks 76 on the dummy gate structures 84, and portions of the gate spacers 233 along sidewalls of the masks 76. After the planarization process, the top surfaces of the gate spacers 233, the ILD layer 260, the CESL, and the dummy gate structures 84 can be coplanar (within process variations). Accordingly, the top surfaces of the dummy gate structures 84 can be exposed through the ILD layer 260. In some embodiments, the masks 76 remain, and the planarization process levels the top surfaces of the ILD layer 260 with the top surfaces of the masks 76.

Reference is made to FIGS. 16A-16C. The dummy gate structures 84 can be removed in an etching process, so that recesses 106 (see FIGS. 16B and 16C) can be formed. In some embodiments, the dummy gate structures 84 can be removed by an anisotropic dry etch process. For example, the etching process may include a dry etch process using reaction gas(es) that selectively etch the dummy gate structures 84 at a faster rate than the ILD layer 260 or the gate spacers 233. During the removal, the dummy dielectrics 72 may be used as etch stop layers when the dummy gate structures 84 are etched. The dummy dielectrics 72 are then removed. Each recess 106 exposes and/or overlies portions of the channel regions. Portions of the second semiconductive sheets 210 which act as the channel regions are disposed between adjacent pairs of the epitaxial source/drain regions 218.

The remaining portions of the first semiconductive sheets 310 can be then removed to expand the recesses 106, such that openings 108 (see FIGS. 16B and 16C) can be formed in regions between the second semiconductive sheets 210. The remaining portions of the first semiconductive sheets 310 can be removed by any acceptable etching process that selectively etches the material of the first semiconductive sheets 310 at a faster rate than the material of the second semiconductive sheets 210. The etching may be isotropic. For example, when the first semiconductive sheets 310 can be formed of silicon germanium and the second semiconductive sheets 210 can be formed of silicon, the etching process may be a wet etch using tetramethylammonium hydroxide (TMAH), ammonium hydroxide (NH₄OH), or the like. In some embodiments, a trim process (not separately illustrated) is performed to decrease the thicknesses of the exposed portions of the second semiconductive sheets 210. In some embodiments, the removing of the remaining portions of the first semiconductive sheets 310 can be interchangeably referred to as a channel releasing process. The second semiconductive sheets 210 can have a vertically sheet pitch within a range of from about 10 nm to about 23 nm, such as about 10, 11, 12, 13, 14, 15, 16, 17, 18, 19, 20, 21, 22, or 23 nm. In some embodiments, the second semiconductive sheets 210 may have a thickness within a range from about 4 to about 8 nm, such as about 4, 5, 6, 7, 8 nm. In some embodiments, the vertically sheet pitch of the between adjacent two of the second semiconductive sheets 210 may be within a range from about 6 to 15 nm, such as about 6, 7, 8, 9, 10, 11, 12, 13, 14, or 15 nm.

Reference is made to FIGS. 17A-17C. Gate structures G1 can be formed to wrap around the second semiconductive sheets 210. Specifically, a gate dielectric layer 231 can be formed in the recesses 106 and the openings 108. Gate electrode layers 232 are formed over the gate dielectric layer 231. The gate dielectric layer 231 and the gate electrode layers 232 are layers for replacement gates, and each wrap around all (e.g., four) sides of the second semiconductive sheet 210. In some embodiments, the gate structure G1 can be interchangeably referred to as a metal gate, a functional gate, a gate strip, a gate pattern, or a gate line.

The gate dielectric layer 231 is disposed on the sidewalls and/or the top surfaces of the fins 52; on the top surfaces, the sidewalls, and the bottom surfaces of the second semiconductive sheets 210; and on the inner sidewalls of the gate spacers 233. The gate dielectric layer 231 may include an oxide such as silicon oxide or a metal oxide, a silicate such as a metal silicate, combinations thereof, multi-layers thereof, or the like. The gate dielectric layer 231 may include a dielectric material having a k-value greater than about 7.0, such as a metal oxide or a silicate of hafnium, aluminum, zirconium, lanthanum, manganese, barium, titanium, lead, and combinations thereof. Although a single-layered gate dielectric layer 231 is illustrated in FIGS. 17B and 17C, as will be subsequently described in greater detail, the gate dielectric layer 231 may include any number of interfacial layers and any number of main layers.

The gate electrode layers 232 may include a metal-containing material such as titanium nitride, titanium oxide, tungsten, cobalt, ruthenium, aluminum, combinations thereof, multi-layers thereof, or the like. Although a single-layered gate electrode layers 232 is illustrated in FIGS. 17B and 17C, as will be subsequently described in greater detail, the gate electrode layer 232 may include any number of work function tuning layers, any number of barrier layers, any number of glue layers, and a fill material. In some embodiments, the gate electrode layers 232 may be made of a material selected from a group including TiN, TaN, TiAl, TiAlN, TaAl, TaAlN, TaAlC, TaCN, WNC, Co, Ni, Pt, W, or combinations thereof.

Subsequently, a removal process is performed to remove the excess portions of the materials of the gate dielectric layer 231 and the gate electrode layers 232, which excess portions are over the top surfaces of the ILD layer 260 and the gate spacers 233, thereby forming gate dielectric layer 231 and gate electrode layers 232. In some embodiments, a planarization process such as a chemical mechanical polish (CMP), an etch-back process, combinations thereof, or the like may be utilized. The gate dielectric layer 231, when planarized, has portions left in the recesses 106 (thus forming the gate dielectric layer 231). The gate electrode layers 232, when planarized, have portions left in the recesses 106 (thus forming the gate electrode layers 232). The top surfaces of the gate spacers 233; the CESL (not shown); the ILD layer 260; the gate dielectric layer 231, and the gate electrodes can be coplanar (within process variations). The gate dielectric layer 231 and the gate electrode layers 232 can form replacement gates of the resulting nano-FETs. In some embodiments, the gate electrode layers 232 each have a gate length in a range from about 6 to about 20 nm, such as about 6, 7, 8, 9, 10, 11, 12, 13, 14, 15, 16, 17, 18, 19, or 20 nm.

Reference is made to FIGS. 18A-18C. Dielectric regions 227 (see FIGS. 18B and 18C) can be formed on opposite ends of the gate structure G1. In some embodiments, each dielectric region 227 can be a gate-cut structure for the gate structure G1, and the gate-cut structure is formed by a cut metal gate (CMG) process. In some embodiments, the dielectric region 227 can be interchangeably referred to a gate end dielectric. Specifically, the opposite ends the gate electrode layers 232 can be removed to form gate trenches. The ends of the gate electrode layers 232 may be removed by dry etching, wet etching, or a combination of dry and wet etching. Subsequently, a dielectric material is deposited into the gate trenches, followed by a planarization process to remove excess portions of the dielectric material. The remaining dielectric material forms the dielectric regions 227.

In some embodiments, the deposition of the dielectric material of the dielectric regions 227 can be performed using a conformal deposition process such as ALD, which may be PEALD, thermal ALD, or the like. The dielectric material may be formed of or comprise SiO₂, SiOC, SiOCN, or the like, or combinations thereof. In some embodiments, the dielectric region 227 may be made of a nitride-based material, such as Si₃N₄, or a carbon-based material, such as SiOCN, or combinations thereof. In some embodiments, the dielectric region 227 may be made of a material having a dielectric constant greater than about 9 (e.g., high dielectric constant (high-k) material). For example, the dielectric region 227 may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. The dielectric regions 227 may be formed of a homogenous material, or may have a composite structure including more than one layer. The dielectric regions 227 may include dielectric liners, which may be formed of, for example, silicon oxide. In some embodiments, the dielectric material of the dielectric regions 227 comprises SiN, and the deposition is performed using process gases including dichlorosilane and ammonia. Hydrogen (H₂) may or may not be added.

Reference is made to FIGS. 19A-19C. An etch back process can be performed on the gate electrode layers 232 and the gate dielectric layer 231 to scale down the gate structure G1. The etch back process may include a bias plasma etching step. The bias plasma etching step may be performed to remove portions of the gate electrode layers 232 and the gate dielectric layer 231. Portions of the gate trenches (e.g., recesses 106) may reappear with shallower depth. Top surfaces of the gate electrode layers 232 and the gate dielectric layer 231 may be no longer level with the ILD layer 260. Inner sidewalls of the gate spacers 233 can be then exposed from the gate electrode layers 232 and the gate dielectric layer 231. In some embodiments, the bias plasma etching step may use a gas mixture of Cl₂, O₂, BCl₃, and Ar with a bias in a range from about 25V to about 1200V.

Subsequently, a hard mask layer 235 can be formed over the gate electrode layers 232 and the gate dielectric layer 231 using, for example, a deposition process to deposit a dielectric material over the substrate 50, followed by a CMP process to remove excess dielectric material above the spacers 233 and the ILD layer 260. In some embodiments, source/drain contacts (e.g., storage node contacts SN1 and SN2, complementary storage node contacts SNB1 and SNB2, bit line contacts BLC1 and BLC2, complementary bit line contact BLBC, match line contact MLC as shown in FIG. 3A) formed subsequently can be formed by a self-aligned contact process using the hard mask layer 235 as a contact etch protection layer. In some embodiments, the hard mask layer 235 may have a thickness in a range from about 2 nm to about 60 nm. In some embodiments, the hard mask layer 235 may be made of a nitride-based material, such as Si₃N₄, SiON, or a carbon-based material, such as SiC, SiOC, SiOCN, or combinations thereof. In some embodiments, the hard mask layer 235 may include SiOₓ, SiBN, SiCBN, other suitable dielectric materials, or combinations thereof. In some embodiments, the hard mask layer 235 may include a metal oxide, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. The hard mask layer 235 can have a different etch selectivity than the spacers 233 and/or the ILD layer 260, so as to selective etch back the hard mask layer 235. By way of example, if the hard mask layer 235 is made of silicon nitride, the spacers 233 and/or the ILD layer 260 may be made of a dielectric material different from silicon nitride. If the hard mask layer 235 is made of silicon carbide (SiC), the spacers 233 and/or the ILD layer 260 may be made of a dielectric material different from silicon carbide. Therefore, the hard mask layer 235 can be used to define self-aligned gate contact region and thus referred to as a self-aligned contact (SAC) structure or a SAC layer. In some embodiments, the hard mask layer 235 may have a thickness in a range from about 2 nm to about 60nm, such as about 2, 5, 10, 15, 20, 25, 30, 35, 40, 45, 50, 55, or 60 nm. In some embodiments, the hard mask layer 235 can be interchangeably referred to a gate-top dielectric layer.

Reference is made to FIGS. 20A-20C. Source/drain contacts (e.g., storage node contacts SN1 and SN2, complementary storage node contacts SNB1 and SNB2, bit line contacts BLC1 and BLC2, complementary bit line contact BLBC, match line contact MLC as shown in FIG. 3A) can be formed in the ILD layer 260 and over the source/drain regions 218. In some embodiments, the power supply voltage contacts 244 can be interchangeably referred to source/drain contacts. In some embodiments, materials of the source/drain contacts and the power supply voltage contacts 244 may include Cu, Co, Ru, Pt, Al, W, Ti, TaN, TiN, Molybdenum (Mo), Ruthenium (Ru), Iridium (Ir), rhodium (Rh), or any combinations thereof.

In some embodiments, front-side silicide layers 270 (see FIG. 20A) can be formed between the source/drain contacts and the source/drain regions 218. In some embodiments, a metal silicidation process can be performed on the source/drain region 218 to form the front-side silicide layer 270. The metal silicidation process is to make a reaction between metal and silicon (or polycrystalline silicon). In some embodiments, a metal layer is formed on the source/drain region 218. Subsequently, regarding the metal silicidation process, a first rapid thermal annealing (RTA) process may be performed in, for example, Ar, He, N2 or other inert atmosphere at a first temperature, such as lower than 200˜300 [symbol] C, to convert the deposited metal layer into metal silicide. This is followed by an etching process to remove the unreacted metal layer from. The etching process may include a wet etch, a dry etch, and/or a combination thereof. As an example, the etchant of the wet etching may include a mixed solution of H₂SO₄, H₂O₂, H₂O, and/or other suitable wet etching solutions, and/or combinations thereof. Then, a second annealing or RTA step at a second temperature higher than the first temperature, such as 400˜500 [symbol] C., thereby forming the front-side silicide layer 270 with low resistance. In some embodiments, the front-side silicide layer 270 may include titanium silicide (TiSi), nickel silicide (NiSi), cobalt silicide (CoSi), Ni-Pt, or combinations thereof.

Subsequently, an ILD layer 262 can be deposited over the ILD layer 260. Subsequently, metal vias 242 can be formed in the ILD layer 262 and land on the source/drain contacts. Gate vias (e.g., search line contact SLC, complementary search line contact SLBC, and word line contacts WLC1, WLC2, WLC3, and WLC4 as shown in FIG. 3A) can be formed to pass through the ILD layer 262 and the hard mask layer 235 and land on the gate structures G1. The metal vias 242 and/or the gate vias 250 may include a metal-containing material such as titanium nitride, titanium oxide, tungsten, cobalt, ruthenium, aluminum, copper, combinations thereof, multi-layers thereof, or the like. The ILD layer 262 may be made of an oxide, such as silicon oxide, a nitride, such as silicon nitride, the like, or a combination thereof, which may be formed by a chemical vapor deposition (CVD) process, such as high density plasma CVD (HDP-CVD), flowable chemical vapor deposition (FCVD), the like, or a combination thereof.

Subsequently, a front-side interconnect structure 240 can be formed over the front-side gate vias and metal vias 242. The front-side interconnect structure 240 can include a plurality of metallization layers with a plurality of metallization vias or interconnects. Other embodiments may contain more or fewer metallization layers and corresponding more or fewer number of vias. The metal line illustrated here just for an example, and the metal line may be otherwise oriented (rotated 90 degrees or at other orientations). The front-side interconnect structure 240 may include the bit line BL, the complementary bit line BLB, search line SL, the complementary search line SLB, and the metal lines M1 formed in a first front-side metallization layer, and include the match line contact MLC and the word lines WL1 and WL2 formed in a second front-side metallization layer over the first front-side metallization layer. The bit line BL, the complementary bit line BLB, search line SL, the complementary search line SLB, the metal lines M1, the match line contact MLC, and the word lines WL1 and WL2 can be formed in an IMD (inter-metal dielectric) layer 264.

In some embodiments, materials of the bit line BL, the complementary bit line BLB, search line SL, the complementary search line SLB, the metal lines M1, the match line contact MLC, and the word lines WL1 and WL2 may include Cu, Co, Ru, Pt, Al, W, Ti, TaN, TiN, Molybdenum (Mo), Ruthenium (Ru), Iridium (Ir), rhodium (Rh), or any combinations thereof. In some embodiments, the IMD layer 264 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, or the like. Subsequently, a protection layer (not shown) can be formed over the front-side interconnect structure 240. The protection layer can be a single layer, some embodiments may utilize multiple dielectric layers. In some embodiments, the protection layer can be a poly layer, or a silicon substrate.

Reference is made to FIGS. 21A-21C. The structures of FIGS. 20A-20C can be “flipped” upside down, and the substrate 50 is removed. The substrate 50 may be removed in a plurality of process operations, for example, CMP, HNA, and/or TMAH etching from the back-side 50k (see FIGS. 20A-20C) of the substrate 50, which stops at the STI structure 251 or the fins 52. After the removal process, the STI structure 251 and/or the fins 52 can be exposed as shown in FIGS. 21A-21C.

Reference is made to FIGS. 22A-22C. A back-side dielectric layer 331 can be formed over a back-side surface of the STI structure 251 and a back-side surface of the fin 52. In some embodiments, the back-side dielectric layer 331 may be made of dielectric material, such as SiO₂, Si₃N₄, SiON, SiOC, SiOCN base dielectric material, or combinations thereof. In some embodiments, the back-side dielectric layer 331 may be made of an oxide, a nitride-based material, such as Si₃N₄, SiON, or a carbon-based material, such as SiC, SiOC, SiOCN, or combinations thereof. In some embodiments, the back-side dielectric layer 331 may be made of a material having a dielectric constant greater than about 9 (e.g., high dielectric constant (high-k) material). For example, the back-side dielectric layer 331 may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof.

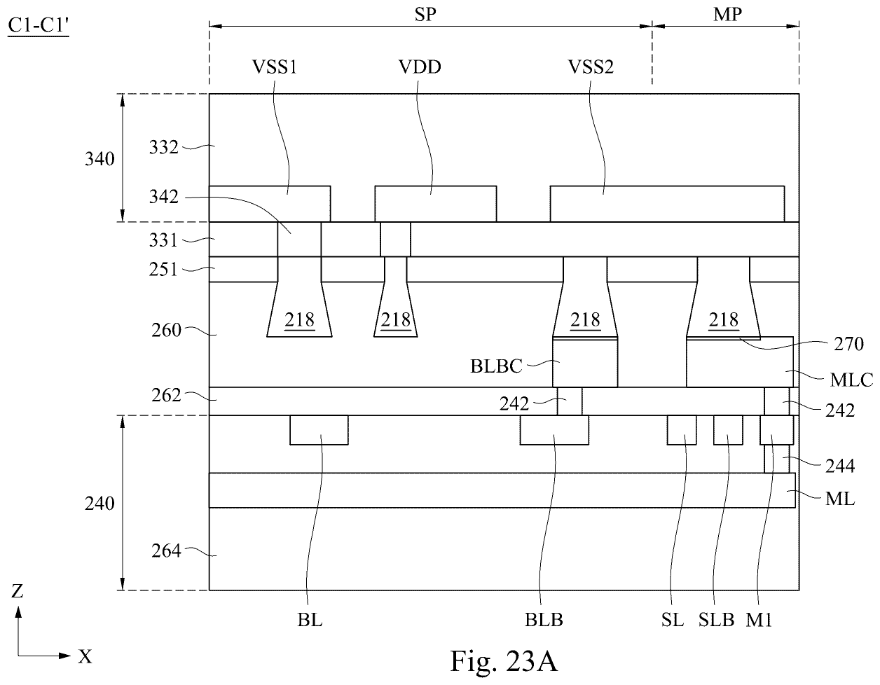

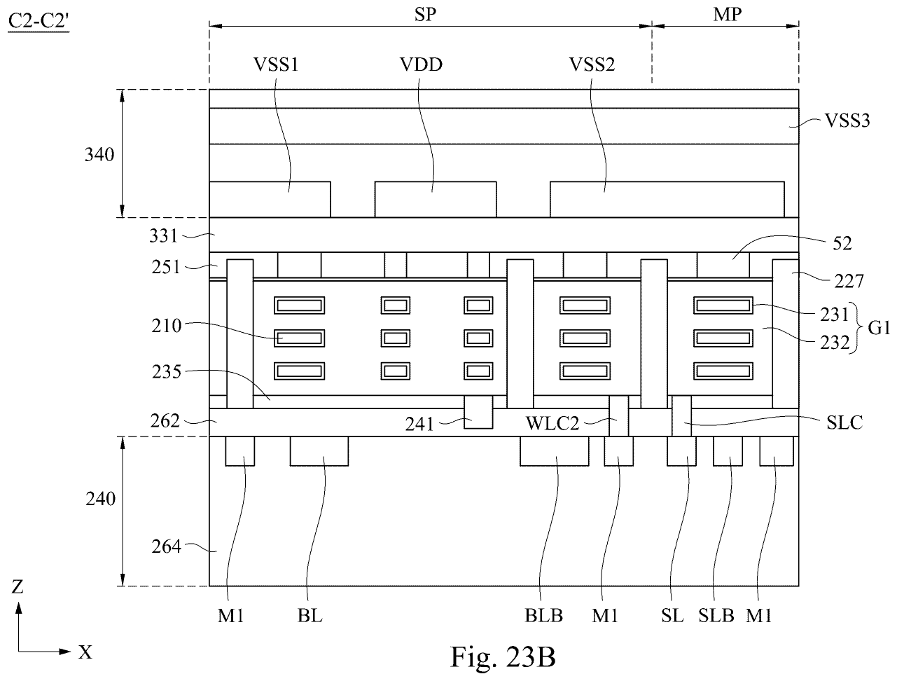

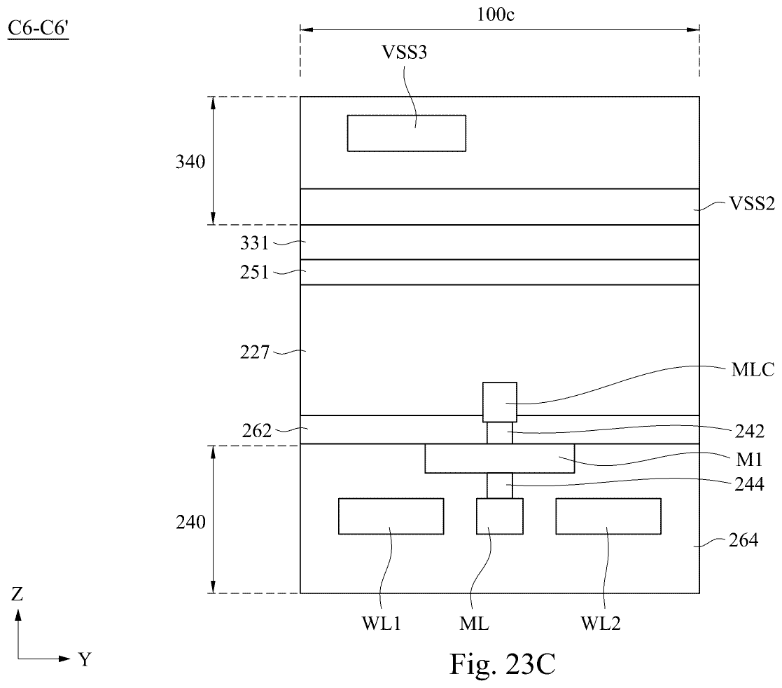

Reference is made to FIGS. 23A-23C. Back-side contacts (e.g., power supply voltage contacts VSSC2, VSSC3, VSSC4, VSSC5, VDDC1, VDDC2, and VDDC3 as shown in FIG. 3B) can be formed in the back-side dielectric layer 331 and over the source/drain regions 218. In some embodiments, materials of the back-side contacts may include Cu, Co, Ru, Pt, Al, W, Ti, TaN, TiN, Molybdenum (Mo), Ruthenium (Ru), Iridium (Ir), rhodium (Rh), or any combinations thereof.

Subsequently, a back-side interconnect structure 340 can be formed over the front-back-side dielectric layer 331. The back-side interconnect structure 340 can includes a plurality of metallization layers with a plurality of metallization vias or interconnects. Other embodiments may contain more or fewer metallization layers and corresponding more or fewer number of vias. The metal line illustrated here just for an example, and the metal line may be otherwise oriented (rotated 90 degrees or at other orientations). The back-side interconnect structure 340 may include the power supply voltage lines VSS1, VSS2, and VDD formed in a first back-side metallization layer, and include the power supply voltage lines VSS3 formed in a second back-side metallization layer over the first back-side metallization layer. The power supply voltage lines VSS1, VSS2, VSS3, and VDD can be formed in an IMD (inter-metal dielectric) layer 332.

In some embodiments, materials of the power supply voltage lines VSS1, VSS2, VSS3, and VDD may include Cu, Co, Ru, Pt, Al, W, Ti, TaN, TiN, Molybdenum (Mo), Ruthenium (Ru), Iridium (Ir), rhodium (Rh), or any combinations thereof. In some embodiments, the IMD layer 332 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, or the like. In some embodiments, after the forming of the back-side interconnect structure 340, a backside to front side connection module formation can be formed on the IC structure, such as a tap structure formation. Subsequently, backside bump pads formation and passivation layer formation can be formed on the back-side interconnect structure 340.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a metal line routing method for memory cell, such as ternary content addressable memory (TCAM) cell, to improve the functional density and operation performance on the IC structure. This method can place lower-level metal layers, such as Vss and/or Vss, to the back-side of the wafer. This placement can not only facilitate further scaling by freeing up space on the front-side but also reduce parasitic capacitance and improve overall device integrity. Additionally, the match line contact of the TCAM cell can be located at the cell boundaries and can be shared with adjacent cells, optimizing the integration within the chip layout and reducing resistance at the junctions, which in turn allows for enhancing the electrical performance and reliability of the device.

In some embodiments, a method includes forming a ternary content addressable memory (TCAM) cell in a device layer, wherein the TCAM cell comprises a first static random access memory (SRAM) cell (e.g., first storage cell 100a illustrated in FIGS. 2A-8B), a second SRAM cell (e.g., second storage cell 100b illustrated in FIGS. 2A-8B), and a match cell (e.g., match cell 100c illustrated in FIGS. 2A-8B), the first SRAM cell comprises a first pull-down transistor (e.g., transistor PU-1 illustrated in FIGS. 2A-8B) and a second pull-down transistor (e.g., transistor PU-2 illustrated in FIGS. 2A-8B), and the second SRAM cell comprises a third pull-down transistor (e.g., transistor PU-3 illustrated in FIGS. 2A-8B) and a fourth pull-down transistor (e.g., transistor PU-4 illustrated in FIGS. 2A-8B); forming a match line (e.g., match line ML illustrated in FIGS. 2A-8B) over a front-side of the device layer, wherein the match line is electrically coupled to the match cell; forming a first power supply voltage line (e.g., power supply voltage line VSS1 illustrated in FIGS. 2A-8B) over a back-side of the device layer, wherein the first power supply voltage line is electrically coupled to the first and third pull-down transistors of the first and second SRAM cells. In some embodiments, the method further includes forming a second power supply voltage line over the back-side of the device layer, wherein the second power supply voltage line is electrically coupled to the second and fourth pull-down transistors of the first and second SRAM cells. In some embodiments, the match cell comprises a first data gate transistor and a second data gate transistor, and the first and second data gate transistors share a source/drain region that is electrically coupled to the match line. In some embodiments, the match cell comprises a first search gate transistor and a second search gate transistor, and the first and second search gate transistors share a source/drain region that is electrically coupled to the match line. In some embodiments, the method further includes forming a second power supply voltage line over the back-side of the device layer, wherein the first SRAM cell comprises a first pull-up transistor and a second pull-up transistor, and the second SRAM cell comprises a third pull-up transistor and a fourth pull-up transistor, and the second power supply voltage line is electrically coupled to the first, second, third, and fourth pull-up transistors. In some embodiments, the method further includes forming a second power supply voltage line over the front-side of the device layer, wherein the first SRAM cell comprises a first pull-up transistor and a second pull-up transistor, and the second SRAM cell comprises a third pull-up transistor and a fourth pull-up transistor, and the second power supply voltage line is electrically coupled to the first, second, third, and fourth pull-up transistors. In some embodiments, the method further includes forming a search line and a complementary search line over the front-side of the device layer at a lower level height than the match line, wherein the match cell comprises a first search gate transistor and a second search gate transistor, the first search gate transistor is electrically coupled to the search line, and the second search gate transistor is electrically coupled to the complementary search line. In some embodiments, the method further includes forming a landing pad at a same level height as the search line and the complementary search line, wherein the match line is electrically coupled to the match cell through the landing pad, and from a top view, the complementary search line is between the search line and the landing pad. In some embodiments, the method further includes forming a landing pad at a same level height as the search line and the complementary search line, wherein the match line is electrically coupled to the match cell through the landing pad, and from a top view, the landing pad is between the search line and the complementary search line. In some embodiments, the method further includes forming a landing pad at a same level height as the search line and the complementary search line, wherein the match line is electrically coupled to the match cell through the landing pad, and from a top view, the search line is between the complementary search line and the landing pad.

In some embodiments, a method includes forming a first static random access memory (SRAM) cell (e.g., first storage cell 100a illustrated in FIGS. 2A-8B) in a device layer, wherein the first SRAM cell each comprises a first pull-up transistor (e.g., transistors PU-2 illustrated in FIGS. 2A-8B) and a first pull-down transistor (e.g., transistors PD-2 illustrated in FIGS. 2A-8B); forming a second SRAM cell (e.g., second storage cell 100b illustrated in FIGS. 2A-8B) in the device layer, wherein the second SRAM cell comprises a second pull-up transistor (e.g., transistors PU-4 illustrated in FIGS. 2A-8B) and a second pull-down transistor (e.g., transistors PD-4 illustrated in FIGS. 2A-8B); forming a match cell (e.g., match cell 100c illustrated in FIGS. 2A-8B) in the device layer, wherein the match cell comprises a first gate data transistor (e.g., transistors DD-1 illustrated in FIGS. 2A-8B) and a second gate data transistor (e.g., transistors DD-2 illustrated in FIGS. 2A-8B), a gate of the first gate data transistor is electrically coupled to a gate of the first pull-up transistor and the first pull-down transistor, and a gate of the second gate data transistor is electrically coupled to a gate of the second pull-up transistor and the second pull-down transistor; forming a first back-side contact extending (e.g., metal via 342 illustrated in FIGS. 2A-8B) over a source/drain region (e.g., epitaxial source/drain regions 218 illustrated in FIGS. 2A-8B) of the first pull-down transistor of the first SRAM cell; forming a first power supply voltage line (e.g., power supply voltage line VSS2 illustrated in FIGS. 2A-8B) over the first back-side contact, the first power supply voltage line being electrically coupled to the source/drain region of the first pull-down transistor through the first back-side contact. In some embodiments, the method further includes forming a second back-side contact extending over a source/drain region of the second pull-down transistor of the second SRAM cell; forming a second power supply voltage line over the second back-side contact, the second power supply voltage line being electrically coupled to the source/drain region of the second pull-down transistor through the second back-side contact. In some embodiments, the first pull-down transistor of the first SRAM cell share the source/drain region with the second pull-down transistor of the second SRAM cell. In some embodiments, the method further includes forming a second back-side contact extending over a source/drain region of the first pull-up transistor of the first SRAM cell; forming a second power supply voltage line over the second back-side contact, the second power supply voltage line being electrically coupled to the source/drain region of the first pull-up transistor through the second back-side contact. In some embodiments, the method further includes forming a bit line, a complementary bit line, a search line, a complementary search line over a front-side of the device layer, wherein from a top view, the complementary bit line, the search line, the complementary search line extend in a direction in parallel with a lengthwise direction of the first power supply voltage line. In some embodiments, the method further includes forming a word line and a match line over a front-side of the device layer, wherein from a top view, the word line and the match line extend in a direction perpendicular to a lengthwise direction of the first power supply voltage line.

In some embodiments, a semiconductor structure includes a device layer, a bit line (e.g., bit line BL illustrated in FIGS. 2A-8B), a match line landing pad (e.g., metal line M1 illustrated in FIGS. 2A-8B), a match line (e.g., match line ML illustrated in FIGS. 2A-8B), and a power supply voltage line (e.g., power supply voltage line VSS2 illustrated in FIGS. 2A-8B). The device layer includes a first ternary content addressable memory (TCAM) cell and a second TCAM cell adjacent to the first TCAM cell, wherein the first TCAM cell comprises a first static random access memory (SRAM) cell (e.g., first storage cell 100a illustrated in FIGS. 2A-8B), a second SRAM cell (e.g., second storage cell 100b illustrated in FIGS. 2A-8B), and a first match cell (e.g., match cell 100c illustrated in FIGS. 2A-8B), and the second TCAM cell comprises a second match cell (e.g., match cell 100c illustrated in FIGS. 2A-8B). The bit line is over a front-side of the device layer, wherein the bit line is electrically coupled to the first and second SRAM cells. The match line landing pad is over the front-side of the device layer, wherein the match line landing pad is electrically coupled to the first and second match cell. The match line is over the match line landing pad. The power supply voltage line is over a back-side of the device layer, wherein the power supply voltage line is electrically coupled to the first SRAM cell, the second SRAM cell, and the first match cell. In some embodiments, the first match cell comprising a first search gate transistor and a second search gate transistor, the first search gate transistor shares a source/drain region with the second search gate transistor, and the match line landing pad is electrically coupled to the shared source/drain region. In some embodiments, the first match cell comprises a first date gate transistor and a second date gate transistor, the first date gate transistor shares a source/drain region with the second date gate transistor, and the match line landing pad is electrically coupled to the shared source/drain region. In some embodiments, the semiconductor structure further includes a word line over the front-side of the device layer, wherein the word line is electrically coupled to the first and second SRAM cells, and the word line is at a higher level height than the bit line and the match line landing pad.

In some embodiments, a semiconductor structure includes a backside dielectric layer, a first transistor cell, a second transistor cell, a cell boundary region, a backside conductive layer, and a front-side metal routing layer. The first transistor cell is over the backside dielectric layer. The first transistor cell includes a first channel layer being of a first conductivity type and a second channel layer being of a second conductivity type, wherein from a top view, the first channel layer has a first width along a lengthwise direction of the first transistor cell, the second channel layer has a second width along the lengthwise direction of the first transistor cell, and the second width is different from the first width. The second transistor cell is over the backside dielectric layer. The cell boundary region is over the backside dielectric layer and coupling to the first and the second transistors cells. The cell boundary region includes a first epitaxial source/drain structure and a second epitaxial source/drain structure separated from the first epitaxial source/drain structure by an isolation layer and located at an edge of the cell boundary region from a cross-sectional view, the first epitaxial source/drain structure being of the first conductivity type and connecting the first channel layer, and the second epitaxial source/drain structure being of the second conductivity type and connecting the second channel layer. The backside conductive layer underlies the backside dielectric layer and couples to a back-side of the first epitaxial source/drain structure. The front-side metal routing layer couples to a front-side of the second epitaxial source/drain structure. In some embodiments, the semiconductor structure further includes an interconnecting feature in the backside dielectric layer. The backside conductive layer couples to the back-side of the first epitaxial source/drain structure through the first interconnecting feature. In some embodiments, the semiconductor structure further includes a first interconnecting feature and a second interconnecting feature. The first interconnecting feature is over the front-side of the second epitaxial source/drain structure. The second interconnecting feature is over the first interconnecting feature, wherein front-side metal routing layer couples to the front-side of the second epitaxial source/drain structure through the first and second interconnecting features. In some embodiments, the second width is wider than the first width.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a ternary content addressable memory (TCAM) cell in a device layer, wherein the TCAM cell comprises a first static random access memory (SRAM) cell, a second SRAM cell, and a match cell, the first SRAM cell comprises a first pull-down transistor and a second pull-down transistor, and the second SRAM cell comprises a third pull-down transistor and a fourth pull-down transistor;
forming a match line over a front-side of the device layer, wherein the match line is electrically coupled to the match cell; and
forming a first power supply voltage line over a back-side of the device layer, wherein the first power supply voltage line is electrically coupled to the first and third pull-down transistors of the first and second SRAM cells.

2. The method of claim 1, further comprising:
forming a second power supply voltage line over the back-side of the device layer, wherein the second power supply voltage line is electrically coupled to the second and fourth pull-down transistors of the first and second SRAM cells.

3. The method of claim 1, wherein the match cell comprises a first data gate transistor and a second data gate transistor, and the first and second data gate transistors share a source/drain region that is electrically coupled to the match line.

4. The method of claim 1, wherein the match cell comprises a first search gate transistor and a second search gate transistor, and the first and second search gate transistors share a source/drain region that is electrically coupled to the match line.

5. The method of claim 1, further comprising:
forming a second power supply voltage line over the back-side of the device layer, wherein the first SRAM cell comprises a first pull-up transistor and a second pull-up transistor, and the second SRAM cell comprises a third pull-up transistor and a fourth pull-up transistor, and the second power supply voltage line is electrically coupled to the first, second, third, and fourth pull-up transistors.

6. The method of claim 1, further comprising:
forming a second power supply voltage line over the front-side of the device layer, wherein the first SRAM cell comprises a first pull-up transistor and a second pull-up transistor, and the second SRAM cell comprises a third pull-up transistor and a fourth pull-up transistor, and the second power supply voltage line is electrically coupled to the first, second, third, and fourth pull-up transistors.

7. The method of claim 1, further comprising:
forming a search line and a complementary search line over the front-side of the device layer at a lower level height than the match line, wherein the match cell comprises a first search gate transistor and a second search gate transistor, the first search gate transistor is electrically coupled to the search line, and the second search gate transistor is electrically coupled to the complementary search line.

8. The method of claim 7, further comprising:
forming a landing pad at a same level height as the search line and the complementary search line, wherein the match line is electrically coupled to the match cell through the landing pad, and from a top view, the complementary search line is between the search line and the landing pad.

9. The method of claim 7, further comprising:
forming a landing pad at a same level height as the search line and the complementary search line, wherein the match line is electrically coupled to the match cell through the landing pad, and from a top view, the landing pad is between the search line and the complementary search line.

10. The method of claim 7, further comprising:
forming a landing pad at a same level height as the search line and the complementary search line, wherein the match line is electrically coupled to the match cell through the landing pad, and from a top view, the search line is between the complementary search line and the landing pad.

11. A method, comprising:
forming a first static random access memory (SRAM) cell in a device layer, wherein the first SRAM cell each comprises a first pull-up transistor and a first pull-down transistor;
forming a second SRAM cell in the device layer, wherein the second SRAM cell comprises a second pull-up transistor and a second pull-down transistor;
forming a match cell in the device layer, wherein the match cell comprises a first gate data transistor and a second gate data transistor, a gate of the first gate data transistor is electrically coupled to a gate of the first pull-up transistor and the first pull-down transistor, and a gate of the second gate data transistor is electrically coupled to a gate of the second pull-up transistor and the second pull-down transistor;
forming a first back-side contact extending over a source/drain region of the first pull-down transistor of the first SRAM cell; and
forming a first power supply voltage line over the first back-side contact, the first power supply voltage line being electrically coupled to the source/drain region of the first pull-down transistor through the first back-side contact.

12. The method of claim 11, further comprising:
forming a second back-side contact extending over a source/drain region of the second pull-down transistor of the second SRAM cell; and
forming a second power supply voltage line over the second back-side contact, the second power supply voltage line being electrically coupled to the source/drain region of the second pull-down transistor through the second back-side contact.

13. The method of claim 11, wherein the first pull-down transistor of the first SRAM cell share the source/drain region with the second pull-down transistor of the second SRAM cell.

14. The method of claim 11, further comprising:
forming a second back-side contact extending over a source/drain region of the first pull-up transistor of the first SRAM cell; and
forming a second power supply voltage line over the second back-side contact, the second power supply voltage line being electrically coupled to the source/drain region of the first pull-up transistor through the second back-side contact.

15. The method of claim 11, further comprising:
forming a bit line, a complementary bit line, a search line, a complementary search line over a front-side of the device layer, wherein from a top view, the complementary bit line, the search line, the complementary search line extend in a direction in parallel with a lengthwise direction of the first power supply voltage line.

16. The method of claim 11, further comprising:
forming a word line and a match line over a front-side of the device layer, wherein from a top view, the word line and the match line extend in a direction perpendicular to a lengthwise direction of the first power supply voltage line.

17. A semiconductor structure, comprising:
a backside dielectric layer;
a first transistor cell over the backside dielectric layer, the first transistor cell comprising a first channel layer being of a first conductivity type and a second channel layer being of a second conductivity type, wherein from a top view, the first channel layer has a first width along a lengthwise direction of the first transistor cell, the second channel layer has a second width along the lengthwise direction of the first transistor cell, and the second width is different from the first width;
a second transistor cell over the backside dielectric layer;
a cell boundary region over the backside dielectric layer and coupling to the first and the second transistors cells, the cell boundary region comprising a first epitaxial source/drain structure and a second epitaxial source/drain structure separated from the first epitaxial source/drain structure by an isolation layer and located at an edge of the cell boundary region from a cross-sectional view, the first epitaxial source/drain structure being of the first conductivity type and connecting the first channel layer, and the second epitaxial source/drain structure being of the second conductivity type and connecting the second channel layer;
a backside conductive layer underlying the backside dielectric layer and coupling to a back-side of the first epitaxial source/drain structure; and
a front-side metal routing layer coupling to a front-side of the second epitaxial source/drain structure.

18. The semiconductor structure of claim 17, wherein the second width is wider than the first width.

19. The semiconductor structure of claim 17, further comprising:
an interconnecting feature in the backside dielectric layer, wherein the backside conductive layer couples to the back-side of the first epitaxial source/drain structure through the interconnecting feature.

20. The semiconductor structure of claim 17, further comprising:
a first interconnecting feature over the front-side of the second epitaxial source/drain structure; and
a second interconnecting feature over the first interconnecting feature, wherein the front-side metal routing layer couples to the front-side of the second epitaxial source/drain structure through the first and second interconnecting features.
